(19) United States
(12) Patent Application Publication
(10) Pub. No.: US 2024/0130225 A1
(43) Pub. Date: Apr. 18, 2024

(54) LIGHT-EMITTING DEVICE, LIGHT-EMITTING APPARATUS, ELECTRONIC DEVICE, DISPLAY DEVICE, AND LIGHTING DEVICE

(71) Applicant: SEMICONDUCTOR ENERGY LABORATORY CO., LTD., Atsugi-shi, Kanagawa-ken (JP)

(72) Inventors: Nobuharu OHSAWA, Zama, Kanagawa (JP); Satoshi SEO, Sagamihara, Kanagawa (JP); Yui YOSHIYASU, Atsugi, Kanagawa (JP); Hideko YOSHIZUMI, Atsugi, Kanagawa (JP)

(21) Appl. No.: 18/262,595

(22) PCT Filed: Jan. 21, 2022
(86) PCT No.: PCT/IB2022/050498

§ 371 Date: Jul. 24, 2023

(30) Foreign Application Priority Data
Jan. 28, 2021 (JP) 2021-012419
Jan. 29, 2021 (JP) 2021-012819

(51) Int. Cl. H10K 85/60; C09K 11/06; H10K 85/30

(52) U.S. Cl. CPC H10K 85/633; C09K 11/06; H10K 85/342; H10K 85/636; H10K 85/654; H10K 85/6572; H10K 85/6576; H10K 50/11

(57) ABSTRACT

A novel light-emitting device that is highly convenient, useful, or reliable is provided. The light-emitting device includes a first electrode, a second electrode, and a first layer. The first layer is positioned between the first electrode and the second electrode. The first layer includes a light-emitting material, a first organic compound, and a first material. The light-emitting material has a function of emitting fluorescent light. The absorption spectrum of the light-emitting material has the longest-wavelength edge at a first wavelength. The first organic compound has a function of converting triplet excitation energy into light emission. The spectrum of the emitted light has the shortest-wavelength edge at a second wavelength. The second wavelength is positioned at a wavelength shorter than the first wavelength. The first organic compound includes a first substituent R1. The first substituent R1 is any of an alkyl group, a substituted or unsubstituted cycloalkyl group, and a trialkylsilyl group. The first material has a function of emitting delayed fluorescent light at room temperature. The difference between the HOMO level and the LUMO level of the first material is smaller than the difference between the HOMO level and the LUMO level of the first organic compound.

### TECHNICAL FIELD

One embodiment of the present invention relates to a light-emitting device, a light-emitting apparatus, an electronic device, a display device, a lighting device, or a semiconductor device.

Note that one embodiment of the present invention is not limited to the above technical field. The technical field of one embodiment of the invention disclosed in this specification relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display apparatus, a light-emitting apparatus, a power storage device, a memory device, a driving method thereof, and a manufacturing method thereof.

### BACKGROUND ART

In recent years, research and development have been extensively conducted on light-emitting devices utilizing electroluminescence (EL). The basic structure of these light-emitting devices is a structure in which a layer containing a light-emitting substance (an EL layer) is interposed between a pair of electrodes. By application of a voltage between the electrodes of this light-emitting device, light emission from the light-emitting substance can be obtained.

Since the above light-emitting device is a self-luminous type, a display device using this has advantages such as high visibility, no necessity of a backlight, and low power consumption. The display device also has advantages in that it can be manufactured to be thin and lightweight and has high response speed, for example.

In the case of a light-emitting device (e.g., an organic EL element) in which an organic compound is used as a light-emitting substance and an EL layer containing the light-emitting organic compound is provided between a pair of electrodes, application of a voltage between the pair of electrodes causes injection of electrons from a cathode and holes from an anode into the light-emitting EL layer and thus a current flows. Then, by recombination of the injected electrons and holes, the light-emitting organic compound is brought into an excited state, and light emission can be obtained from the excited light-emitting organic compound.

The types of excited states formed by an organic compound are a singlet excited state (S*) and a triplet excited state (T*); light emission from the singlet excited state is referred to as fluorescence, and light emission from the triplet excited state is referred to as phosphorescence. The statistical formation ratio of them in the light-emitting device is S*:T*=1:3. For this reason, a light-emitting device using a compound that emits phosphorescence (a phosphorescent material) can have higher emission efficiency than a light-emitting device using a compound that emits fluorescence (a fluorescent material). Therefore, light-emitting devices using phosphorescent materials capable of converting energy of the triplet excited state into light emission have been actively developed in recent years.

Among light-emitting devices using phosphorescent materials, a light-emitting device that emits blue light in particular has not yet been put into practical use because it is difficult to develop a stable compound having a high triplet excitation energy level. For this reason, the development of a light-emitting device using a fluorescent material, which is more stable, has been conducted and a technique for improving the emission efficiency of a light-emitting device using a fluorescent material (a fluorescent light-emitting device) has been searched.

As a material capable of converting part or all of energy of the triplet excited state into light emission, a thermally activated delayed fluorescent (TADF) material is known in addition to a phosphorescent material. In a thermally activated delayed fluorescent material, a singlet excited state is generated from a triplet excited state by reverse intersystem crossing, and energy of the singlet excited state is converted into light emission.

In order to improve the emission efficiency of a light-emitting device using a thermally activated delayed fluorescent material, not only efficient generation of a singlet excited state from a triplet excited state but also efficient light emission from a singlet excited state, that is, high fluorescence quantum yield, is important in the thermally activated delayed fluorescent material. It is, however, difficult to design a light-emitting material that simultaneously meets these two.

A method in which in a light-emitting device containing a thermally activated delayed fluorescent material and a fluorescent material, singlet excitation energy of the thermally activated delayed fluorescent material is transferred to the fluorescent material and light emission is obtained from the fluorescent material has been proposed (see Patent Document 1).

A light-emitting device in which a light-emitting layer includes a host material and a guest material is known (see Patent Document 2). The host material has a function of converting triplet excitation energy into light emission, and the guest material emits fluorescence. The molecular structure of the guest material has a structure including a luminophore and protecting groups, where one molecule includes five or more protecting groups. Introduction of the protecting groups into the molecule can inhibit the transfer of triplet excitation energy from the host material to the guest material by the Dexter mechanism. As the protecting groups, alkyl groups or branched-chain alkyl groups can be used.

### REFERENCE

### Patent Document

[Patent Document 1] Japanese Published Patent Application No. 2014-45179
[Patent Document 2] PCT International Publication No. 2019/171197

### SUMMARY OF THE INVENTION

### Problems to be Solved by the Invention

An object of one embodiment of the present invention is to provide a novel light-emitting device that is highly convenient, useful, or reliable. Another object is to provide a novel electronic device that is highly convenient, useful, or reliable. Another object is to provide a novel display device that is highly convenient, useful, or reliable. Another object is to provide a novel lighting device that is highly convenient, useful, or reliable. Another object is to provide a novel light-emitting device, a novel light-emitting apparatus, a novel electronic device, a novel display device, a novel lighting device, or a novel semiconductor device.

Note that the description of these objects does not preclude the existence of other objects. Note that one embodiment of the present invention does not have to achieve all the objects. Other objects will be apparent from the description of the specification, the drawings, the claims, and the like, and other objects can be derived from the description of the specification, the drawings, the claims, and the like.

### Means for Solving the Problems

(1) One embodiment of the present invention is a light-emitting device including a first electrode, a second electrode, and a first layer.

The second electrode includes a region overlapping with the first electrode, the first layer is positioned between the first electrode and the second electrode, and the first layer includes a light-emitting material FM, a first organic compound, and a first material.

The light-emitting material FM has a function of emitting fluorescent light, and the absorption spectrum of the light-emitting material FM has the longest-wavelength edge at a first wavelength λabs (nm).

The first organic compound has a function of converting triplet excitation energy into light emission, the spectrum of light emitted by the first organic compound has the shortest-wavelength edge at a second wavelength λp (nm), and the second wavelength λp is positioned at a wavelength shorter than the first wavelength λabs.

The first organic compound includes a first substituent R¹, and the first substituent R¹ is any of an alkyl group, a substituted or unsubstituted cycloalkyl group, and a trialkylsilyl group. Note that the number of carbon atoms of the alkyl group is 3 to 12, the number of carbon atoms forming a ring of the cycloalkyl group is 3 to 10, and the number of carbon atoms of the trialkylsilyl group is 3 to 12.

The first material has a function of emitting delayed fluorescent light at room temperature.

(2) One embodiment of the present invention is a light-emitting device including a first electrode, a second electrode, and a first layer.

The second electrode includes a region overlapping with the first electrode, the first layer is positioned between the first electrode and the second electrode, and the first layer contains a light-emitting material FM, a first organic compound, and a first material.

The light-emitting material FM has a function of emitting fluorescent light, and the absorption spectrum of the light-emitting material FM has the longest-wavelength edge at a first wavelength λabs (nm).

The first organic compound has a function of converting triplet excitation energy into light emission, the spectrum of light emitted by the first organic compound has the shortest-wavelength edge at a second wavelength λp (nm), and the second wavelength λp is positioned at a wavelength shorter than the first wavelength λabs.

The first organic compound includes a first substituent R¹, and the first substituent R¹ is any of an alkyl group, a substituted or unsubstituted cycloalkyl group, and a trialkylsilyl group. The number of carbon atoms of the alkyl group is 3 to 12, the number of carbon atoms forming a ring of the cycloalkyl group is 3 to 10, and the number of carbon atoms of the trialkylsilyl group is 3 to 12.

The first material contains a second organic compound and a third organic compound, and the second organic compound and the third organic compound form an exciplex.

(3) One embodiment of the present invention is the above-described light-emitting device in which the first organic compound has a first HOMO level HOMO1 and a first LUMO level LUMO1, and the first material has a second HOMO level HOMO2 and a second LUMO level LUMO2

The first HOMO level HOMO1, the first LUMO level LUMO1, the second HOMO level HOMO2, and the second LUMO level LUMO2 satisfy a formula (1) below.

[Formula 1]

(LUMO2−HOMO2)<(LUMO1−HOMO1) (1)

Accordingly, the first organic compound can be used as an energy donor material ED to allow the transfer of the energy, particularly triplet excitation energy, of the energy donor material ED to the light-emitting material FM. The first substituent R¹ is interposed between the energy donor material ED and the light-emitting material FM that is close to the energy donor material ED. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased.

Triplet excitons generated in the first material can be converted into singlet excitons. The difference between the HOMO level and the LUMO level derived from the first material can be smaller than the difference between the HOMO level and the LUMO level derived from the first organic compound, so that the number of carriers moving in the first material can be increased. The recombination probability of carriers in the first material can be increased. Energy can be transferred from excitons generated in the first material to the energy donor material ED. Excitons can be generated in the first material, and the energy of the excitons can be transferred to the light-emitting material FM through the energy donor material ED. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

Accordingly, the number of carriers moving in the first material can be increased. The recombination probability of carriers in the first material can be increased. Energy can be transferred from excitons generated in the first material to the energy donor material ED. Excitons can be generated in the first material and the energy of the excitons can be transferred to the light-emitting material FM through the energy donor material ED. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

(4) One embodiment of the present invention is the above-described light-emitting device in which the light-emitting material FM has a second substituent R², and the second substituent R² is any of a methyl group, a branched alkyl group, a substituted or unsubstituted cycloalkyl group, and a trialkylsilyl group.

Note that the number of carbon atoms of the branched alkyl group is 3 to 12, the number of carbon atoms forming a ring of the cycloalkyl group is 3 to 10, and the number of carbon atoms of the trialkylsilyl group is 3 to 12.

(5) One embodiment of the present invention is the above-described light-emitting device in which the light-emitting material FM includes five or more second substituents R², and at least five of the five or more second substituents R² are each independently any of a branched alkyl group, a substituted or unsubstituted cycloalkyl group, and a trialkylsilyl group.

Note that the number of carbon atoms of the branched alkyl group is 3 to 12, the number of carbon atoms forming a ring of the cycloalkyl group is 3 to 10, and the number of carbon atoms of the trialkylsilyl group is 3 to 12.

Thus, the second substituent R² is interposed between the light-emitting material FM and the energy donor material ED that is close to the light-emitting material FM. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

(6) One embodiment of the present invention is the above-described light-emitting device in which the light-emitting material FM has a third LUMO level LUMO3, and the third LUMO level LUMO3 is higher than the second LUMO level LUMO2.

(7) One embodiment of the present invention is the above-described light-emitting device in which the second HOMO level HOMO2 is higher than the first HOMO level HOMO1, and the second LUMO level LUMO2 is lower than the first LUMO level LUMO1.

Thus, electrons can be inhibited from being captured by the light-emitting material FM. The recombination probability of carriers in the light-emitting material FM can be reduced. A phenomenon in which the light-emitting material FM in a triplet excited state is generated owing to recombination of carriers in the light-emitting material FM can be inhibited. Excitons can be generated in the first material, and the energy of the excitons can be transferred to the light-emitting material FM through the energy donor material ED. The probability of generating the singlet excited state of the light-emitting material FM can be increased. The emission efficiency can be increased. Consequently, a novel light-emitting device that is highly convenient, useful, or reliable can be provided.

(8) One embodiment of the present invention is the above-described light-emitting device in which the first HOMO level HOMO1 is higher than the second HOMO level HOMO2.

Accordingly, the organometallic complex can capture holes easily. The recombination probability of carriers in the organometallic complex can be increased. The organometallic complex can be used as the energy donor material ED to allow the transfer of the energy, particularly triplet excitation energy, of the energy donor material ED to the light-emitting material FM. The first substituent R¹ is interposed between the energy donor material ED and the light-emitting material FM that is close to the energy donor material ED. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

(9) One embodiment of the present invention is the above-described light-emitting device in which the first LUMO level LUMO1 is lower than the second LUMO level LUMO2.

Accordingly, the organometallic complex can capture electrons easily. The recombination probability of carriers in the energy donor material ED can be increased. The organometallic complex can be used as the energy donor material ED to allow the transfer of the energy, particularly triplet excitation energy, of the energy donor material ED to the light-emitting material FM. The first substituent R¹ is interposed between the energy donor material ED and the light-emitting material FM that is close to the energy donor material ED. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

(10) One embodiment of the present invention is a light-emitting apparatus including the above-described light-emitting device, and a transistor or a substrate.

(11) One embodiment of the present invention is a display device including the above-described light-emitting device, and a transistor or a substrate.

(12) One embodiment of the present invention is a lighting device including the above-described light-emitting apparatus and a housing.

(13) One embodiment of the present invention is an electronic device including the above-described display device, and a sensor, an operation button, a speaker, or a microphone.

Although a block diagram in which components are classified by their functions and shown as independent blocks is shown in the drawing attached to this specification, it is difficult to completely separate actual components according to their functions and one component can relate to a plurality of functions.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

According to one embodiment of the present invention, a novel light-emitting device that is highly convenient, useful, or reliable can be provided. Alternatively, a novel electronic device that is highly convenient, useful, or reliable can be provided. Alternatively, a novel display device that is highly convenient, useful, or reliable can be provided. Alternatively, a novel lighting device that is highly convenient, useful, or reliable can be provided. Alternatively, a novel light-emitting device, a novel light-emitting apparatus, a novel electronic device, a novel display device, a novel lighting device, or a novel semiconductor device can be provided.

Note that the description of these effects does not preclude the existence of other effects. Note that one embodiment of the present invention does not need to have all the effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1E are diagrams illustrating a structure of a light-emitting device of an embodiment.

FIG. 2A to FIG. 2C are diagrams illustrating a structure of a light-emitting device of an embodiment.

FIG. 3A and FIG. 3B are diagrams each illustrating a structure of a light-emitting device of an embodiment.

FIG. 4A and FIG. 4B are diagrams illustrating a structure of a functional panel of an embodiment.

FIG. 5A to FIG. 5C are diagrams illustrating a structure of a functional panel of an embodiment.

FIG. 6A and FIG. 6B are conceptual diagrams of an active matrix light-emitting apparatus.

FIG. 7A and FIG. 7B are each a conceptual view of an active matrix light-emitting apparatus.

FIG. 8 is a conceptual diagram of an active matrix light-emitting apparatus.

FIG. 9A and FIG. 9B are conceptual diagrams of a passive matrix light-emitting apparatus.

FIG. 10A and FIG. 10B are diagrams illustrating a lighting device.

FIG. 11A to FIG. 11D are diagrams illustrating electronic devices.

FIG. 12A to FIG. 12C are diagrams illustrating electronic devices.

FIG. 13 is a diagram illustrating a lighting device.

FIG. 14 is a diagram illustrating a lighting device.

FIG. 15 is a diagram illustrating in-vehicle display devices and lighting devices.

FIG. 16A to FIG. 16C are diagrams illustrating an electronic device.

FIG. 17A to FIG. 17C are diagrams showing a structure of a light-emitting device of an example.

FIG. 18 is graph showing an absorption spectrum and emission spectra of materials used for light-emitting devices of an example.

FIG. 19 is a graph showing an absorption spectrum and emission spectra of materials used for light-emitting devices of an example.

FIG. 20 is a graph showing an absorption spectrum and emission spectra of materials used for light-emitting devices of an example.

FIG. 21 is a graph showing an absorption spectrum and emission spectra of materials used for light-emitting devices of an example.

FIG. 22 is a graph showing current density-luminance characteristics of light-emitting devices of an example.

FIG. 23 is a graph showing luminance-current efficiency characteristics of light-emitting devices of an example.

FIG. 24 is a graph showing voltage-luminance characteristics of light-emitting devices of an example.

FIG. 25 is a graph showing voltage-current characteristics of light-emitting devices of an example.

FIG. 26 is a graph showing luminance-external quantum efficiency characteristics of light-emitting devices of an example.

FIG. 27 is a graph showing emission spectra of light-emitting devices of an example.

FIG. 28 is a graph showing normalized luminance-temporal change characteristics of light-emitting devices of an example.

FIG. 29 is a graph showing voltage-current characteristics of reference devices of an example.

FIG. 30 is a graph showing emission spectra of reference devices of an example.

FIG. 31 is a graph showing changes in emission intensity of reference devices of an example at the time of operating in pulse driving.

FIG. 32 is a graph showing current density-luminance characteristics of light-emitting devices of an example.

FIG. 33 is a graph showing luminance-current efficiency characteristics of light-emitting devices of an example.

FIG. 34 is a graph showing voltage-luminance characteristics of light-emitting devices of an example.

FIG. 35 is a graph showing voltage-current characteristics of light-emitting devices of an example.

FIG. 36 is a graph showing luminance-external quantum efficiency characteristics of light-emitting devices of an example.

FIG. 37 is a graph showing emission spectra of light-emitting devices of an example.

FIG. 38 is a graph showing normalized luminance-temporal change characteristics of light-emitting devices of an example.

FIG. 39 is a graph showing current density-luminance characteristics of light-emitting devices of an example.

FIG. 40 is a graph showing luminance-current efficiency characteristics of light-emitting devices of an example.

FIG. 41 is a graph showing voltage-luminance characteristics of light-emitting devices of an example.

FIG. 42 is a graph showing voltage-current characteristics of light-emitting devices of an example.

FIG. 43 is a graph showing luminance-external quantum efficiency characteristics of light-emitting devices of an example.

FIG. 44 is a graph showing emission spectra of light-emitting devices of an example.

FIG. 45 is a graph showing normalized luminance-temporal change characteristics of light-emitting devices of an example.

FIG. 46 is a graph showing normalized luminance-temporal change characteristics of light-emitting devices of an example.

### MODE FOR CARRYING OUT THE INVENTION

A light-emitting device of one embodiment of the present invention includes a first electrode, a second electrode, and a first layer, and the second electrode includes a region overlapping with the first electrode. The first layer is positioned between the first electrode and the second electrode, and the first layer contains a light-emitting material, a first organic compound, and a first material. The light-emitting material has a function of emitting fluorescent light, and the absorption spectrum of the light-emitting material has the longest-wavelength edge at a first wavelength. The first organic compound has a function of converting triplet excitation energy into light emission, the spectrum of the light emission has the shortest-wavelength edge at a second wavelength, and the second wavelength is positioned at a wavelength shorter than the first wavelength. The first organic compound has a first substituent R¹, and the first substituent R¹ is any of an alkyl group, a cycloalkyl group, and a trialkylsilyl group. The first material has a function of emitting delayed fluorescent light at room temperature, and the difference between the HOMO level and the LUMO level of the first material is lower than that of the first organic compound.

Thus, the first organic compound can be used as an energy donor material to allow the transfer of the energy, particularly triplet excitation energy, of the energy donor material to the light-emitting material. The first substituent R¹ is interposed between the energy donor material and the light-emitting material that is close to the energy donor material. The center distance between the energy donor material ED and the light-emitting material FM that is close to the energy donor material can be set suitable. Energy transfer by the Dexter mechanism can be inhibited. Energy transfer by the Forster mechanism can be dominant. The light-emitting material can be brought into a singlet excited state. The probability of generating the singlet excited state of the light-emitting material can be increased. The emission efficiency can be increased.

Triplet excitons generated in the first material can be converted into singlet excitons. The difference between the HOMO level and the LUMO level derived from the first material can be smaller than the difference between the HOMO level and the LUMO level derived from the first organic compound, so that the number of carriers moving in the first material can be increased. The recombination probability of carriers in the first material can be increased. Energy can be transferred from excitons generated in the first material to the energy donor material. Excitons can be generated in the first material, and the energy of the excitons can be transferred to the light-emitting material through the energy donor material. The light-emitting material can be brought into a singlet excited state. The probability of generating the singlet excited state of the light-emitting material can be increased. The emission efficiency can be increased. Consequently, a novel light-emitting device that is highly convenient, useful, or reliable can be provided.

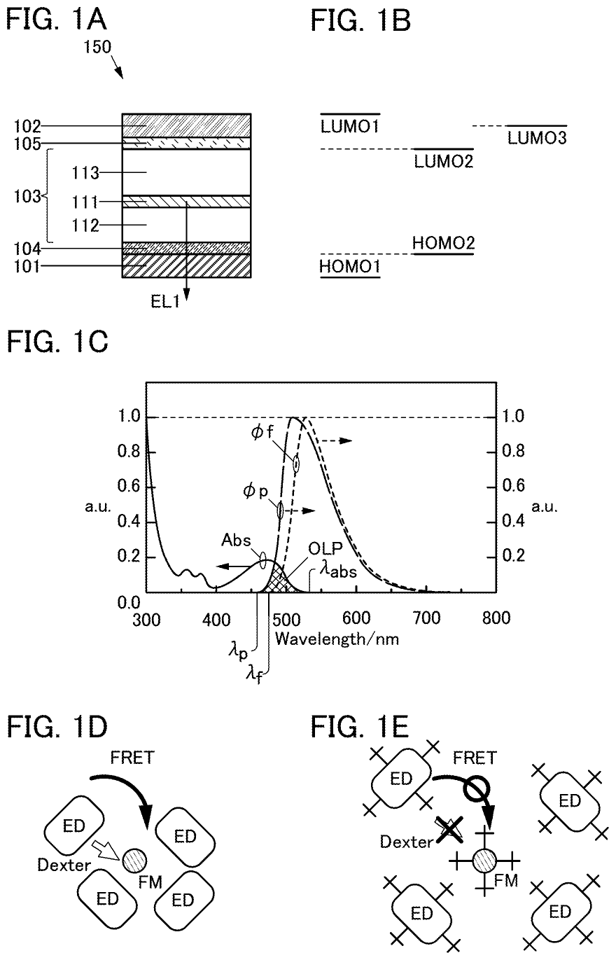

The first layer includes a light-emitting material FM and an energy donor material ED of an exciton capture (harvest) type (see FIG. 1E). An organometallic complex, a TADF material, or an exciplex can be used for the energy donor material ED. A substituent R¹ or a substituent R² is interposed between the energy donor material ED and the light-emitting material FM that is close to the energy donor material ED. The center distance between the energy donor material ED and the light-emitting material FM that is close to the energy donor material can be set suitable. Energy transfer by the Dexter mechanism (Dexter) can be inhibited. Energy transfer by the Forster mechanism (FRET) can be dominant. Note that in general, the Dexter mechanism is dominant when the distance between the energy donor material ED and the light-emitting material FM is less than or equal to 1 nm (see FIG. 1D), and the Forster mechanism is dominant when it is greater than or equal to 1 nm and less than or equal to 10 nm (see FIG. 1E). The light-emitting material FM can be brought into a singlet excited state. The probability of generating the singlet excited state of the light-emitting material FM can be increased. The emission efficiency can be increased. The reliability can be increased.

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

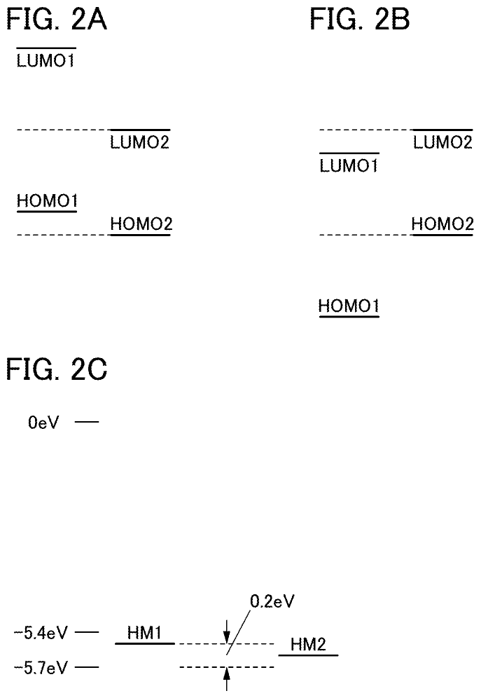

In this embodiment, a structure of a light-emitting device 150 of one embodiment of the present invention is described with reference to FIG. 1 and FIG. 2.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting devices of different colors (here, blue (B), green (G), and red (R)) are separately formed or separately patterned may be referred to as a SBS (Side By Side) structure. In this specification and the like, a light-emitting device capable of emitting white light may be referred to as a white-light-emitting device. Note that a white-light-emitting device that is combined with coloring layers (e.g., color filters) can be a light-emitting device for full-color display.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more of light-emitting layers are selected such that their emission colors are complementary to each other. For example, when emission color of a first light-emitting layer and emission color a second light-emitting layer are complementary colors, the light-emitting device can be configured to emit white light as a whole. The same applies to a light-emitting device including three or more light-emitting layers.

A device having a tandem structure includes two or more light-emitting units between a pair of electrode, and each light-emitting unit preferably includes one or more light-emitting layers. To obtain white light emission, the structure is made so that light from light-emitting layers of the light-emitting units can be combined to be white light. Note that a structure for obtaining white light emission is similar to that in the case of a single structure. In the device having a tandem structure, it is preferable that an intermediate layer such as a charge-generation layer is provided between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

<Structure example of light-emitting device 150>

The light-emitting device 150 described in this embodiment includes an electrode 101, an electrode 102, and a unit 103 (see FIG. 1A). The electrode 102 includes a region overlapping with the electrode 101, and the unit 103 includes a region interposed between the electrode 101 and the electrode 102.

<Structure example of unit 103>

The unit 103 has a single-layer structure or a stacked-layer structure. For example, the unit 103 includes a layer 111, a layer 112, and a layer 113. The unit 103 has a function of emitting light EL1.

The layer 111 includes a region interposed between the layer 112 and the layer 113, the layer 112 includes a region interposed between the electrode 101 and the layer 111, and the layer 113 includes a region interposed between the electrode 102 and the layer 111.

For example, a layer selected from functional layers such as a light-emitting layer, a hole-transport layer, an electron-transport layer, and a carrier-blocking layer can be used in the unit 103. Moreover, a layer selected from functional layers such as a hole-injection layer, an electron-injection layer, an exciton-blocking layer, and a charge-generation layer can be used in the unit 103.

### <<Structure Example 1 of Layer 111>>

The layer 111 contains a light-emitting material FM, an energy donor material ED, and a host material.

### [Example 1 of Light-Emitting Material FM]

The light-emitting material FM has a function of emitting fluorescent light and has an absorption spectrum Abs (see FIG. 1C). The light-emitting material FM can be referred to as a fluorescent substance.

The absorption spectrum Abs of the light-emitting material FM has the longest-wavelength edge at a wavelength λabs (nm). Note that the wavelength λabs (nm) can be calculated as a wavelength at the intersection of the horizontal axis and a tangent to the wavelength in the longest wavelength range at the point where the slope of the tangent of the absorption spectrum has a minimum value. In other words, the wavelength λabs (nm) is an absorption edge of the absorption spectrum.

### [Example 2 of Light-Emitting Material FM]

Fluorescent light emitted by the light-emitting material FM has a fluorescence spectrum ϕf, and the fluorescence spectrum ϕf has the shortest-wavelength edge at a wavelength λf (nm) (see FIG. 1C). The wavelength λf (nm) can be calculated as a wavelength at the intersection of the horizontal axis and a tangent to the wavelength in the shortest wavelength range at the point where the slope of the tangent of the fluorescence spectrum has a maximum value. That is, the wavelength λf (nm) corresponds to the rising (onset) on the shorter wavelength side of the fluorescence spectrum.

### [Example 3 of Light-Emitting Material FM]

For example, any of the following fluorescent substances can be used for the layer 111. Note that the fluorescent substance that can be used for the layer 111 is not limited to the following, and a variety of known fluorescent substances can be used.

Specifically, N,N′,N′,N-tetrakis(4-methylphenyl)-9,10-anthracenediamine (abbreviation: TTPA), N,N′-diphenylquinacridone (abbreviation: DPQd), or the like can be used.

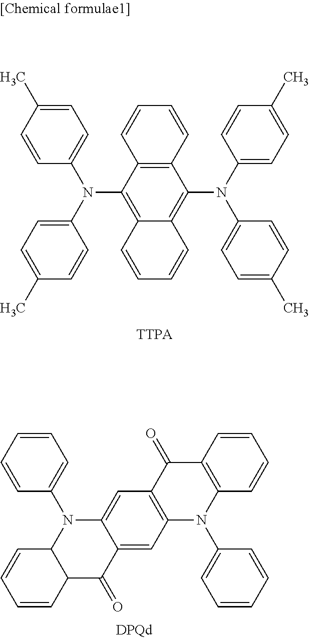 [SMILES: Cc1ccc(N(c2ccc(C)cc2)c2c3ccccc3c(N(c3ccc(C)cc3)c3ccc(C)cc3)c3ccccc23)cc1 ; O=C1c2cc3c(cc2N(c2ccccc2)C2C=CC=CC12)c(=O)c1ccccc1n3-c1ccccc1]

### [Example 1 of Exciplex Donor Material ED]

The energy donor material ED has a function of converting triplet excitation energy into light emission, and an emission spectrum ϕp of the energy donor material ED has a region OLP overlapping with the absorption spectrum Abs of the light-emitting material FM (see FIG. 1C). The region OLP is in the absorption band in the longest wavelength range of the absorption spectrum Abs of the light-emitting material FM.

For example, an organometallic complex can be used as the energy donor material ED. The organometallic complex has a function of emitting phosphorescent light at room temperature, and the phosphorescent spectrum of the organometallic complex overlaps with the absorption spectrum of the light-emitting material FM. That is, the emission spectrum of the energy donor material ED overlaps with the absorption spectrum Abs of the light-emitting material FM.

The phosphorescent spectrum of the organometallic complex has the shortest-wavelength edge at a wavelength λp (nm), and the wavelength λp is positioned at a wavelength shorter than the wavelength λabs (see FIG. 1C). Note that the wavelength λp (nm) can be calculated as a wavelength at the intersection of the horizontal axis and a tangent to the wavelength in the shortest wavelength range at the point where the slope of the tangent of the phosphorescence spectrum has a maximum value. That is, the wavelength λp (nm) corresponds to the rising (onset) on the shorter wavelength side of the phosphorescence spectrum.

The relationship between the wavelength λp (nm) and the wavelength λabs (nm) preferably satisfies Formula (2) shown below. Thus, the absorption band of the light-emitting material FM that is positioned in the longest wavelength range overlaps better with the phosphorescence spectrum of the organometallic complex.

$$\begin{matrix}[ Formula 2 ] & \\ 0.05 < 1240 \times ( \frac{1}{{λ}_{p}} - \frac{1}{{λ}_{abs}} ) \leq 0.3 & ( 2 )\end{matrix}$$

The relationship between the wavelength λp (nm) and the wavelength λf (nm) preferably satisfies Formula (3) shown below. Thus, the absorption band of the light-emitting material FM that is positioned in the longest wavelength range overlaps better with the phosphorescence spectrum of the organometallic complex.

$$\begin{matrix}[ Formula 3 ] & \\ 0 \leq 1240 \times ( \frac{1}{{λ}_{p}} - \frac{1}{{λ}_{f}} ) \leq 0.1 & ( 3 )\end{matrix}$$

For example, the organometallic complex can be used as the energy donor material ED. The organometallic complex has a ligand, and the ligand has a substituent R¹. The substituent R¹ is any of an alkyl group, a cycloalkyl group, and a trialkylsilyl group.

Note that when the substituent R¹ is an alkyl group, the number of carbon atoms of the alkyl group is 3 to 12; when the substituent R¹ is a cycloalkyl group, the number of carbon atoms forming a ring of the cycloalkyl group is 3 to 10; and when the substituent R¹ is a trialkylsilyl group, the number of carbon atoms of the trialkylsilyl group is 3 to 12.

Examples of a secondary or tertiary alkyl group having 3 to 12 carbon atoms are branched-chain alkyl groups such as an isopropyl group and a tert-butyl group. The branched-chain alkyl group is not limited thereto. Examples of a cycloalkyl group having 3 to 10 carbon atoms include a cyclopropyl group, a cyclobutyl group, a cyclohexyl group, a norbomyl group, and an adamantyl group. The cycloalkyl group is not limited thereto. In the case where the cycloalkyl group has a substituent, examples of the substituent include an alkyl group having 1 to 7 carbon atoms, such as a methyl group, an isopropyl group, or a tert-butyl group, a cycloalkyl group having 5 to 7 carbon atoms, such as a cyclopentyl group, a cyclohexyl group, a cycloheptyl group, or a 8,9,10-trinorbomanyl group, and an aryl group having 6 to 12 carbon atoms, such as a phenyl group, a naphthyl group, or a biphenyl group. Examples of a trialkylsilyl group having 3 to 12 carbon atoms include a trimethylsilyl group, a triethylsilyl group, and a tert-butyl dimethylsilyl group. The trialkylsilyl group is not limited thereto.

The substituent R¹ can include, for example, deuterium instead of hydrogen. This can inhibit release of hydrogen. Alternatively, the reliability of the light-emitting device can be increased.

The organometallic complex has a first HOMO level HOMO1 and a first LUMO level LUMO1 (see FIG. 1B).

### [Example 2 of Energy Donor Material ED]

An organometallic complex can be used as the energy donor material ED. The organometallic complex has a ligand and a transition metal. For example, the transition metal can be used as the central metal. In particular, an organometallic complex having iridium or platinum as the central metal is preferably used. Thus, a radiative triplet excited state can be obtained. The organometallic complex can be chemically stabilized. Since a ligand around the central metal is likely to form a three-dimensionally bulky structure, which can easily prevent the Dexter transfer, trivalent iridium is particularly preferred as the central metal.

The ligand has a first ring and a second ring, and at least one substituent R¹ is bonded to at least one of the first ring and the second ring.

The first ring is a six-membered ring and includes an atom that is covalently bonded to the transition metal as a constituent atom. The second ring is a five-membered ring or a six-membered ring and includes an atom that is coordinated to the transition metal as a constituent atom. Note that the first ring is preferably a benzene ring. The constituent atom coordinated to the transition metal may be N as in a pyridine ring or C as in carbene.

### [Example 3 of Energy Donor Material ED]

For example, an organometallic complex can be used as the energy donor material ED. The organometallic complex has a ligand.

The ligand has a phenylpyridine skeleton, and at least one substituent R¹ is bonded to carbon of the phenylpyridine skeleton.

### [Example 4 of Energy Donor Material ED]

For example, an organometallic complex represented by General formula (G0) shown below can be used as the energy donor material ED.

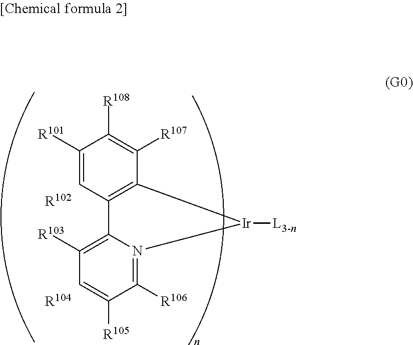

In the above general formula, L is a ligand, and n is an integer greater than or equal to 1 and less than or equal to 3. Note that n is preferably an integer of 2 or more. This inhibits energy transfer by the Dexter mechanism. Alternatively, energy transfer by the Forster mechanism can be dominant.

Furthermore, R¹⁰¹ to R¹⁰⁸ are each hydrogen or a substituent, and R¹⁰¹ to R¹⁰⁸ include any one or more of an alkyl group, a substituted or unsubstituted cycloalkyl group, and a trialkylsilyl group. Note that the alkyl group is preferably an alkyl group having 3 to 12 carbon atoms, the cycloalkyl group preferably has 3 to 10 carbon atoms, and the trialkylsilyl group preferably has 3 to 12 carbon atoms. In other words, the above substituent R¹ is included in R¹⁰¹ to R¹⁰⁸.

Accordingly, emission efficiency can be increased. Consequently, a novel light-emitting device that is highly convenient, useful, or reliable can be provided.

### [Example 5 of Energy Donor Material ED]

For example, two ligands have a phenylpyridine skeleton and a substituent, and the substituent is bonded to carbon of the phenylpyridine skeleton. For example, a secondary or tertiary alkyl group having 3 to 12 carbon atoms, a cycloalkyl group having 3 to 12 carbon atoms, or a trialkylsilyl group having 3 to 12 carbon atoms can be used as the substituent.

Specific examples of the organic compounds with the above structures are shown below.

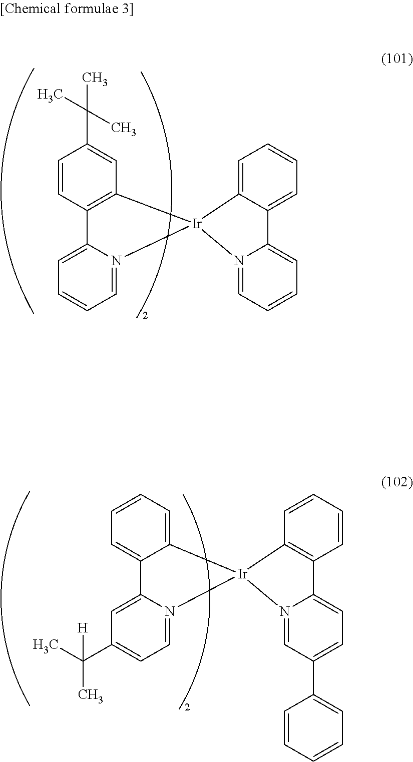

### [Example 6 of Energy Donor Material ED]

For example, three ligands have a phenylpyridine skeleton and one or more substituents, and the substituent is bonded to carbon of the phenylpyridine skeleton. For example, a secondary or tertiary alkyl group having 3 to 12 carbon atoms, a cycloalkyl group having 3 to 12 carbon atoms, or a trialkylsilyl group having 3 to 12 carbon atoms can be used as the substituent. The ligands having the same structure can be used as two of the three ligands.

A specific example of the organic compound with the above structure is shown below.

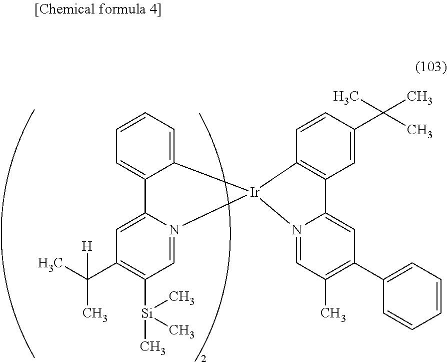

### [Example 7 of Energy Donor Material ED]

For example, three ligands have a phenylpyridine skeleton and a substituent, and the substituent is bonded to carbon of the phenylpyridine skeleton. For example, a secondary or tertiary alkyl group having 3 to 12 carbon atoms, a cycloalkyl group having 3 to 12 carbon atoms, or a trialkylsilyl group having 3 to 12 carbon atoms can be used as the substituent. The ligands having the same structure can be used as the three ligands.

Specific examples of the organic compounds with the above structures are shown below.

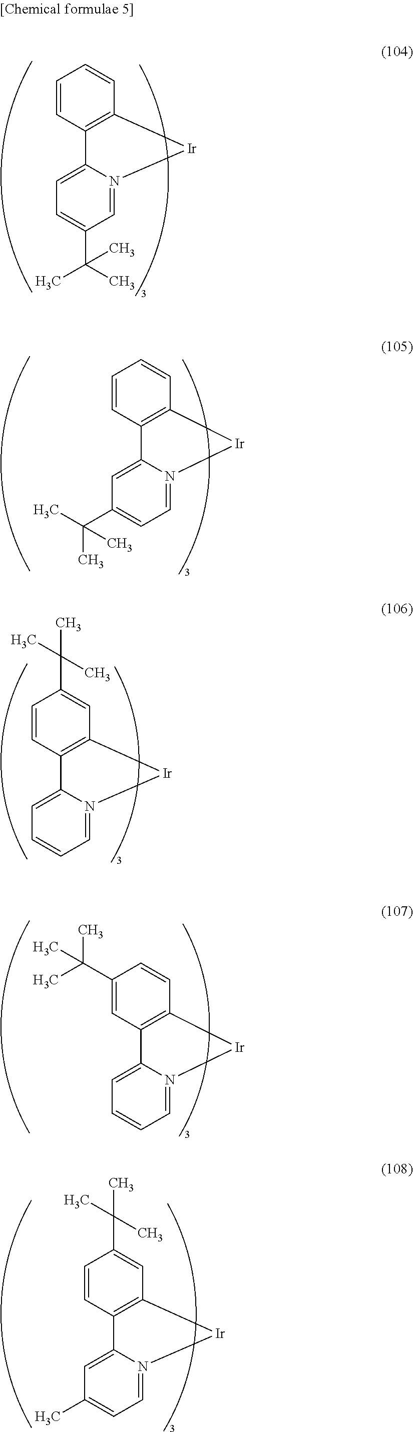

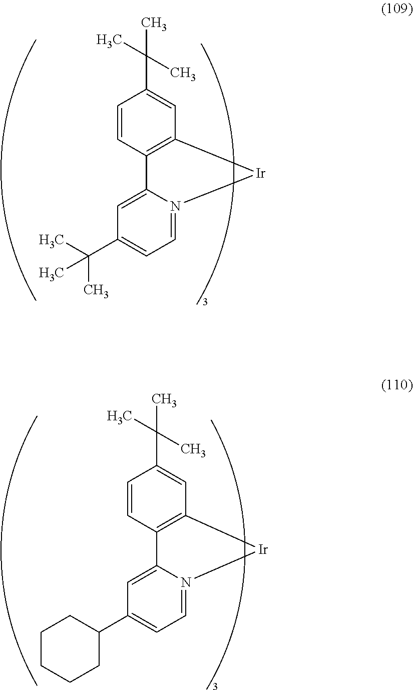

### [Example 8 of Energy Donor Material ED]

For example, a ligand has a phenylpyridine skeleton and a substituent, and the substituent is bonded to carbon of the phenylpyridine skeleton. For example, a secondary or tertiary alkyl group having 3 to 12 carbon atoms, a cycloalkyl group having 3 to 12 carbon atoms, or a trialkylsilyl group having 3 to 12 carbon atoms can be used as the substituent. As the substituent, a substituent in which part or all of the hydrogen is replaced with deuterium can be used. In this case, the reliability can be improved.

Specific examples of the organic compounds with the above structures are shown below.

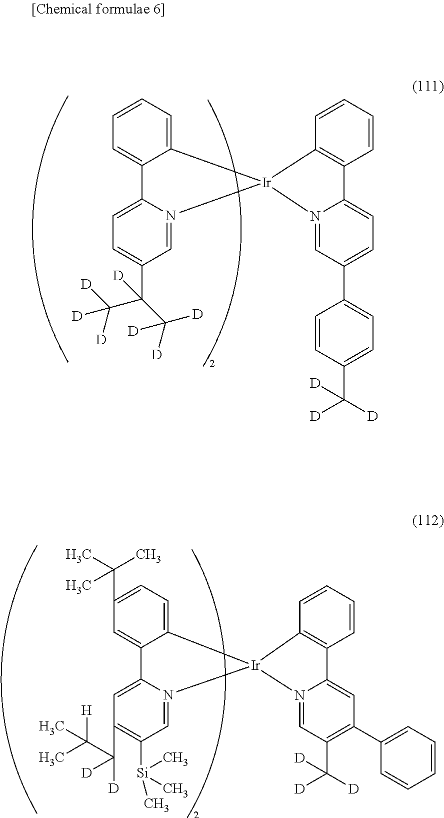

### [Example 9 of Energy Donor Material ED]

An organic compound having a function of emitting delayed fluorescent light at room temperature can be used as the energy donor material ED. For example, a substance exhibiting thermally activated delayed fluorescence can be used as the energy donor material ED. The TADF material has a function of emitting delayed fluorescent light at room temperature, and its emission spectrum overlaps with the absorption spectrum of the light-emitting material FM.

The emission spectrum of the TADF material has the shortest-wavelength edge at the wavelength λp (nm), and the wavelength λp is positioned at a wavelength shorter than the wavelength λabs (see FIG. 1C). Note that the wavelength λp (nm) can be calculated as a wavelength at the intersection of the horizontal axis and a tangent to the wavelength in the shortest wavelength range at the point where the slope of the tangent of the emission spectrum has a maximum value. That is, the wavelength λp (nm) corresponds to the rising (onset) on the shorter wavelength side of the emission spectrum.

The relationship between the wavelength λp (nm) and the wavelength λabs (nm) preferably satisfies Formula (2) shown below. Thus, the absorption band of the light-emitting material FM that is positioned in the longest wavelength range overlaps better with the emission spectrum of the TADF material.

$$\begin{matrix}[ Formula 4 ] & \\ 0.05 < 1240 \times ( \frac{1}{{λ}_{p}} - \frac{1}{{λ}_{abs}} ) \leq 0.3 & ( 2 )\end{matrix}$$

The relationship between the wavelength λp (nm) and the wavelength λf (nm) preferably satisfies Formula (3) shown below. Thus, the absorption band of the light-emitting material FM that is positioned in the longest wavelength range overlaps better with the emission spectrum of the TADF material.

$$\begin{matrix}[ Formula 5 ] & \\ 0 \leq 1240 \times ( \frac{1}{{λ}_{p}} - \frac{1}{{λ}_{f}} ) \leq 0.1 & ( 3 )\end{matrix}$$

For example, the TADF material can be used as the energy donor material ED. The TADF material has a substituent R¹. The substituent R¹ is any of an alkyl group, a cycloalkyl group, and a trialkylsilyl group.

Note that when the substituent R¹ is an alkyl group, the number of carbon atoms of the alkyl group is 3 to 12; when the substituent R¹ is a cycloalkyl group, the number of carbon atoms forming a ring of the cycloalkyl group is 3 to 10; and when the substituent R¹ is a trialkylsilyl group, the number of carbon atoms of the trialkylsilyl group is 3 to 12.

The substituent R¹ can include, for example, deuterium instead of hydrogen. This can inhibit release of hydrogen. Alternatively, the reliability of the light-emitting device can be increased.

The TADF material has the first HOMO level HOMO1 and the first LUMO level LUMO1 (see FIG. 1B).

### [Example 1 of Host Material]

The host material has a function of emitting delayed fluorescent light at room temperature. Note that a first material can be used as the host material. The host material is contained in the light-emitting layer at a higher weight percentage than at least the light-emitting material and is preferably contained in the light-emitting layer at the highest weight percentage. For example, a substance exhibiting thermally activated delayed fluorescence can be used as the host material. Specifically, any of the TADF materials given below can be used as the host material. Note that without being limited thereto, a variety of known TADF materials can be used as the host material.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used for the TADF material.

Specifically, any of the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

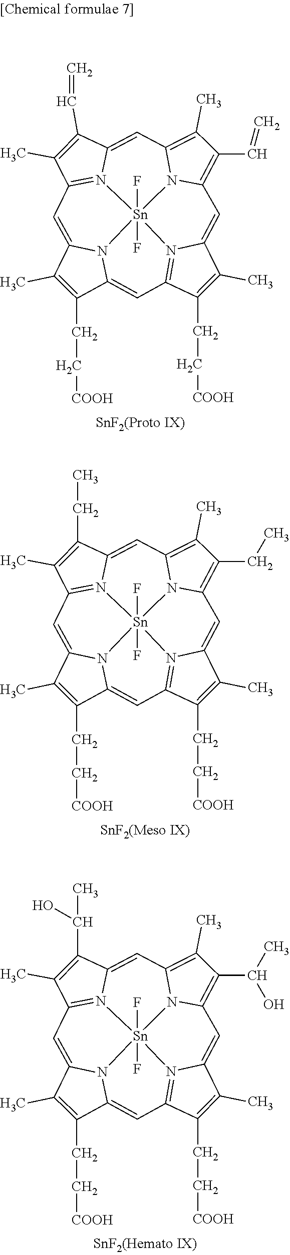

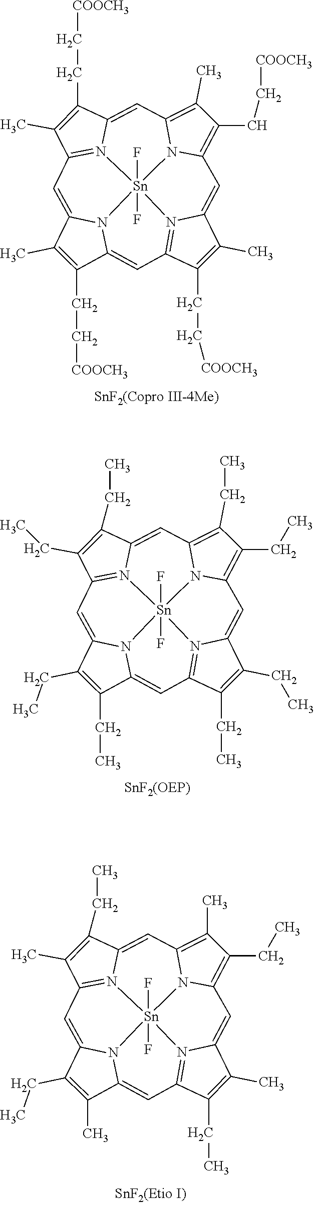

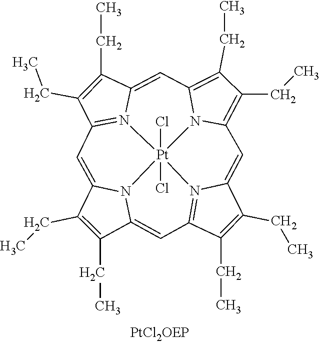

Furthermore, a heterocyclic compound including one or both of a 7t-electron rich heteroaromatic ring and a π-electron deficient heteroaromatic ring can be used, for example, for the TADF material.

Specifically, any of the following materials whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

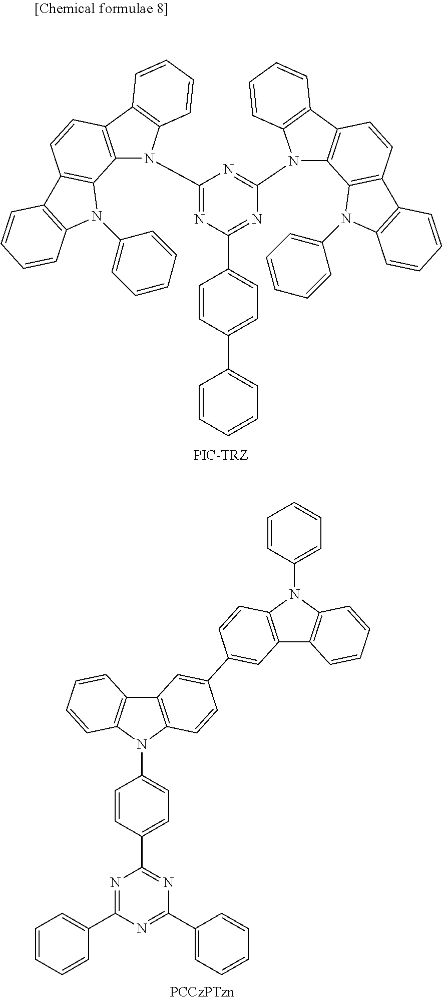 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

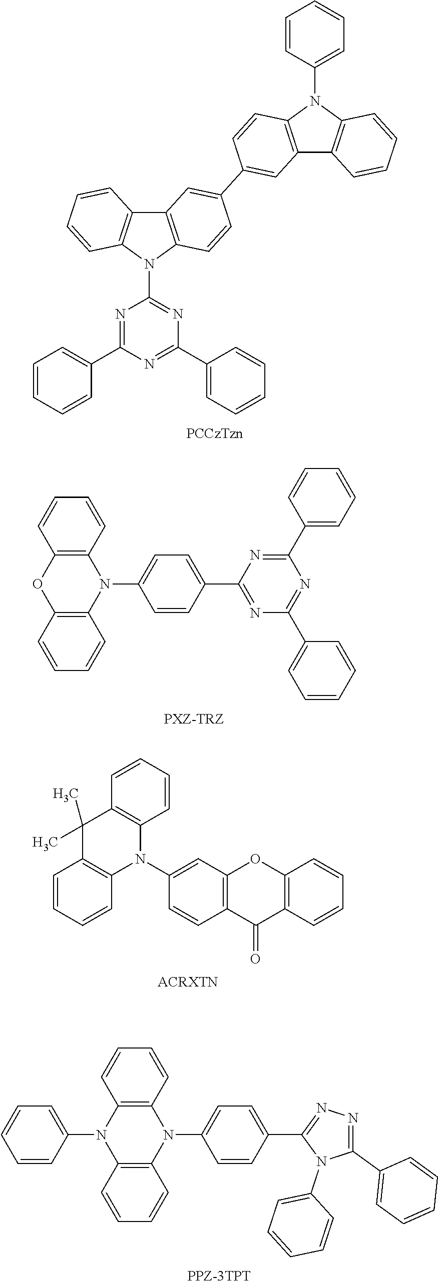 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1]

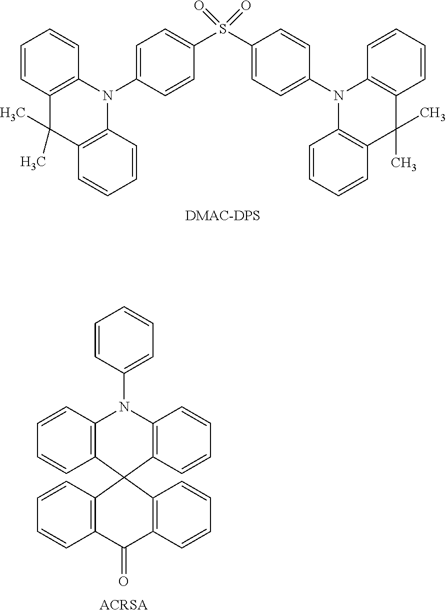 [SMILES: CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Such a heterocyclic compound is preferable because of having excellent electron-transport property and hole-transport property owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor property and favorable reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. In particular, as a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferable because the electron-donating property of the π-electron rich heteroaromatic ring and the electron-acceptor property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used.

As described above, a π-electron deficient skeleton and a π-electron rich skeleton can be used instead of at least one of the π-electron deficient heteroaromatic ring and the π-electron rich heteroaromatic ring.

### [Example 2 of Host Material]

A material in which a plurality of kinds of substances are mixed can be used as the host material. In other words, a material in which a plurality of kinds of substances are mixed can be used as the first material. For example, a mixed material that is formed of a mixture of a substance A and a substance B and in which the substance A and the substance B form an exciplex can be used as the host material. Preferably, a mixed material of a material having a hole-transport property and a material having an electron-transport property can be used as the host material. Note that the weight ratio between the material having a hole-transport property and the material having an electron-transport property contained in the mixed material is set to (the material having a hole-transport property/the material having an electron-transport property)=(1/19) or more and (19/1) or less. Accordingly, the carrier-transport property of the layer 111 can be easily adjusted. In addition, a recombination region can be controlled easily.

The HOMO level of the material having a hole-transport property is preferably higher than or equal to the HOMO level of the material having an electron-transport property. Alternatively, the LUMO level of the material having a hole-transport property is preferably higher than or equal to the LUMO level of the material having an electron-transport property. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the material having a hole-transport property and the material having an electron-transport property are mixed is shifted to a longer wavelength side than the emission spectrum of each of the materials (or has another peak on the longer wavelength side) observed in comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed in comparison of transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed in comparison of the transient EL of the material having a hole-transport property, the transient EL of the material having an electron-transport property, and the transient EL of the mixed film of these materials.

### [Example 3 of Host Material]

The first material of the host material has a second HOMO level HOMO2 and a second LUMO level LUMO2. Note that in the case where a mixed material of a plurality of substances is used as the host material, with the HOMO levels of the plurality of materials compared with each other, the highest HOMO level can be used as the second HOMO level HOMO2. In addition, with the LUMO levels of the plurality of materials compared with each other, the lowest LUMO level can be used as the second LUMO level LUMO2.

The first HOMO level HOMO1, the first LUMO level LUMO1, the second HOMO level HOMO2 and the second LUMO level LUMO2 satisfy the following formula (1).

[Formula 6]

(LUMO2−HOMO2)<(LUMO1−HOMO1) (1)

Accordingly, the organometallic complex or the TADF material can be used as the energy donor material ED to allow the transfer of the energy, particularly triplet excitation energy, of the energy donor material ED to the light-emitting material FM. The substituent R¹ is interposed between the energy donor material ED and the light-emitting material FM that is close to the energy donor material ED. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased.

Triplet excitons generated in the host material can be converted into singlet excitons. The difference between the HOMO level and the LUMO level derived from the host material can be smaller than the difference between the HOMO level and the LUMO level derived from the energy donor material ED, so that the number of carriers moving in the host material can be increased. The recombination probability of carriers in the host material can be increased. Energy can be transferred from excitons generated in the host material to the energy donor material ED. Excitons can be generated in the host material, and the energy of the excitons can be transferred to the light-emitting material FM through the energy donor material ED. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

### [Example 4 of Host Material]

The second HOMO level HOMO2 of the host material is higher than the first HOMO level HOMO1 of the energy donor material ED (see FIG. 1B). The second LUMO level LUMO2 of the host material is lower than the first LUMO level LUMO1 of the energy donor material ED.

Thus, the number of carriers moving in the host material can be increased. The recombination probability of carriers in the host material can be increased. Energy can be transferred from excitons generated in the host material to the energy donor material ED. Excitons can be generated in the host material, and the energy of the excitons can be transferred to the light-emitting material FM through the energy donor material ED. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

### [Example 4 of Light-Emitting Material FM]

The light-emitting material FM that can be preferably used for the light-emitting device of one embodiment of the present invention has at least one substituent R².

The substituent R² is selected from a methyl group, a branched alkyl group, a substituted or unsubstituted cycloalkyl group, and a trialkylsilyl group. When the substituent R² is a branched alkyl group, the number of carbon atoms of the branched alkyl group is 3 to 12; when the substituent R² is a cycloalkyl group, the number of carbon atoms forming a ring of the cycloalkyl group is 3 to 10; and when the substituent R² is a trialkylsilyl group, the number of carbon atoms of the trialkylsilyl group is 3 to 12.

Examples of a secondary or tertiary alkyl group having 3 to 12 carbon atoms include branched-chain alkyl groups such as an isopropyl group and a tert-butyl group. The branched-chain alkyl group is not limited thereto. Examples of a cycloalkyl group having 3 to 10, inclusive, carbon atoms include a cyclopropyl group, a cyclobutyl group, a cyclohexyl group, a norbomyl group, and an adamantyl group. The cycloalkyl group is not limited thereto. In the case where the cycloalkyl group has a substituent, examples of the substituent include an alkyl group having 1 to 7 carbon atoms, such as a methyl group, an isopropyl group, or a tert-butyl group, a cycloalkyl group having 5 to 7 carbon atoms, such as a cyclopentyl group, a cyclohexyl group, a cycloheptyl group, or a 8,9,10-trinorbomanyl group, and an aryl group having 6 to 12 carbon atoms, such as a phenyl group, a naphthyl group, or a biphenyl group. Examples of a trialkylsilyl group having 3 to 12 carbon atoms include a trimethylsilyl group, a triethylsilyl group, and a tert-butyl dimethylsilyl group. The trialkylsilyl group is not limited thereto.

When the substituent R² is a branched alkyl group, for example, a secondary alkyl group or a tertiary alkyl group can be used as the substituent R². Specifically, as the substituent R², an alkyl group in which carbon bonded to the mother skeleton is branched can be used. Accordingly, the number of α-hydrogen atoms can be reduced. In addition, the reliability of the light-emitting device can be increased.

When the substituent R² is a branched alkyl group, for example, an alkyl group having 3 or 4 carbon atoms can be used as the substituent R².

When the substituent R² is a cycloalkyl alkyl group, for example, a cycloalkyl group having 3 to 6 carbon atoms can be used as the substituent R².

When the substituent R² is a trialkylsilyl alkyl group, for example, a trimethylsilyl group can be used as the substituent R².

Thus, the substituent R² is interposed between the light-emitting material FM and the energy donor material ED that is close to the light-emitting material FM. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

The substituent R² can include, for example, deuterium instead of hydrogen. This can inhibit release of hydrogen. Alternatively, the reliability of the light-emitting device can be increased.

### [Example 5 of Light-Emitting Material FM]

The light-emitting material FM that can be used for the light-emitting device of one embodiment of the present invention has a condensed aromatic ring or a condensed heteroaromatic ring and five or more substituents R².

The condensed aromatic ring or the condensed heteroaromatic ring includes 3 to 10 rings. The five or more substituents R² each independently include a branched alkyl group, a substituted or unsubstituted cycloalkyl group, or a trialkylsilyl group. In other words, the five or more substituents R² are groups other than a methyl group. When the substituent R² is a branched alkyl group, the number of carbon atoms of the branched alkyl group is 3 to 12; when the substituent R² is a cycloalkyl group, the number of carbon atoms forming a ring of the cycloalkyl group is 3 to 10; and when the substituent R² is a trialkylsilyl group, the number of carbon atoms of the trialkylsilyl group is 3 to 12.

### [Example 6 of Light-Emitting Material FM]

The light-emitting material FM that can be used for the light-emitting device of one embodiment of the present invention has a condensed aromatic ring or a condensed heteroaromatic ring and three or more substituents R².

The condensed aromatic ring or the condensed heteroaromatic ring includes 3 to 10 rings. The three or more substituents R² are not directly bonded to the condensed aromatic ring or the condensed heteroaromatic ring. The three or more substituents R² each independently include an alkyl group, a substituted or unsubstituted cycloalkyl group, or a trialkylsilyl group. When the substituent R² is an alkyl group, the number of carbon atoms of the alkyl group is 3 to 12; when the substituent R² is a cycloalkyl group, the number of carbon atoms forming a ring of the cycloalkyl group is 3 to 10; and when the substituent R² is a trialkylsilyl group, the number of carbon atoms of the trialkylsilyl group is 3 to 12.

### [Example 7 of Light-Emitting Material FM]

The light-emitting material FM that can be used for the light-emitting device of one embodiment of the present invention has a condensed aromatic ring or a condensed heteroaromatic ring and a diarylamino group.

The condensed aromatic ring or the condensed heteroaromatic ring includes 3 to 10 rings. A nitrogen atom of the diarylamino group is bonded to the condensed aromatic ring or the condensed heteroaromatic ring, and an aryl group of the diarylamino group is bonded to the substituent R².

### [Example 8 of Light-Emitting Material FM]

For example, an organic compound represented by General formula (G1) shown below can be used as the light-emitting material FM.

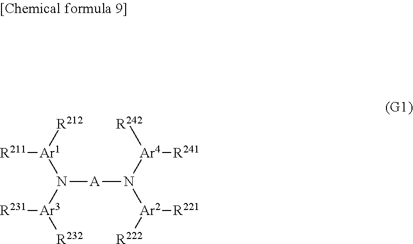

In the above general formula, A is a t-conjugated system, and for example, a condensed aromatic ring or a condensed heteroaromatic ring can be used for A. Specifically, a condensed aromatic ring including 3 to 10 rings or a condensed heteroaromatic ring including 3 to 10 rings can be used for A.

Furthermore, R²¹¹ to R²⁴² are each hydrogen or a substituent and include any one or more of a branched alkyl group, a substituted or unsubstituted cycloalkyl group, and a trialkylsilyl group. Note that the branched alkyl group is preferably a secondary or tertiary alkyl group having 3 to 12 carbon atoms, the cycloalkyl group preferably has 3 to 10 carbon atoms and the trialkylsilyl group preferably has 3 to 12 carbon atoms. In other words, the above substituent R² is included in R²¹¹ to R²⁴².

Furthermore, N is a nitrogen atom and Ar¹ to Ar⁴ are aryl groups. In other words, the light-emitting material FM includes a diarylamino group. A nitrogen atom of the diarylamino group is bonded to A, and an aryl group of the diarylamino group is bonded to the substituent R². Note that the light-emitting material FM preferably includes two or more diarylamino groups.

[Example 9 of light-emitting material FM]

For example, an organic compound represented by General formula (G2) or General formula (G3) shown below can be used as the light-emitting material FM.

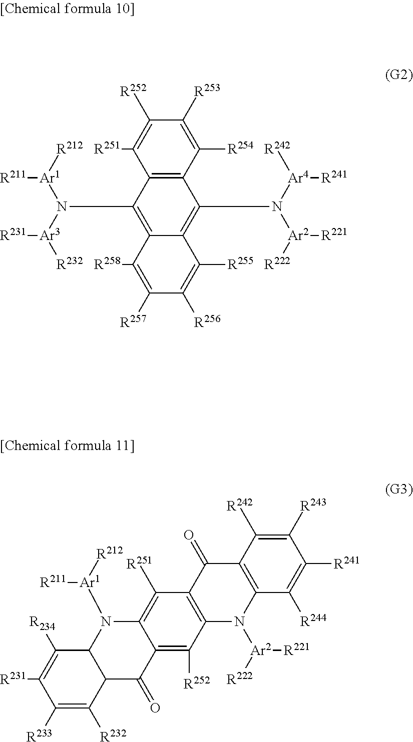

In the above general formulae, R²¹¹ to R²⁵⁸ are each hydrogen or a substituent and include any one or more of a branched alkyl group, a substituted or unsubstituted cycloalkyl group, and a trialkylsilyl group. Note that the branched alkyl group is preferably a secondary or tertiary alkyl group having 3 to 12 carbon atoms, the cycloalkyl group preferably has 3 to 10 carbon atoms, and the trialkylsilyl group preferably has 3 to 12 carbon atoms. In other words, the above substituent R² is included in R²¹¹ to R²⁵⁸

### [Example 10 of Light-Emitting Material FM]

For example, an organic compound represented by General formula (G4) or General formula (G5) shown below can be used as the light-emitting material FM.

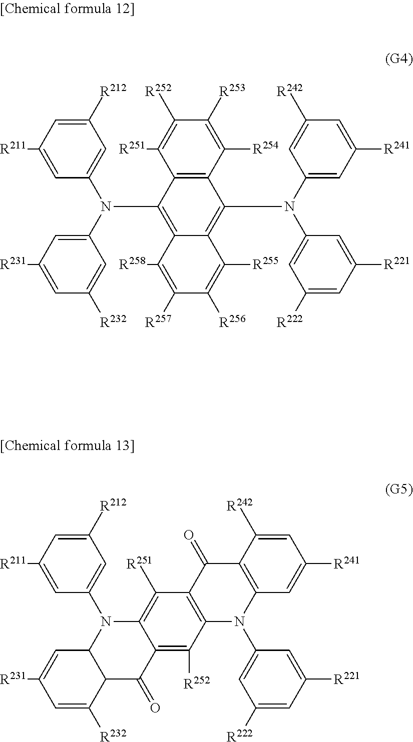

In the above general formulae, R²¹¹ to R²⁵⁸ are each hydrogen or a substituent and include any one or more of a branched alkyl group, a substituted or unsubstituted cycloalkyl group, and a trialkylsilyl group. Note that the branched alkyl group is preferably a secondary or tertiary alkyl group having 3 to 12 carbon atoms, the cycloalkyl group preferably has 3 to 10 carbon atoms, and the trialkylsilyl group preferably has 3 to 12 carbon atoms. In other words, the above substituent R² is included in R²¹¹ to R²⁵⁸, and the substituent R² is bonded to the carbon atom in the meta-position of a benzene ring bonded to the nitrogen atom in the diarylamino group.

Thus, the organometallic complex can be used as the energy donor material ED to allow the transfer of the energy, particularly triplet excitation energy, of the energy donor material ED to the light-emitting material FM. The first substituent R¹ and the second substituent R² are interposed between the energy donor material ED and the light-emitting material FM that is close to the energy donor material ED. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. The concentration of the light-emitting material FM can be increased. Consequently, a novel light-emitting device that is highly convenient, useful, or reliable can be provided.

Specific examples of the organic compounds with the above structures are shown below.

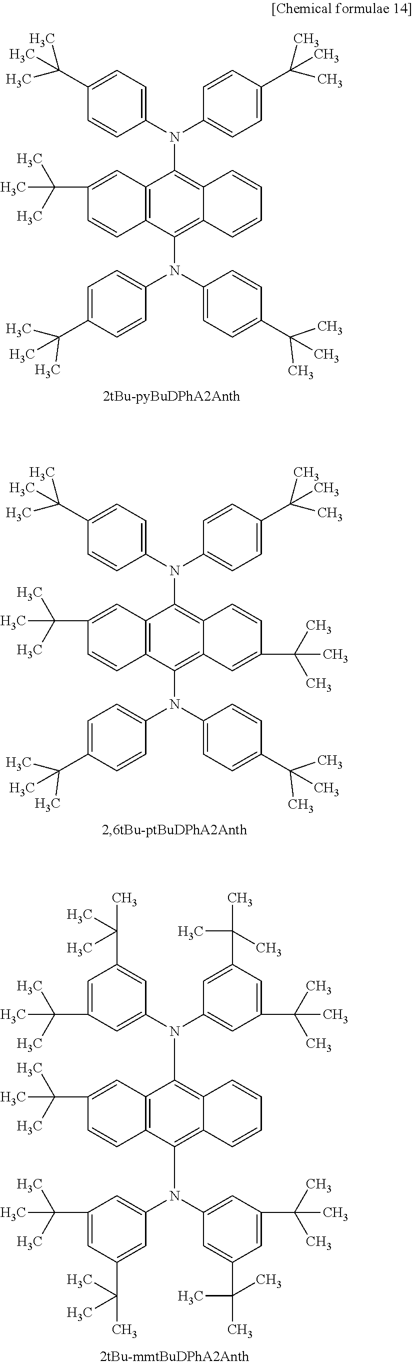

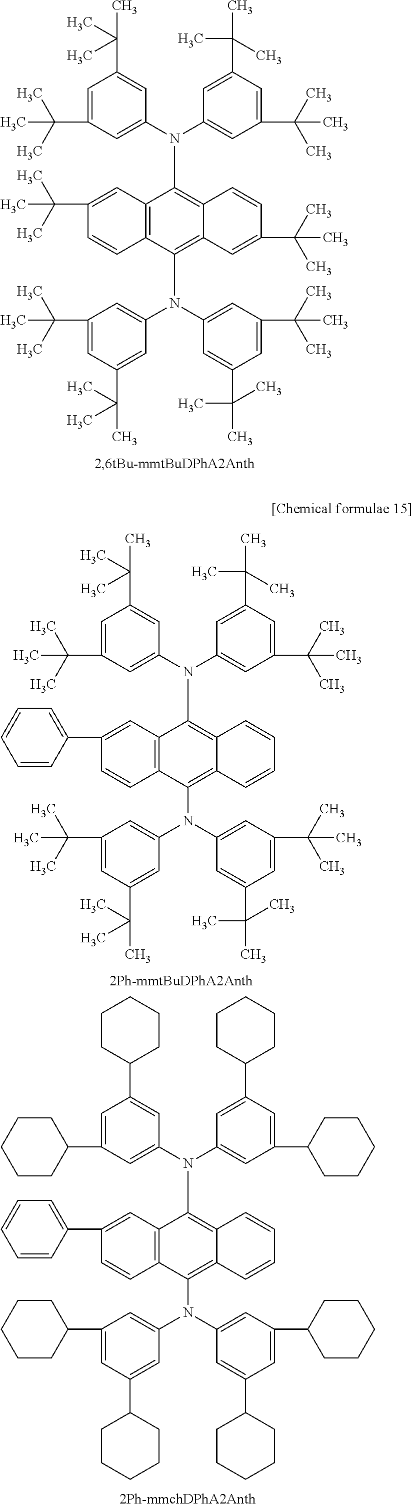

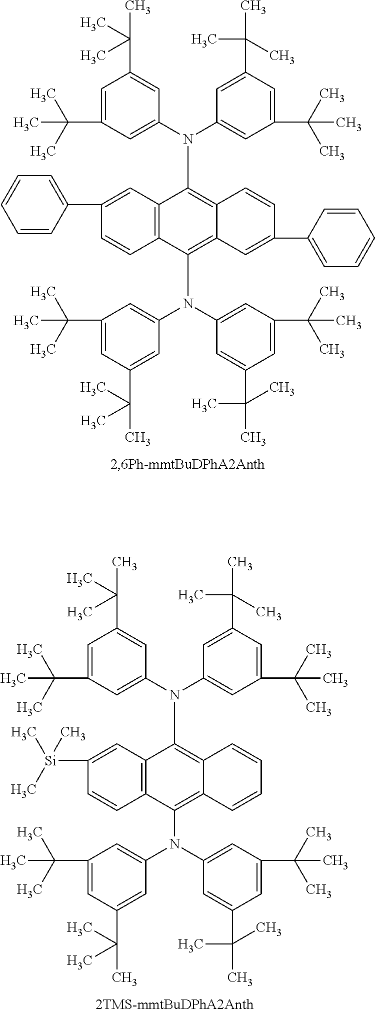 [SMILES: CC(C)(C)c1cc(N(c2cc(C(C)(C)C)cc(C(C)(C)C)c2)c2c3ccc(-c4ccccc4)cc3c(N(c3cc(C(C)(C)C)cc(C(C)(C)C)c3)c3cc(C(C)(C)C)cc(C(C)(C)C)c3)c3ccc(-c4ccccc4)cc23)cc(C(C)(C)C)c1 ; CC(C)(C)c1cc(N(c2cc(C(C)(C)C)cc(C(C)(C)C)c2)c2c3ccccc3c(N(c3cc(C(C)(C)C)cc(C(C)(C)C)c3)c3cc(C(C)(C)C)cc(C(C)(C)C)c3)c3cc([Si](C)(C)C)ccc23)cc(C(C)(C)C)c1]

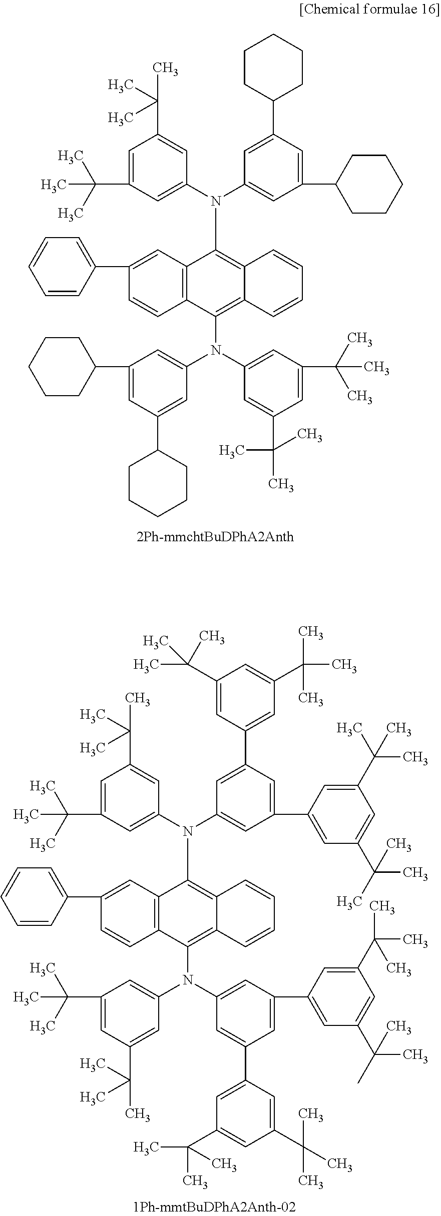 [SMILES: CC(C)(C)c1cc(N(c2cc(C3CCCCC3)cc(C3CCCCC3)c2)c2c3ccccc3c(N(c3cc(C4CCCCC4)cc(C4CCCCC4)c3)c3cc(C(C)(C)C)cc(C(C)(C)C)c3)c3cc(-c4ccccc4)ccc23)cc(C(C)(C)C)c1 ; CC(C)(C)c1cc(-c2cc(-c3cc(C(C)(C)C)cc(C(C)(C)C)c3)cc(N(c3cc(C(C)(C)C)cc(C(C)(C)C)c3)c3c4ccccc4c(N(c4cc(-c5cc(C(C)(C)C)cc(C(C)(C)C)c5)cc(-c5cc(C(C)(C)C)cc(C(C)(C)C)c5)c4)c4cc(C(C)(C)C)cc(C(C)(C)C)c4)c4cc(-c5ccccc5)ccc34)c2)cc(C(C)(C)C)c1]

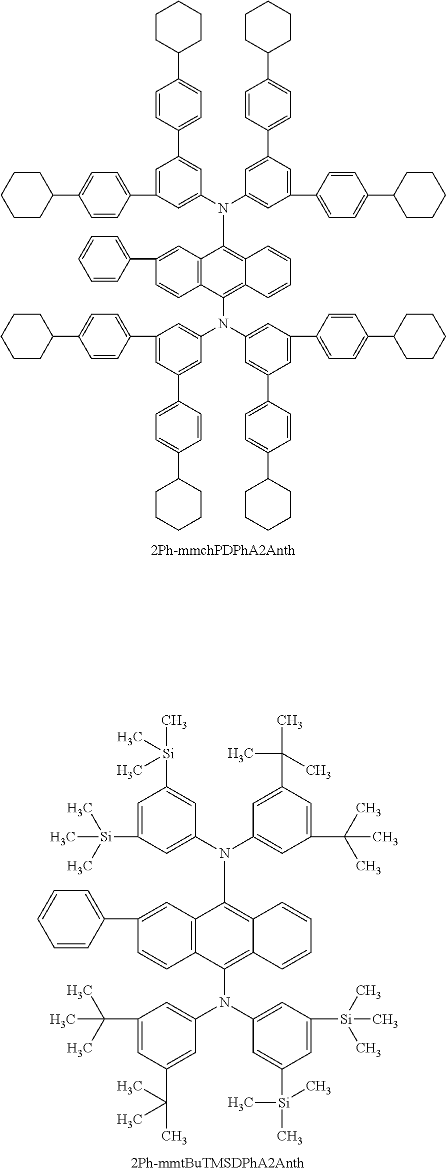 [SMILES: c1ccc(-c2ccc3c(N(c4cc(-c5ccc(C6CCCCC6)cc5)cc(-c5ccc(C6CCCCC6)cc5)c4)c4cc(-c5ccc(C6CCCCC6)cc5)cc(-c5ccc(C6CCCCC6)cc5)c4)c4ccccc4c(N(c4cc(-c5ccc(C6CCCCC6)cc5)cc(-c5ccc(C6CCCCC6)cc5)c4)c4cc(-c5ccc(C6CCCCC6)cc5)cc(-c5ccc(C6CCCCC6)cc5)c4)c3c2)cc1 ; CC(C)(C)c1cc(N(c2cc([Si](C)(C)C)cc([Si](C)(C)C)c2)c2c3ccccc3c(N(c3cc(C(C)(C)C)cc(C(C)(C)C)c3)c3cc([Si](C)(C)C)cc([Si](C)(C)C)c3)c3cc(-c4ccccc4)ccc23)cc(C(C)(C)C)c1]

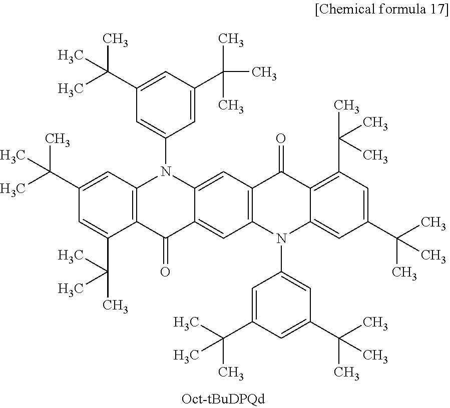 [SMILES: CC(C)(C)c1cc(-n2c3cc4c(=O)c5c(C(C)(C)C)cc(C(C)(C)C)cc5n(-c5cc(C(C)(C)C)cc(C(C)(C)C)c5)c4cc3c(=O)c3c(C(C)(C)C)cc(C(C)(C)C)cc32)cc(C(C)(C)C)c1]

### [Example 10 of Light-Emitting Material FM]

The light-emitting material FM has a third LUMO level LUMO3 (see FIG. 1B). The third LUMO level LUMO3 is higher than the second LUMO level LUMO2 of the host material.

In this case, electrons can be inhibited from being captured by the light-emitting material FM. The recombination probability of carriers in the light-emitting material FM can be reduced. A phenomenon in which the light-emitting material FM in a triplet excited state is generated owing to recombination of carriers in the light-emitting material FM can be inhibited. Excitons can be generated in the host material, and the energy of the excitons can be transferred to the light-emitting material FM through the energy donor material ED. The probability of generating the singlet excited state of the light-emitting material FM can be increased. The emission efficiency can be increased. Consequently, a novel light-emitting device that is highly convenient, useful, or reliable can be provided.

### <<Structure Example 2 of Layer 111>>

The layer 111 contains the light-emitting material FM, the energy donor material ED, and the host material. Note that a difference from Structure example 1 of layer 111 is that the layer 111 includes a carrier trap state.

### [Example 2 of Energy Donor Material ED]

The first HOMO level HOMO1 of the energy donor material ED is higher than the second HOMO level HOMO2 of the host material (see FIG. 2A).

Accordingly, the energy donor material ED can capture holes easily. The recombination probability of carriers in the energy donor material ED can be increased. The organometallic complex or the TADF material can be used as the energy donor material ED to allow the transfer of the energy, particularly triplet excitation energy, of the energy donor material ED to the light-emitting material FM. The substituent R¹ is interposed between the energy donor material ED and the light-emitting material FM that is close to the energy donor material ED. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

### [Example 3 of Energy Donor Material ED]

The first LUMO level LUMO1 of the energy donor material ED is lower than the second LUMO level LUMO2 of the host material (see FIG. 2B).

Accordingly, the energy donor material ED can capture holes easily. Furthermore, the recombination probability of carriers in the energy donor material ED can be increased. The organometallic complex or the TADF material can be used as the energy donor material ED to allow the transfer of the energy, particularly triplet excitation energy, of the energy donor material ED to the light-emitting material FM. The substituent R¹ is interposed between the energy donor material ED and the light-emitting material FM that is close to the energy donor material ED. The center distance between the energy donor material ED and the light-emitting material FM that is close to the energy donor material ED can be set suitable. Energy transfer by the Dexter mechanism can be inhibited. Energy transfer by the Forster mechanism can be dominant. The light-emitting material FM can be brought into a singlet excited state. The probability of generating the singlet excited state of the light-emitting material FM can be increased. The emission efficiency can be increased. Consequently, a novel light-emitting device that is highly convenient, useful, or reliable can be provided.

Note that this embodiment can be combined with any of the other embodiments described in this specification as appropriate.

### Embodiment 2

In this embodiment, the structure of the light-emitting device 150 of one embodiment of the present invention is described with reference to FIG. 1 and FIG. 2.

### <Structure Example of Light-Emitting Device 150>

The light-emitting device 150 described in this embodiment includes the electrode 101, the electrode 102, and the unit 103. The electrode 102 includes a region overlapping with the electrode 101, and the unit 103 includes a region interposed between the electrode 101 and the electrode 102.

### <Structure Example of Unit 103>>

The unit 103 has a single-layer structure or a stacked-layer structure. For example, the unit 103 includes the layer 111, the layer 112, and the layer 113 (see FIG. TA). The unit 103 has a function of emitting light EL1.

For example, a layer selected from functional layers such as a light-emitting layer, a hole-transport layer, an electron-transport layer, and a carrier-blocking layer can be used in the unit 103.

The layer 111 includes a region interposed between the layer 112 and the layer 113, the layer 112 includes a region interposed between the electrode 101 and the layer 111, and the layer 113 includes a region interposed between the electrode 102 and the layer 111. For example, the structure described in Embodiment 1 can be used for the layer 111.

### <<Structure Example of Layer 112>>

A material having a hole-transport property can be used for the layer 112, for example. The layer 112 can be referred to as a hole-transport layer. A material having a wider bandgap than the light-emitting material contained in the layer 111 is preferably used for the layer 112. Thus, transfer of energy from excitons generated in the layer 111 to the layer 112 can be inhibited.

### [Material Having Hole-Transport Property]

A material having a hole mobility of 1×10⁻⁶ cm²/Vs or higher can be suitably used as the material having a hole-transport property.

As the material having a hole-transport property, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. In particular, a compound having an aromatic amine skeleton and a compound having a carbazole skeleton are preferable because these have favorable reliability, have high hole-transport properties, and contribute to a reduction in driving voltage.

The following are examples that can be used as a compound having an aromatic amine skeleton: 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]spiro-9,9′-bifluoren-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), or the like can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), or the like can be used.

As a compound having a furan skeleton, for example, 4,4′,4″-(benzene-1,3,5-triyl)tri(dibenzofuran) (abbreviation: DBF3P-II), 4-{3-[3-(9-phenyl-9H-fluoren-9-yl)phenyl]phenyl}dibenzofuran (abbreviation: mmDBFFLBi-II), or the like can be used.

### <<Structure Example of Layer 113>>

For example, a material having an electron-transport property, a material having an anthracene skeleton, and a mixed material can be used for the layer 113. The layer 113 can be referred to as an electron-transport layer. A material having a wider band gap than the light-emitting material contained in the layer 111 is preferably used for the layer 113. Thus, energy transfer from excitons generated in the layer 111 to the layer 113 can be inhibited.

### [Material Having Electron-Transport Property]

For example, a metal complex or an organic compound having a π-electron deficient heteroaromatic ring skeleton can be used as the material having an electron-transport property.

A material having an electron mobility higher than or equal to 1×10⁻⁷ cm²/Vs and lower than or equal to 5×10⁻⁵ cm²/Vs in a condition where the square root of the electric field strength [V/cm] is 600 can be favorably used as the material having an electron-transport property. Thus, the electron-transport property in the electron-transport layer can be inhibited. Alternatively, the amount of electrons injected into the light-emitting layer can be controlled. Alternatively, the light-emitting layer can be prevented from having excess electrons.

As the metal complex, bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), or the like can be used, for example.

As the organic compound having a π-electron deficient heteroaromatic ring skeleton, a heterocyclic compound having a polyazole skeleton, a heterocyclic compound having a diazine skeleton, a heterocyclic compound having a pyridine skeleton, a heterocyclic compound having a triazine skeleton, or the like can be used, for example. In particular, the heterocyclic compound having a diazine skeleton or the heterocyclic compound having a pyridine skeleton has favorable reliability and thus is preferable. Furthermore, the heterocyclic compound having a diazine (pyrimidine or pyrazine) skeleton has a high electron-transport property and contributes to a reduction in driving voltage.

As the heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-TH-benzimidazole (abbreviation: mDBTBIm-II), or the like can be used, for example.

As the heterocyclic compound having a diazine skeleton, 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,8-bis[3-(dibenzothiophen-4-yl)phenyl]benzo[h]quinazoline (abbreviation: 4,8mDBtP2Bqn), or the like can be used, for example.

As the heterocyclic compound having a pyridine skeleton, 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), or the like can be used, for example.

As the heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), or the like can be used, for example.

### [Material Having Anthracene Skeleton]

An organic compound having an anthracene skeleton can be used for the layer 113. In particular, an organic compound having both an anthracene skeleton and a heterocyclic skeleton can be suitably used.

For example, an organic compound having both an anthracene skeleton and a nitrogen-containing five-membered ring skeleton can be used. Alternatively, an organic compound having both an anthracene skeleton and a nitrogen-containing five-membered ring skeleton where two heteroatoms are included in a ring can be used. Specifically, a pyrazole ring, an imidazole ring, an oxazole ring, a thiazole ring, or the like can be favorably used as the heterocyclic skeleton.

For example, an organic compound having both an anthracene skeleton and a nitrogen-containing six-membered ring skeleton can be used. Alternatively, an organic compound having both an anthracene skeleton and a nitrogen-containing six-membered ring skeleton where two heteroatoms are included in a ring can be used. Specifically, a pyrazine ring, a pyrimidine ring, a pyridazine ring, or the like can be favorably used as the heterocyclic skeleton.

### [Structure Example of Mixed Material]

A material in which a plurality of kinds of substances are mixed can be used for the layer 113. Specifically, a mixed material that contains a substance having an electron-transport property and any of an alkali metal, an alkali metal compound, and an alkali metal complex can be used for the layer 113. Note that it is further preferable that the HOMO level of the material having an electron-transport property be −6.0 eV or higher.

The mixed material can be suitably used for the layer 113 in combination with a structure using a composite material for a layer 104. For example, a composite material of a substance having an acceptor property and a material having a hole-transport property can be used for the layer 104. Specifically, a composite material of a substance having an acceptor property and a substance having a relatively deep HOMO level HMT, which is greater than or equal to −5.7 eV and lower than or equal to −5.4 eV, can be used for the layer 104 (see FIG. 2C). In particular, the mixed material can be suitably used for the layer 113 in combination with the structure using the composite material for the layer 104. As a result, the reliability of the light-emitting device can be increased.

Furthermore, a structure using a material having a hole-transport property for the layer 112 can be suitably combined with the structure using the mixed material for the layer 113 and the composite material for the layer 104. For example, a substance having a HOMO level HM2, which is within the range of −0.2 eV to 0 eV from the relatively deep HOMO level HMT, can be used for the layer 112 (see FIG. 2C). As a result, the reliability of the light-emitting device can be increased. Note that in this specification and the like, the structure of the above-described light-emitting device is referred to as a Recombination-Site Tailoring Injection structure (ReSTI structure) in some cases.

The concentration of the alkali metal, the alkali metal compound, or the alkali metal complex preferably differs in the thickness direction of the layer 113 (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

Note that this embodiment can be combined with any of the other embodiments described in this specification as appropriate.

### Embodiment 3

In this embodiment, the structure of the light-emitting device 150 of one embodiment of the present invention is described with reference to FIG. TA.

<Structure example of light-emitting device 150>

The light-emitting device 150 described in this embodiment includes the electrode 101, the electrode 102, the unit 103, and the layer 104. The electrode 102 includes a region overlapping with the electrode 101, and the unit 103 includes a region interposed between the electrode 101 and the electrode 102. The layer 104 includes a region interposed between the electrode 101 and the unit 103. For example, the structure described in Embodiment 2 can be used for the unit 103.

<Structure example of electrode 101>

For example, a conductive material can be used for the electrode 101. Specifically, a metal, an alloy, a conductive compound, a mixture of these, or the like can be used for the electrode 101. For example, a material having a work function higher than or equal to 4.0 eV can be suitably used.

For example, indium oxide-tin oxide (ITO: Indium Tin Oxide), indium oxide-tin oxide containing silicon or silicon oxide (ITSO), indium oxide-zinc oxide, indium oxide containing tungsten oxide and zinc oxide (IWZO), or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used. Alternatively, graphene can be used.

### <<Structure Example of Layer 104>>

For example, a material having a hole-injection property can be used for the layer 104. The layer 104 can be referred to as a hole-injection layer.

Specifically, a substance having an acceptor property can be used for the layer 104. Alternatively, a material in which a substance having an acceptor property and a material having a hole-transport property are combined can be used for the layer 104. This can facilitate injection of holes from the electrode 101, for example. Alternatively, the driving voltage of the light-emitting device can be lowered.

### [Substance Having Acceptor Property]

An organic compound and an inorganic compound can be used as the substance having an acceptor property. The substance having an acceptor property can extract electrons from an adjacent hole-transport layer or an adjacent material having a hole-transport property by the application of an electric field.

For example, a compound having an electron-withdrawing group (a halogen group or a cyano group) can be used as the substance having an acceptor property. Note that an organic compound having an acceptor property is easily evaporated and deposited. As a result, the productivity of the light-emitting device can be increased.

Specifically, it is possible to use, for example, 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile.

A compound in which electron-withdrawing groups are bonded to a condensed aromatic ring having a plurality of heteroatoms, such as HAT-CN, is particularly preferable because it is thermally stable.

Alternatively, a [3]radialene derivative having an electron-withdrawing group (in particular, a cyano group or a halogen group such as a fluoro group) is preferable because it has a very high electron-accepting property.

Specifically, it is possible to use, for example, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], or α,α′,α″-1,2,3-cyclopropanetriylidenetris[2,3,4,5,6-pentafluorobenzeneacetonitrile].

As the substance having an acceptor property, molybdenum oxide, vanadium oxide, ruthenium oxide, tungsten oxide, manganese oxide, or the like can be used.

Alternatively, it is possible to use phthalocyanine (abbreviation: H₂Pc), a phthalocyanine-based complex compound such as and copper phthalocyanine (CuPc), and compounds having an aromatic amine skeleton such as 4,4′-bis[N-(4-diphenylaminophenyl)-N-phenylamino]biphenyl (abbreviation: DPAB) and N,N′-bis{4-[bis(3-methylphenyl)amino]phenyl}-N,N′-diphenyl-(1,1′-biphenyl)-4,4′-diamine (abbreviation: DNTPD).

Alternatively, a high molecular compound such as poly(3,4-ethylenedioxythiophene)/poly(styrenesulfonic acid) (PEDOT/PSS), or the like can be used.

[Structure example 1 of composite material]A material in which a plurality of kinds of substances are combined can be used as the material having a hole-injection property. For example, a substance having an acceptor property and a material having a hole-transport property can be used for the composite material. Thus, besides a material having a high work function, a material having a low work function can also be used for the electrode 101. Alternatively, a material used for the electrode 101 can be selected from a wide range of materials regardless of its work function.

As the material having a hole-transport property in the composite material, for example, a compound having an aromatic amine skeleton, a carbazole derivative, an aromatic hydrocarbon, an aromatic hydrocarbon having a vinyl group, a high molecular compound (such as an oligomer, a dendrimer, or a polymer), or the like can be used. A material having a hole mobility of 1×10⁻⁶ cm²/Vs or higher can be suitably used as the material having a hole-transport property in the composite material.

A substance having a relatively deep HOMO level can be suitably used as the material having a hole-transport property in the composite material. Specifically, the HOMO level is preferably higher than or equal to −5.7 eV and lower than or equal to −5.4 eV, in which case hole injection to the unit 103 can be facilitated. Alternatively, hole injection to the layer 112 can be facilitated. Alternatively, the reliability of the light-emitting device can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), or the like can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), 1,4-bis[4-(N-carbazolyl)phenyl]-2,3,5,6-tetraphenylbenzene, or the like can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, coronene, or the like can be used.

As the aromatic hydrocarbon having a vinyl group, for example, 4,4′-bis(2,2-diphenylvinyl)biphenyl (abbreviation: DPVBi), 9,10-bis[4-(2,2-diphenylvinyl)phenyl]anthracene (abbreviation: DPVPA), or the like can be used.

As the high molecular compound, for example, poly(N-vinylcarbazole) (abbreviation: PVK), poly(4-vinyltriphenylamine) (abbreviation: PVTPA), poly[N-(4-{NV-[4-(4-diphenylamino)phenyl]phenyl-N-phenylamino}phenyl)methacrylamide] (abbreviation: PTPDMA), poly[N,N′-bis(4-butylphenyl)-N,N′-bis(phenyl)benzidine] (abbreviation: Poly-TPD), or the like can be used.

As another example, a substance having any of a carbazole skeleton, a dibenzofuran skeleton, a dibenzothiophene skeleton, and an anthracene skeleton can be favorably used as the material having a hole-transport property in the composite material. Moreover, as the material having a hole-transport property in the composite material, it is possible to use a substance including any of an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With the use of a substance including an N,N′-bis(4-biphenyl)amino group, the reliability of the light-emitting device can be increased.

Examples of the above-described substances include N-(4-biphenyl)-6,N-diphenylbenzo[b]naphtho[1,2-d]furan-8-amine (abbreviation: BnfABP), N,N′-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N′-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N′-bis(4-biphenyl)benzo[b]naphtho[2,3-d]furan-4-amine (abbreviation: BBABnf(II) (4)), N,N′-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBi3NB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl)-4-yl)-9,9′-spirobi[9H-fluoren]-2-amine (abbreviation: BBASF), N,N′-bis([1,1′-biphenyl]-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N′-bis(9,9-dimethyl-9H-fluoren-2-yl)-9,9′-spirobi-9H-fluoren-4-amine, N,N′-bis(9,9-dimethyl-9H-fluoren-2-yl)-9,9′-spirobi-9H-fluoren-3-amine, N,N′-bis(9,9-dimethyl-9H-fluoren-2-yl)-9,9′-spirobi-9H-fluoren-2-amine, and N,N′-bis(9,9-dimethyl-9H-fluoren-2-yl)-9,9′-spirobi-9H-fluoren-1-amine.

### [Structure Example 2 of Composite Material]

For example, a composite material including a material having an acceptor property, a material having a hole-transport property, and a fluoride of an alkali metal or a fluoride of an alkaline earth metal can be used as the material having a hole-injection property. In particular, a composite material in which the proportion of fluorine atoms is higher than or equal to 20% can be favorably used. Thus, the refractive index of the layer 111 can be reduced. Alternatively, a layer with a low refractive index can be formed inside the light-emitting device. Alternatively, the external quantum efficiency of the light-emitting device can be improved

Note that this embodiment can be combined with any of the other embodiments described in this specification as appropriate.

### Embodiment 4

In this embodiment, the structure of the light-emitting device 150 of one embodiment of the present invention is described with reference to FIG. TA.

### <Structure Example of Light-Emitting Device 150>

The light-emitting device 150 described in this embodiment includes the electrode 101, the electrode 102, the unit 103, and a layer 105. The electrode 102 includes a region overlapping with the electrode 101, and the unit 103 includes a region interposed between the electrode 101 and the electrode 102. The layer 105 includes a region interposed between the unit 103 and the electrode 102. For example, the structure described in Embodiment 2 can be used for the unit 103.

### <Structure Example of Electrode 102>

A conductive material can be used for the electrode 102, for example. Specifically, a metal, an alloy, a conductive compound, a mixture of these, or the like can be used for the electrode 102. For example, a material having a lower work function than the electrode 101 can be suitably used for the electrode 102. Specifically, a material having a work function lower than or equal to 3.8 eV is preferable.

For example, an element belonging to Group 1 of the periodic table, an element belonging to Group 2 of the periodic table, a rare earth metal, or an alloy containing any of these elements can be used for the electrode 102.

Specifically, lithium (Li), cesium (Cs), or the like; magnesium (Mg), calcium (Ca), strontium (Sr), or the like; europium (Eu), ytterbium (Yb), or the like; or an alloy containing any of these (MgAg or AlLi) can be used for the electrode 102.

### <<Structure Example of Layer 105>>

A material having an electron-injection property can be used for the layer 105, for example. The layer 105 can be referred to as an electron-injection layer.

Specifically, a substance having a donor property can be used for the layer 105. Alternatively, a material in which a substance having a donor property and a material having an electron-transport property are combined can be used for the layer 105. Alternatively, electride can be used for the layer 105. This can facilitate injection of electrons from the electrode 102, for example. Alternatively, besides a material having a low work function, a material having a high work function can also be used for the electrode 102. Alternatively, a material used for the electrode 102 can be selected from a wide range of materials regardless of its work function. Specifically, Al, Ag, ITO, indium oxide-tin oxide containing silicon or silicon oxide, or the like can be used for the electrode 102. Alternatively, the driving voltage of the light-emitting device can be lowered.

### [Substance Having Donor Property]

For example, an alkali metal, an alkaline earth metal, a rare earth metal, or a compound thereof (an oxide, a halide, a carbonate, or the like) can be used as the substance having a donor property. Alternatively, an organic compound such as tetrathianaphthacene (abbreviation: TTN), nickelocene, or decamethylnickelocene can be used as the substance having a donor property.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example 1 of Composite Material]

A material in which a plurality of kinds of substances are combined can be used as the material having an electron-injection property. For example, a substance having a donor property and a material having an electron-transport property can be used for the composite material.

For example, a metal complex or an organic compound having a π-electron deficient heteroaromatic ring skeleton can be used as the material having an electron-transport property for the composite material. For example, a material having an electron-transport property usable for the unit 103 can be used for the composite material.

### [Structure Example 2 of Composite Material]

A material including a fluoride of an alkali metal in a microcrystalline state and a material having an electron-transport property can be used for the composite material. Alternatively, a material including a fluoride of an alkaline earth metal in a microcrystalline state and a material having an electron-transport property can be used for the composite material. In particular, a composite material including a fluoride of an alkali metal or a fluoride of an alkaline earth metal at 50 wt % or higher can be suitably used. Alternatively, a composite material including an organic compound having a bipyridine skeleton can be suitably used. Thus, the refractive index of the layer 104 can be reduced. Alternatively, the external quantum efficiency of the light-emitting device can be improved.

### [Electride]

For example, a substance obtained by adding electrons at high concentration to an oxide where calcium and aluminum are mixed, or the like can be used as the material having an electron-injection property.

Note that this embodiment can be combined with any of the other embodiments described in this specification as appropriate.

### Embodiment 5

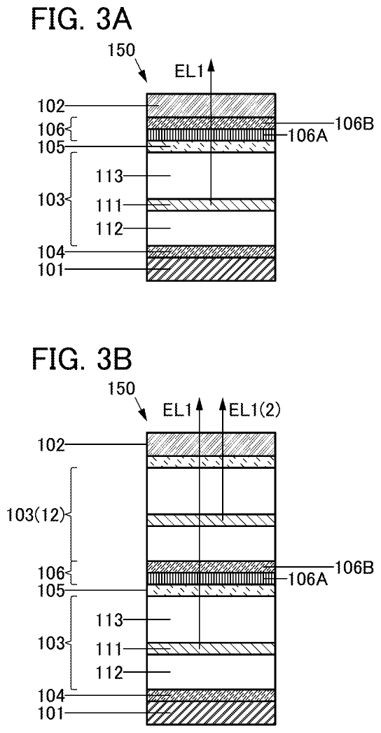

In this embodiment, the structure of the light-emitting device 150 of one embodiment of the present invention is described with reference to FIG. 3A.

FIG. 3A is a cross-sectional view illustrating a structure of the light-emitting device of one embodiment of the present invention.

### <Structure Example of Light-Emitting Device 150>

The light-emitting device 150 described in this embodiment includes the electrode 101, the electrode 102, the unit 103, and an intermediate layer 106 (see FIG. 3A). The electrode 102 includes a region overlapping with the electrode 101, and the unit 103 includes a region interposed between the electrode 101 and the electrode 102. The intermediate layer 106 includes a region interposed between the unit 103 and the electrode 102.

### <Structure Example of Intermediate Layer 106>>

The intermediate layer 106 includes a layer 106A and a layer 106B. The layer 106B includes a region interposed between the layer 106A and the electrode 102.

### <<Structure Example of Layer 106A>>

For example, a material having an electron-transport property can be used for the layer 106A. The layer 106A can be referred to as an electron-relay layer. With the use of the layer 106A, a layer that is in contact with the anode side of the layer 106A can be distanced from a layer that is in contact with the cathode side of the layer 106A. It is possible to reduce interaction between the layer in contact with the anode side of the layer 106A and the layer in contact with the cathode side of the layer 106A. Electrons can be smoothly supplied to the layer in contact with the anode side of the layer 106A.

A substance whose LUMO level is positioned between the LUMO level of the substance having an acceptor property included in the layer in contact with the anode side of the layer 106A and the LUMO level of the substance included in the layer in contact with the cathode side of the layer 106A can be suitably used for the layer 106A.

For example, a material that has a LUMO level in a range higher than or equal to −5.0 eV, preferably higher than or equal to −5.0 eV and lower than or equal to −3.0 eV can be used for the layer 106A.

Specifically, a phthalocyanine-based material can be used for the layer 106A. Alternatively, a metal complex having a metal-oxygen bond and an aromatic ligand can be used for the layer 106A.

### <<Structure Example of Layer 106B>>

For example, a material that supplies electrons to the anode side and supplies holes to the cathode side when voltage is applied can be used for the layer 106B. Specifically, electrons can be supplied to the unit 103 that is positioned on the anode side. The layer 106B can be referred to as a charge-generation layer.

Specifically, a material having a hole-injection property usable for the layer 104 can be used for the layer 106B. For example, a composite material can be used for the layer 106B. As another example, a stacked film in which a film including the composite material and a film including a material having a hole-transport property are stacked can be used as the layer 106B.

Note that this embodiment can be combined with any of the other embodiments described in this specification as appropriate.

### Embodiment 6

In this embodiment, the structure of the light-emitting device 150 of one embodiment of the present invention is described with reference to FIG. 3B.

FIG. 3B is a cross-sectional view illustrating a structure of the light-emitting device of one embodiment of the present invention, which is different from the structure illustrated in FIG. 3A.

### <Structure Example of Light-Emitting Device 150>

The light-emitting device 150 described in this embodiment includes the electrode 101, the electrode 102, the unit 103, the intermediate layer 106, and a unit 103(12) (see FIG. 3B). The electrode 102 includes a region overlapping with the electrode 101, the unit 103 includes a region interposed between the electrode 101 and the electrode 102, and the intermediate layer 106 includes a region positioned between the unit 103 and the electrode 102. The unit 103(12) includes a region interposed between the intermediate layer 106 and the electrode 102, and the unit 103(12) has a function of emitting light ELT(2).

A structure including the intermediate layer 106 and a plurality of units is referred to as a stacked light-emitting device or a tandem light-emitting device in some cases. This structure can obtain light emission at high luminance while the current density is kept low. Alternatively, the reliability can be increased. Alternatively, the driving voltage can be lowered compared to other structures with the same luminance. Alternatively, power consumption can be reduced.

### <<Structure Example of Unit 103(12)>>

The structure usable for the unit 103 can be employed for the unit 103(12). In other words, the light-emitting device 150 includes a plurality of units that are stacked. Note that the number of stacked units is not limited to two, and three or more units can be stacked.

The same structure as the unit 103 can be employed for the unit 103(12). Alternatively, a structure different from that of the unit 103 can be employed for the unit 103(12).

For example, a structure that exhibits a different emission color from the emission color of the unit 103 can be employed for the unit 103(12). Specifically, the unit 103 that emits red light and green light and the unit 103(12) that emits blue light can be employed. Accordingly, a light-emitting device that emits light of a desired color can be provided. For example, a light-emitting device that emits white light can be provided.

### <<Structure Example of Intermediate Layer 106>>

The intermediate layer 106 has a function of supplying electrons to one of the unit 103 and the unit 103(12) and supplying holes to the other. For example, the intermediate layer 106 described in Embodiment 5 can be used.

### <Fabrication Method of Light-Emitting Device 150>

For example, each layer of the electrode 101, the electrode 102, the unit 103, the intermediate layer 106, and the unit 103(12) can be formed by a dry process, a wet process, an evaporation method, a droplet discharge method, a coating method, a printing method, or the like. Different methods can be used to form the components.

Specifically, the light-emitting device 150 can be manufactured with a vacuum evaporation machine, an inkjet machine, a coating machine such as a spin coater, a gravure printing machine, an offset printing machine, a screen printing machine, or the like.

For example, the electrode can be formed by a wet process or a sol-gel method using a paste of a metal material. An indium oxide-zinc oxide film can be formed by a sputtering method using a target obtained by adding, to indium oxide, zinc oxide at higher than or equal to 1 wt % and lower than or equal to 20 wt %. An indium oxide film containing tungsten oxide and zinc oxide (IWZO) can be formed by a sputtering method using a target containing, with respect to indium oxide, tungsten oxide at higher than or equal to 0.5 wt % and lower than or equal to 5 wt % and zinc oxide at higher than or equal to 0.1 wt % and lower than or equal to 1 wt %.

Note that this embodiment can be combined with any of the other embodiments described in this specification as appropriate.

### Embodiment 7

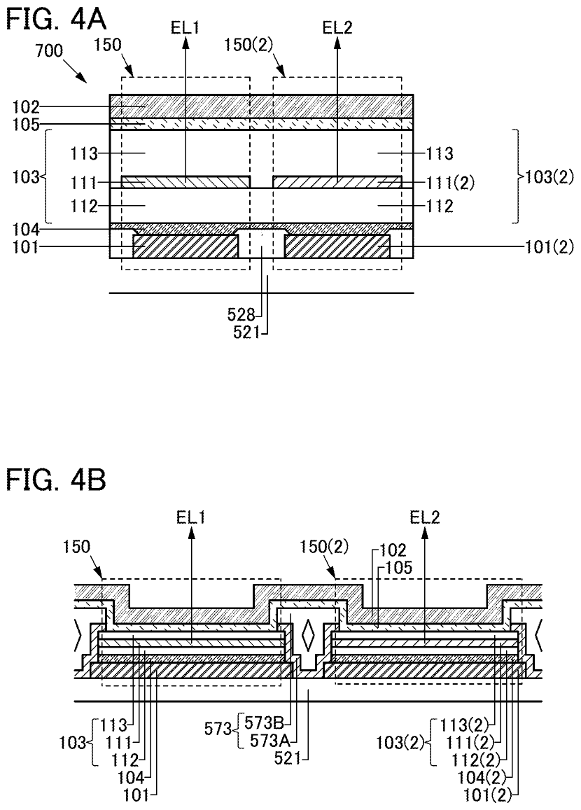

In this embodiment, a structure of a functional panel 700 of one embodiment of the present invention is described with reference to FIG. 4A and FIG. 4B.

FIG. 4A is a cross-sectional view illustrating the structure of the functional panel 700 of one embodiment of the present invention, and FIG. 4B is a cross-sectional view illustrating a structure of the functional panel 700 of one embodiment of the present invention different from that in FIG. 4A.

### <Structure Example 1 of Functional Panel 700>

The functional panel 700 described in this embodiment includes the light-emitting device 150 and a light-emitting device 150(2) (see FIG. 4A). Furthermore, the functional panel 700 includes an insulating film 521.

The functional panel 700 includes an insulating film 528 (see FIG. 4A). The insulating film 528 has openings; one opening overlaps with the electrode 101 and the other opening overlaps with an electrode 101(2).

### <Structure Example 2 of Functional Panel 700>

The functional panel 700 includes an insulating film 573, for example (see FIG. 4B). The insulating film 573 includes an insulating film 573A and an insulating film 573B, and the insulating film 573A includes a region interposed between the insulating film 573B and the insulating film 521.

A groove is provided between an unit 103(2) and the unit 103, and the unit 103(2) has a sidewall along the groove. The unit 103 also has a sidewall along the groove.

The insulating film 573A includes a region in contact with the sidewall of unit 103(2) and a region in contact with the sidewall of the unit 103.

For example, the light-emitting device described in any of Embodiment 1 to Embodiment 6 can be used as the light-emitting device 150.

### <Structure Example of Light-Emitting Device 150(2)>

The light-emitting device 150(2) described in this embodiment includes the electrode 101(2), the electrode 102, and the unit 103(2) (see FIG. 4A). The electrode 102 includes a region overlapping with the electrode 101(2), and the unit 103(2) includes a region interposed between the electrode 101(2) and the electrode 102.

The electrode 101(2) can have a potential that is the same as or different from that of the electrode 101. By supplying a different potential, the light-emitting device 150(2) can be driven under conditions different from those for the light-emitting device 150. Note that a material that can be used for the electrode 101 can be used for the electrode 101(2).

The light-emitting device 150(2) includes the layer 104 and the layer 105. The layer 104 includes a region interposed between the electrode 101(2) and the unit 103(2), and the layer 105 includes a region interposed between the unit 103(2) and the electrode 102. Note that some of the components of the light-emitting device 150 can be used as some of the components of the light-emitting device 150(2). Thus, some of the components can be used in common. Alternatively, the manufacturing process can be simplified.

<Structure example of unit 103(2)>

The unit 103(2) has a single-layer structure or a stacked-layer structure. The unit 103(2) includes, for example, a layer 111(2), the layer 112, and the layer 113 (see FIG. 4A). Alternatively, the unit 103(2) includes, for example, the layer 111(2), a layer 112(2), and a layer 113(2) (see FIG. 4B). Note that the layer 112(2) has a structure usable for the layer 112, and the layer 113(2) has a structure usable for the layer 113.

The layer 111(2) includes a region interposed between the layer 112 and the layer 113, the layer 112 includes a region interposed between the electrode 101(2) and the layer 111(2), and the layer 113 includes a region interposed between the electrode 102 and the layer 111(2).

For example, a layer selected from functional layers such as a light-emitting layer, a hole-transport layer, an electron-transport layer, and a carrier-blocking layer can be used in the unit 103(2). Moreover, a layer selected from functional layers such as a hole-injection layer, an electron-injection layer, an exciton-blocking layer, and a charge-generation layer can be used in the unit 103(2).

<<Structure Example 1 of Layer 111(2)>>

A light-emitting material or a light-emitting material and a host material can be used for the layer 111(2), for example. The layer 111(2) can be referred to as a light-emitting layer. The layer 111(2) is preferably provided in a region where holes and electrons are recombined. Thus, energy generated by recombination of carriers can be efficiently converted into light and emitted. Furthermore, the layer 111(2) is preferably provided apart from a metal used for the electrode or the like. Thus, a quenching phenomenon caused by the metal used for the electrode or the like can be inhibited.

For example, a light-emitting material different from the light-emitting material used for the layer 111 can be used for the layer 111(2). Specifically, a light-emitting material having a different emission color from that of the layer 111 can be used for the layer 111(2). Thus, light-emitting devices with different hues can be provided. Alternatively, additive color mixing can be performed using a plurality of light-emitting devices with different hues. Alternatively, it is possible to express a color of a hue that an individual light-emitting device cannot display.

For example, a light-emitting device that emits blue light, a light-emitting device that emits green light, and a light-emitting device that emits red light can be provided in the functional panel. Alternatively, a light-emitting device that emits white light, a light-emitting device that emits yellow light, and a light-emitting device that emits infrared rays can be provided in the functional panel.

### <<Structure Example 2 of Layer 111(2)>>

For example, a fluorescent substance, a phosphorescent substance, or a substance exhibiting thermally activated delayed fluorescence (also referred to as a TADF material) can be used as the light-emitting material. Thus, energy generated by recombination of carriers can be released as light EL2 from the light-emitting material (see FIG. 4A).

### [Fluorescent Substance]

A fluorescent substance can be used for the layer 111(2). For example, the following fluorescent substances can be used for the layer 111(2). Note that without being limited to the following ones, a variety of known fluorescent substances can be used for the layer 111(2).

Specifically, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPm), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-20 tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N′,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-(pyrene-1,6-diyl)bis[(6,N-diphenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), or 3,10-bis[N-(dibenzofuran-3-yl)-N-phenylamino]naphtho[2,3-b;6,7-b′]bisbenzofuran (abbreviation: 3,10FrA2Nbf(IV)-02).

Condensed aromatic diamine compounds typified by pyrenediamine compounds such as 1,6FLPAPm, 1,6mMemFLPAPm, and 1,6BnfAPm-03 are particularly preferable because of their high hole-trapping properties, high light emission efficiency, or high reliability.

### [Phosphorescent Substance]

A phosphorescent substance can be used for the layer 111(2). For example, the following phosphorescent substances can be used for the layer 111(2). Note that without being limited to the following ones, a variety of known phosphorescent substances can be used for the layer 111(2).

For example, any of the following can be used for the layer 111(2): an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, and a platinum complex.

### [Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato]iridium(III) (abbreviation: [Ir(Prptz1-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), bis[2-(4′,6′-difluorophenyl)pyridinato-N,C^{2′}]iridium(III) acetylacetonate (abbreviation: FIracac), or the like can be used.

Note that these are compounds exhibiting blue phosphorescence, and are compounds having an emission wavelength peak at 440 nm to 520 nm.

### [Phosphorescent Substance (Green)]

As an organometallic iridium complex having a pyrimidine skeleton or the like, it is possible to use, for example, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]).

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, it is possible to use, for example, tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-d3-methyl-8-(2-pyridinyl-κN)benzofuro[2,3-b]pyridine-κC]bis[2-(5-d3-methyl-2-pyridinyl-κN2)phenyl-κC]iridium(III) (abbreviation: [Ir(5mppy-d3)₂(mbfpypy-d3)]), or [2-d3-methyl-(2-pyridinyl-κN)benzofuro[2,3-b]pyridine-κC]bis[2-(2-pyridinyl-KM)phenyl-κC]iridium(III) (abbreviation: [Ir(ppy)₂(mbfpypy-d3)]).

An example of a rare earth metal complex is tris(acetylacetonato) (monophenanthroline)terbium(III) (abbreviation: [Tb(acac)₃(Phen)]).

Note that these are compounds mainly exhibiting green phosphorescence, and have an emission wavelength peak at 500 nm to 600 nm. An organometallic iridium complex having a pyrimidine skeleton excels particularly in reliability or light emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato] (dipivaloylmethanato)iridium(III) (abbreviation: [Ir(d1npm)₂(dpm)]), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C²′)iridium(III) (abbreviation: [Ir(piq)₃]), bis(1-phenylisoquinolinato-N,C²′)iridium(III) acetylacetonate (abbreviation: [Ir(piq)₂(acac)]), or the like can be used.

As a rare earth metal complex or the like, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato] (monophenanthroline)europium(III) (abbreviation: [Eu(TTA)₃(Phen)]), or the like can be used.

As a platinum complex or the like, 2,3,7,8,12,13,17,18-octaethyl-21H,23H-porphyrin platinum(II) (abbreviation: PtOEP) or the like can be used.

Note that these are compounds exhibiting red phosphorescence, and have an emission peak at 600 nm to 700 nm. Furthermore, from the organometallic iridium complex having a pyrazine skeleton, red light emission with chromaticity favorably used for display apparatuses can be obtained.

### [Substance Exhibiting Thermally Activated Delayed Fluorescence (TADF)]

A TADF material can be used for the layer 111(2). In the TADF material, the difference between the S1 level and the T1 level is small, and reverse intersystem crossing (upconversion) from the triplet excited state into the singlet excited state can be achieved by a little thermal energy. Thus, the singlet excited state can be efficiently generated from the triplet excited state. In addition, the triplet excitation energy can be converted into light.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the shortest wavelength side is the S1 level and the level of energy with a wavelength of the line obtained by extrapolating a tangent to the phosphorescent spectrum at a tail on the shortest wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than that of the TADF material. In addition, the T1 level of the host material is preferably higher than that of the TADF material.

For example, the TADF material that can be used as the host material described in Embodiment 1 can be used as the light-emitting material.

### <<Structure Example 3 of Layer 111(2)>>

A material having a carrier-transport property can be used as the host material. For example, a material having a hole-transport property, a material having an electron-transport property, a substance exhibiting thermally activated delayed fluorescence, a material having an anthracene skeleton, or a mixed material can be used as the host material. A material having a wider bandgap than the light-emitting material contained in the layer 111(2) is preferably used as the host material. Thus, transfer of energy from excitons generated in the layer 111(2) to the host material can be inhibited.

### [Material Having Hole-Transport Property]

A material having a hole mobility of 1×10⁻⁶ cm²/Vs or higher can be suitably used as the material having a hole-transport property.

For example, a material having a hole-transport property that can be used for the layer 112 can be used for the layer 111(2). Specifically, a material having a hole-transport property that can be used for the hole-transport layer can be used for the layer 111(2).

### [Material Having Electron-Transport Property]

For example, a material having an electron-transport property that can be used for the layer 113 can be used for the layer 111(2). Specifically, a material having an electron-transport property that can be used for the electron-transport layer can be used for the layer 111(2).

### [Material Having Anthracene Skeleton]

An organic compound having an anthracene skeleton can be used as the host material. An organic compound having an anthracene skeleton is preferable particularly in the case where a fluorescent substance is used as the light-emitting substance. Thus, a light-emitting device with high emission efficiency and high durability can be obtained.

As the organic compound having an anthracene skeleton, an organic compound having a diphenylanthracene skeleton, in particular, a 9,10-diphenylanthracene skeleton is chemically stable and thus is preferable. The host material preferably has a carbazole skeleton, in which case the hole-injection and hole-transport properties are improved. In particular, the host material preferably has a dibenzocarbazole skeleton, in which case the HOMO level thereof is shallower than that of carbazole by approximately 0.1 eV so that holes enter the host material easily, the hole-transport property is improved, and the heat resistance is increased. Note that in terms of the hole-injection and hole-transport properties, a benzofluorene skeleton or a dibenzofluorene skeleton may be used instead of a carbazole skeleton.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

For example, it is possible to use 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9-(1-naphthyl)-10-[4-(2-naphthyl)phenyl]anthracene (abbreviation: αN-βNPAnth), 9-phenyl-3-[4-(10-phenyl-9-anthryl)phenyl]-9H-carbazole (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), or 3-[4-(1-naphthyl)-phenyl]-9-phenyl-9H-carbazole (abbreviation: PCPN).

In particular, CzPA, cgDBCzPA, 2mBnfPPA, and PCzPA have excellent characteristics

### [Structure Example 1 of Mixed Material]

A material in which a plurality of kinds of substances are mixed can be used as the host material. For example, a material having an electron-transport property and a material having a hole-transport property can be used in the mixed material. The weight ratio between the material having a hole-transport property and the material having an electron-transport property contained in the mixed material may be (the material having a hole-transport property/the material having an electron-transport property)=(1/19) or more and (19/1) or less. Accordingly, the carrier-transport property of the layer 111(2) can be easily adjusted. Furthermore, a recombination region can be easily controlled.

### [Structure Example 2 of Mixed Material]

A material mixed with a phosphorescent substance can be used as the host material. When a fluorescent substance is used as the light-emitting substance, a phosphorescent substance can be used as an energy donor for supplying excitation energy to the fluorescent substance.

A mixed material containing a material to form an exciplex can be used as the host material. For example, a material in which an emission spectrum of a formed exciplex overlaps with a wavelength of the absorption band on the lowest energy side of the light-emitting substance can be used as the host material. This enables smooth energy transfer and improves emission efficiency. The driving voltage can be inhibited. With such a structure, light emission can be efficiently obtained by ExTET (Exciplex-Triplet Energy Transfer), which is energy transfer from an exciplex to a light-emitting substance (a phosphorescent material).

A phosphorescent substance can be used as at least one of the materials forming an exciplex. Accordingly, reverse intersystem crossing can be used. Alternatively, triplet excitation energy can be efficiently converted into singlet excitation energy.

A combination of materials forming an exciplex is preferably such that the HOMO level of a material having a hole-transport property is higher than or equal to the HOMO level of a material having an electron-transport property. Alternatively, the LUMO level of the material having a hole-transport property is preferably higher than or equal to the LUMO level of the material having an electron-transport property. Thus, an exciplex can be efficiently formed. Note that the LUMO levels and the HOMO levels of the materials can be derived from the electrochemical characteristics (reduction potentials and oxidation potentials). Specifically, the reduction potentials and the oxidation potentials can be measured by cyclic voltammetry (CV).

The formation of an exciplex can be confirmed by a phenomenon in which the emission spectrum of a mixed film in which the material having a hole-transport property and the material having an electron-transport property are mixed is shifted to the longer wavelength side than the emission spectrum of each of the materials (or has another peak on the longer wavelength side) observed by comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient PL lifetime of the mixed film has longer lifetime components or has a larger proportion of delayed components than that of each of the materials, observed by comparison of transient photoluminescence (PL) of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of these materials.

Note that this embodiment can be combined with any of the other embodiments described in this specification as appropriate.

### Embodiment 8

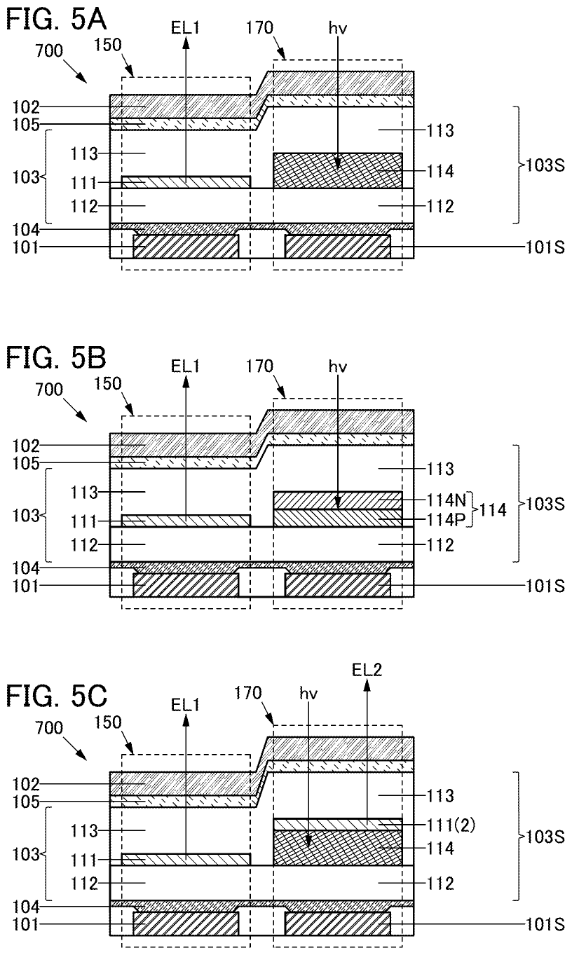

In this embodiment, structures of the functional panel 700 of one embodiment of the present invention will be described with reference to FIG. 5.

### <Structure Example 1 of Functional Panel 700>

The functional panel 700 described in this embodiment includes the light-emitting device 150 and an optical functional device 170 (see FIG. 5A).

For example, the light-emitting device described in any of Embodiment 1 to Embodiment 6 can be used as the light-emitting device 150.

### <Structure Example of Optical Functional Device 170>

The optical functional device 170 described in this embodiment includes an electrode 101S, the electrode 102, and a unit 103S. The electrode 102 includes a region overlapping with the electrode 101S, and the unit 103S includes a region interposed between the electrode 101S and the electrode 102.

The optical functional device 170 includes the layer 104 and the layer 105. The layer 104 includes a region interposed between the electrode 101S and the unit 103S, and the layer 105 includes a region interposed between the unit 103S and the electrode 102. Note that some of the components of the light-emitting device 150 can be used as some of the components of the optical functional device 170. Thus, some of the components can be used in common. Alternatively, the manufacturing process can be simplified.

### <Structure Example 1 of Unit 103S>

The unit 103S has a single-layer structure or a stacked-layer structure. For example, the unit 103S includes a layer 114, the layer 112, and the layer 113 (see FIG. 5A).

The layer 114 includes a region interposed between the layer 112 and the layer 113, the layer 112 includes a region interposed between the electrode 101S and the layer 114, and the layer 113 includes a region interposed between the electrode 102 and the layer 114.

For example, a layer selected from functional layers such as a photoelectric conversion layer, a hole-transport layer, an electron-transport layer, and a carrier-blocking layer can be used in the unit 103S. Moreover, a layer selected from functional layers such as a hole-injection layer, an electron-injection layer, an exciton-blocking layer, and a charge-generation layer can be used in the unit 103S.

The unit 103S absorbs light hv, supplies electrons to one electrode, and supplies holes to the other electrode. For example, the unit 103S supplies holes to the electrode 101S and supplies electrons to the electrode 102.

### <<Structure Example of Layer 112>>

A material having a hole-transport property can be used for the layer 112, for example. The layer 112 can be referred to as a hole-transport layer. For example, the structure described in Embodiment 2 can be used for the layer 112.

### <<Structure Example of Layer 113>>

A material having an electron-transport property, a material having an anthracene skeleton, and a mixed material can be used for the layer 113, for example. For example, the structure described in Embodiment 2 can be used for the layer 113.

### <<Structure Example 1 of Layer 114>>

For example, an electron-accepting material and an electron-donating material can be used for the layer 114. Specifically, a material that can be used for an organic solar cell can be used for the layer 114. The layer 114 can be referred to as a photoelectric conversion layer. The layer 114 absorbs the light hv, supplies electrons to one electrode, and supplies holes to the other electrode. For example, the layer 114 supplies holes to the electrode 101S and supplies electrons to the electrode 102.

### [Example of Electron-Accepting Material]

As the electron-accepting material, a fullerene derivative or a non-fullerene electron acceptor can be used, for example.

As the electron-accepting material, a C₆₀ fullerene, a C₇₀ fullerene, [6,6]-phenyl-C₇₁-butyric acid methyl ester (abbreviation: PC71BM), [6,6]-phenyl-C₆₁-butyric acid methyl ester (abbreviation: PC61BM), 1′,1″,4′,4″-tetrahydro-di[1,4]methanonaphthaleno[1,2:2′,3′,56,60:2″,3″][5,6]fullerene-C₆₀ (abbreviation: ICBA), or the like can be used.

As the non-fullerene electron acceptor, a perylene derivative, a compound having a dicyanomethyleneindanone group, or the like can be used. For example, N,N-dimethyl-3,4,9,10-perylenedicarboximide (abbreviation: Me-PTCDI) can be used.

### [Example of Electron-Donating Material]

As the electron-donating material, for example, a phthalocyanine compound, a tetracene derivative, a quinacridone derivative, or a rubrene derivative can be used.

As the electron-donating material, copper(II) phthalocyanine (abbreviation: CuPc), tin(II) phthalocyanine (SnPc), zinc phthalocyanine (ZnPc), tetraphenyldibenzoperiflanthene (DBP), rubrene, or the like can be used.

### <<Structure Example 2 of Layer 114>>

The layer 114 can have a single-layer structure or a stacked-layer structure, for example. Specifically, the layer 114 can have a bulk heterojunction structure. Alternatively, the layer 114 can have a heterojunction structure.

### [Structure Example of Mixed Material]

A mixed material containing an electron-accepting material and an electron-donating material can be used for the layer 114, for example (see FIG. 5A). Note that a structure in which such a mixed material containing an electron-accepting material and an electron-donating material is used for the layer 114 can be referred to as a bulk heterojunction structure.

Specifically, a mixed material containing a C₇₀ fullerene and DBP can be used for the layer 114.

### [Example of Heterojunction Structure]

A layer 114N and a layer 114P can be used for the layer 114. The layer 114N includes a region interposed between one electrode and the layer 114P, and the layer 114P includes a region interposed between the layer 114N and the other electrode. For example, the layer 114N includes a region interposed between the electrode 102 and the layer 114P, and the layer 114P includes a region interposed between the layer 114N and the electrode 101S (see FIG. 5B).

An n-type semiconductor can be used for the layer 114N. For example, Me-PTCDI can be used for the layer 114N.

A p-type semiconductor can be used for the layer 114P. For example, rubrene can be used for the layer 114P.

Note that the optical functional device 170 in which the layer 114P is in contact with the layer 114N can be referred to as a pn-junction photodiode.

### <Structure Example 2 of Unit 103S>

The unit 103S includes the layer 111(2), and the layer 111(2) includes a region interposed between the layer 114 and the layer 113 (see FIG. 5C).

Structure example 2 of unit 103S is different from Structure example 1 of unit 103S in that the layer 111(2) is provided. Different portions will be described in detail below, and the above description is referred to for portions having the same structure as the above.

### <<Structure Example of Layer 111(2)>>

A light-emitting material or a light-emitting material and a host material can be used for the layer 111(2), for example. The layer 111(2) can be referred to as a light-emitting layer. The layer 111(2) is preferably provided in a region where holes and electrons are recombined. Thus, energy generated by recombination of carriers can be efficiently converted into light and emitted. Furthermore, the layer 111(2) is preferably provided apart from a metal used for the electrode or the like. Thus, a quenching phenomenon caused by the metal used for the electrode or the like can be inhibited.

Specifically, the structure described in Embodiment 7 can be used for the layer 111(2). In particular, the structure that emits light with a wavelength which is hardly absorbed by the layer 114 can be suitably employed for the layer 111(2). Accordingly, the light EL2 emitted from the layer 111(2) can be extracted with high efficiency.

Note that this embodiment can be combined with any of the other embodiments described in this specification as appropriate.

### Embodiment 9

In this embodiment, a light-emitting apparatus including the light-emitting device described in any one of Embodiment 1 to Embodiment 6 is described.

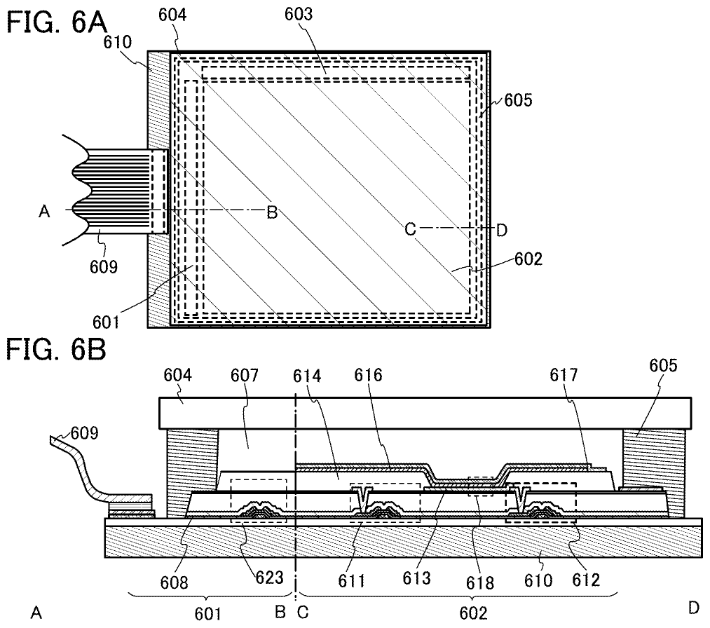

In this embodiment, a light-emitting apparatus fabricated using the light-emitting device described in any one of Embodiment 1 to Embodiment 6 is described with reference to FIG. 6. FIG. 6A is a top view illustrating the light-emitting apparatus, and FIG. 6B is a cross-sectional view taken along A-B and C-D in FIG. 6A. This light-emitting apparatus includes a driver circuit portion (source line driver circuit 601), a pixel portion 602, and a driver circuit portion (gate line driver circuit 603) that are to control light emission of light-emitting devices and are illustrated with dotted lines. Reference numeral 604 denotes a sealing substrate; 605, a sealant; and 607, a space surrounded by the sealant 605.

A lead wiring 608 is a wiring for transmitting signals to be input to the source line driver circuit 601 and the gate line driver circuit 603 and receives a video signal, a clock signal, a start signal, a reset signal, or the like from an FPC (flexible printed circuit) 609 serving as an external input terminal. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure is described with reference to FIG. 6B. The driver circuit portions and the pixel portion are formed over an element substrate 610; here, the source line driver circuit 601, which is a driver circuit portion, and one pixel in the pixel portion 602 are illustrated.

The element substrate 610 may be formed using a substrate containing glass, quartz, an organic resin, a metal, an alloy, a semiconductor, or the like or a plastic substrate formed of FRP (Fiber Reinforced Plastics), PVF (polyvinyl fluoride), polyester, an acrylic resin, or the like.

There is no particular limitation on the structure of transistors used in pixels or driver circuits. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used because deterioration of the transistor characteristics can be inhibited.

Here, an oxide semiconductor is preferably used for semiconductor devices such as the transistors provided in the pixels or the driver circuits and transistors used for after-mentioned touch sensors and the like. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is inhibited.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic device with extremely low power consumption can be obtained.

For stable characteristics or the like of the transistor, a base film is preferably provided. The base film can be formed with a single layer or stacked layers using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film does not have to be provided if not necessary.

Note that an FET 623 is illustrated as a transistor formed in the source line driver circuit 601. The driver circuit is formed with any of a variety of circuits such as a CMOS circuit, a PMOS circuit, or an NMOS circuit. Although a driver-integrated type in which the driver circuit is formed over the substrate is illustrated in this embodiment, the driver circuit is not necessarily formed over the substrate, and the driver circuit can be formed outside, not over the substrate.

The pixel portion 602 is formed with a plurality of pixels including a switching FET 611, a current control FET 612, and a first electrode 613 electrically connected to a drain of the current control FET 612; however, without being limited thereto, a pixel portion in which three or more FETs and a capacitor are combined may be employed.

Note that an insulator 614 is formed to cover an end portion of the first electrode 613. Here, the insulator 614 can be formed using a positive photosensitive acrylic resin film.

In order to improve the coverage with an EL layer or the like which is formed later, the insulator 614 is formed to have a curved surface with curvature at its upper or lower end portion. For example, in the case where a positive photosensitive acrylic resin is used as a material for the insulator 614, only the upper end portion of the insulator 614 preferably has a curved surface with a curvature radius (greater than or equal to 0.2 μm and less than or equal to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material with a high work function is desirably used. For example, a single-layer film of an ITO film, an indium tin oxide film containing silicon, an indium oxide film containing zinc oxide at 2 wt % or higher and 20 wt % or lower, a titanium nitride film, a chromium film, a tungsten film, a Zn film, a Pt film, or the like, a stacked layer of a titanium nitride film and a film containing aluminum as its main component, a three-layer structure of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in any one of Embodiment 1 to Embodiment 6. As another material included in the EL layer 616, a low molecular compound or a high molecular compound (including an oligomer or a dendrimer) may be used.

As a material used for the second electrode 617, which is formed over the EL layer 616 and functions as a cathode, a material with a low work function (e.g., Al, Mg, Li, Ca, or an alloy or a compound thereof (e.g., MgAg, MgIn, or AlLi)) is preferably used. Note that in the case where light generated in the EL layer 616 passes through the second electrode 617, it is preferable to use, for the second electrode 617, a stacked layer of a thin metal film and a transparent conductive film (e.g., ITO, indium oxide containing zinc oxide at 2 wt % or higher and 20 wt % or lower, indium tin oxide containing silicon, or zinc oxide (ZnO)).

Note that a light-emitting device 618 is formed with the first electrode 613, the EL layer 616, and the second electrode 617. The light-emitting device is the light-emitting device described in any one of Embodiment 1 to Embodiment 6. A plurality of light-emitting devices are formed in the pixel portion, and the light-emitting apparatus of this embodiment may include both the light-emitting device described in any one of Embodiment 1 to Embodiment 6 and a light-emitting device having a different structure.

The sealing substrate 604 is attached to the element substrate 610 with the sealant 605, so that the light-emitting device 618 is provided in the space 607 surrounded by the element substrate 610, the sealing substrate 604, and the sealant 605. The space 607 is filled with a filler; it is filled with an inert gas (e.g., nitrogen or argon) in some cases, and filled with the sealant in some cases. It is preferable that the sealing substrate have a recessed portion provided with a desiccant, in which case degradation due to the influence of moisture can be inhibited.

Note that an epoxy-based resin or glass frit is preferably used for the sealant 605. Furthermore, these materials are preferably materials that transmit moisture and oxygen as little as possible. As the material used for the sealing substrate 604, in addition to a glass substrate and a quartz substrate, a plastic substrate formed of FRP (Fiber Reinforced Plastics), PVF (polyvinyl fluoride), polyester, an acrylic resin, or the like can be used.

Although not illustrated in FIG. 6A or FIG. 6B, a protective film may be provided over the second electrode. The protective film is formed using an organic resin film or an inorganic insulating film. The protective film may be formed so as to cover an exposed portion of the sealant 605. The protective film can be provided to cover surfaces and side surfaces of the pair of substrates and exposed side surfaces of a sealing layer, an insulating layer, and the like.

The protective film can be formed using a material that does not easily transmit an impurity such as water. Thus, diffusion of an impurity such as water from the outside into the inside can be effectively inhibited.

As a material of the protective film, an oxide, a nitride, a fluoride, a sulfide, a ternary compound, a metal, a polymer, or the like can be used. For example, it is possible to use a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an atomic layer deposition (ALD) method. A material that can be deposited by an ALD method is preferably used for the protective film. With the use of an ALD method, a dense protective film with reduced defects such as cracks or pinholes or with a uniform thickness can be formed. Furthermore, damage caused to a process member in forming the protective film can be reduced.

By an ALD method, for example, a uniform protective film with few defects can be formed even on a surface with a complex uneven shape or upper, side, and lower surfaces of a touch panel.

As described above, the light-emitting apparatus fabricated using the light-emitting device described in any one of Embodiment 1 to Embodiment 6 can be obtained.

The light-emitting apparatus in this embodiment is fabricated using the light-emitting device described in any one of Embodiment 1 to Embodiment 6 and thus can have favorable characteristics. Specifically, since the light-emitting device described in any one of Embodiment 1 to Embodiment 6 has favorable emission efficiency, the light-emitting apparatus with low power consumption can be obtained.

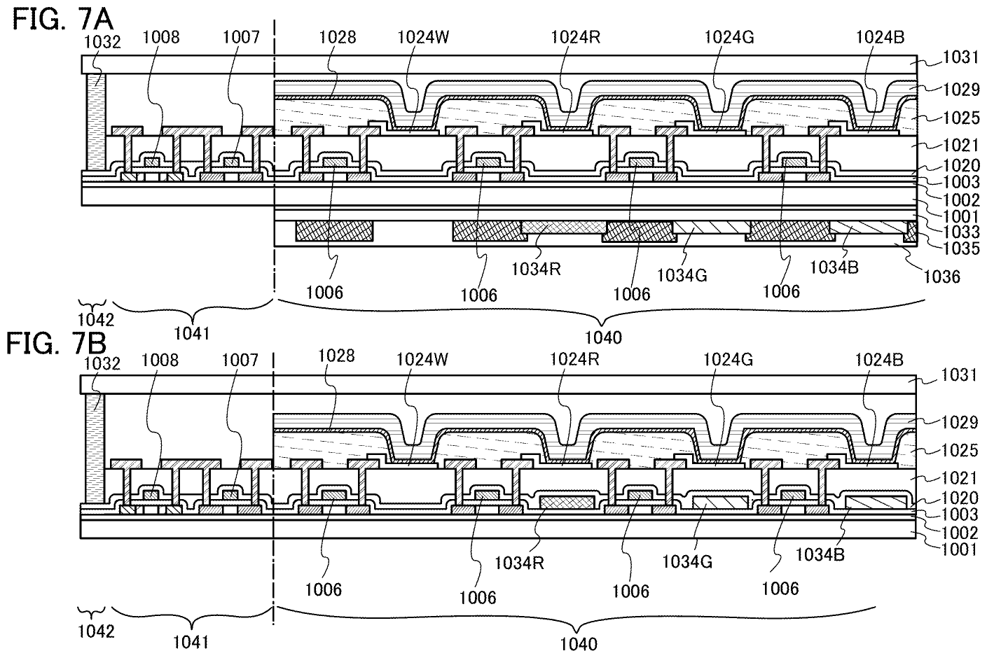

FIG. 7 illustrates examples of a light-emitting apparatus in which full color display is achieved by formation of light-emitting devices exhibiting white light emission and provision of coloring layers (color filters) and the like. FIG. 7A illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, first electrodes 1024 W, 1024R, 1024G, and 1024B of the light-emitting devices, a partition 1025, an EL layer 1028, a second electrode 1029 of the light-emitting devices, a sealing substrate 1031, a sealant 1032, and the like.

In FIG. 7A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036. In FIG. 7A, a light-emitting layer from which light is emitted to the outside without passing through the coloring layer and light-emitting layers from which light is emitted to the outside, passing through the coloring layers of the respective colors are shown. Since light that does not pass through the coloring layer is white and light that passes through the coloring layer is red, green, or blue, an image can be expressed by pixels of the four colors.

FIG. 7B shows an example in which the coloring layers (the red coloring layer 1034R, the green coloring layer 1034G, and the blue coloring layer 1034B) are formed between the gate insulating film 1003 and the first interlayer insulating film 1020. As in the structure, the coloring layers may be provided between the substrate 1001 and the sealing substrate 1031.

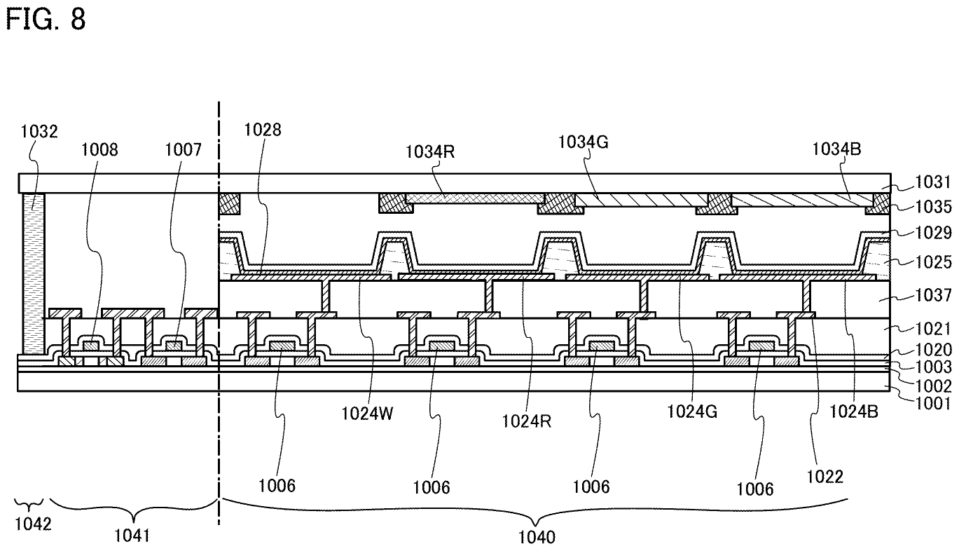

The above-described light-emitting apparatus has a structure in which light is extracted from the substrate 1001 side where FETs are formed (a bottom emission structure), but may have a structure in which light is extracted from the sealing substrate 1031 side (atop emission structure). FIG. 8 shows a cross-sectional view of a top-emission light-emitting apparatus. In this case, a substrate that does not transmit light can be used as the substrate 1001. The top-emission light-emitting apparatus is formed in a manner similar to that of the bottom-emission light-emitting apparatus until a connection electrode that connects the FET and the anode of the light-emitting device is formed. Then, a third interlayer insulating film 1037 is formed to cover an electrode 1022. This insulating film may have a planarization function. The third interlayer insulating film 1037 can be formed using a material similar to that of the second interlayer insulating film, and can alternatively be formed using any of other known materials.

The first electrodes 1024 W, 1024R, 1024G, and 1024B of the light-emitting devices are each an anode here, but may each be a cathode. In the case of the top-emission light-emitting apparatus such as one in FIG. 8, the first electrodes are preferably reflective electrodes. The structure of the EL layer 1028 is such a structure as that of the unit 103 described in any one of Embodiment 1 to Embodiment 6, and an element structure with which white light emission can be obtained.

In the case of such a top-emission structure as in FIG. 8, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 that is positioned between pixels. The coloring layers (the red coloring layer 1034R, the green coloring layer 1034G, and the blue coloring layer 1034B) or the black matrix may be covered with the overcoat layer 1036. Note that a substrate having a light-transmitting property is used as the sealing substrate 1031. Although an example in which full color display is performed using four colors of red, green, blue, and white is shown here, there is no particular limitation and full color display may be performed using four colors of red, yellow, green, and blue or three colors of red, green, and blue.

In the top-emission light-emitting apparatus, a microcavity structure can be favorably employed. A light-emitting device with a microcavity structure can be obtained with the use of a reflective electrode as the first electrode and a transflective electrode as the second electrode. The light-emitting device with a microcavity structure includes at least an EL layer between the reflective electrode and the transflective electrode, and the EL layer includes at least a light-emitting layer serving as a light-emitting region.

Note that the reflective electrode is a film having a visible light reflectivity of 40% to 100%, preferably 70% to 100%, and a resistivity of 1×10⁻² Ωcm or lower. In addition, the transflective electrode is a film having a visible light reflectivity of 20% to 80%, preferably 40% to 70%, and a resistivity of 1×10⁻² Ωcm or lower.

Light emitted from the light-emitting layer included in the EL layer is reflected and resonated by the reflective electrode and the transflective electrode.

In the light-emitting device, by changing thicknesses of the transparent conductive film, the above-described composite material, the carrier-transport material, or the like, the optical path length between the reflective electrode and the transflective electrode can be changed. Thus, light with a wavelength that is resonated between the reflective electrode and the transflective electrode can be intensified while light with a wavelength that is not resonated therebetween can be attenuated.

Note that light that is reflected back by the reflective electrode (first reflected light) considerably interferes with light that directly enters the transflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer positioned between the EL layers.

With the microcavity structure, emission intensity with a specific wavelength in the front direction can be increased, whereby power consumption can be reduced. Note that in the case of a light-emitting apparatus that displays images with subpixels of four colors, red, yellow, green, and blue, the light-emitting apparatus can have favorable characteristics because the luminance can be increased owing to yellow light emission and each subpixel can employ a microcavity structure suitable for wavelengths of the corresponding color.

The light-emitting apparatus in this embodiment is fabricated using the light-emitting device described in any one of Embodiment 1 to Embodiment 6 and thus can have favorable characteristics. Specifically, since the light-emitting device described in any one of Embodiment 1 to Embodiment 6 has favorable emission efficiency, the light-emitting apparatus with low power consumption can be obtained.

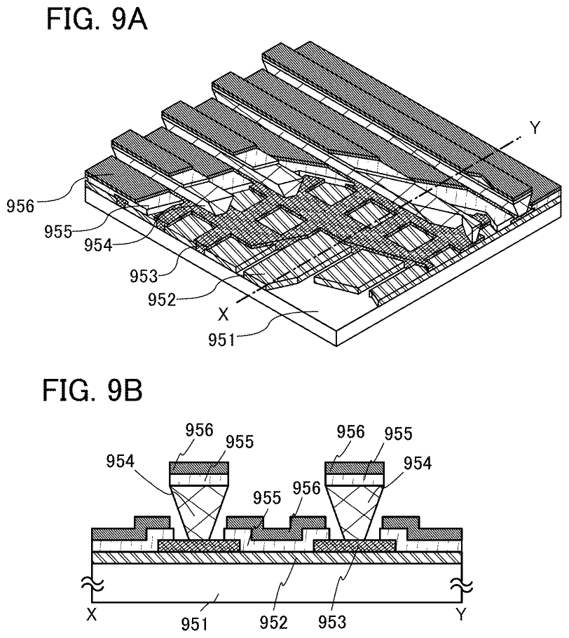

The active matrix light-emitting apparatus is described above, whereas a passive matrix light-emitting apparatus is described below. FIG. 9 illustrates a passive matrix light-emitting apparatus fabricated using the present invention. Note that FIG. 9A is a perspective view illustrating the light-emitting apparatus, and FIG. 9B is a cross-sectional view taken along X-Y in FIG. 9A. In FIG. 9, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. In other words, a cross section taken along the direction of the short side of the partition layer 954 is trapezoidal, and the lower side (a side that is parallel to the surface of the insulating layer 953 and is in contact with the insulating layer 953) is shorter than the upper side (a side that is parallel to the surface of the insulating layer 953 and is not in contact with the insulating layer 953). The partition layer 954 thus provided can prevent defects in the light-emitting device due to static electricity or the like. The passive matrix light-emitting apparatus also uses the light-emitting device described in any one of Embodiment 1 to Embodiment 6; thus, the light-emitting apparatus can have favorable reliability or low power consumption.

In the light-emitting apparatus described above, many minute light-emitting devices arranged in a matrix can each be controlled; thus, the light-emitting apparatus can be suitably used as a display apparatus for displaying images.

This embodiment can be freely combined with any of the other embodiments.

### Embodiment 10

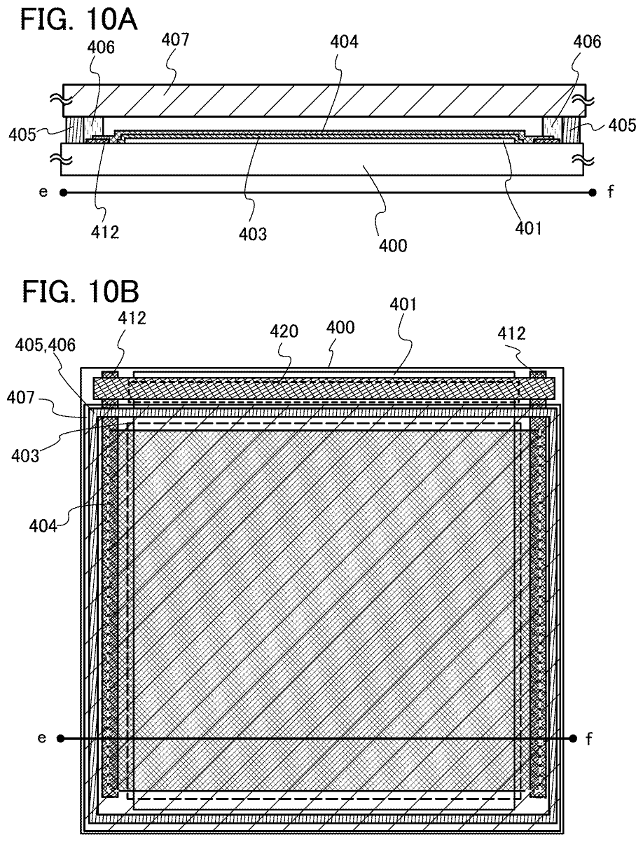

In this embodiment, an example in which the light-emitting device described in any one of Embodiment 1 to Embodiment 6 is used for a lighting device is described with reference to FIG. 10. FIG. 10B is a top view of the lighting device, and FIG. 10A is a cross-sectional view taken along e-f in FIG. 10B.

In the lighting device in this embodiment, a first electrode 401 is formed over a substrate 400 that is a support and has a light-transmitting property. The first electrode 401 corresponds to the electrode 101 in any one of Embodiment 1 to Embodiment 6. In the case where light emission is extracted from the first electrode 401 side, the first electrode 401 is formed with a material having a light-transmitting property.

A pad 412 for supplying a voltage to a second electrode 404 is formed over the substrate 400.

An EL layer 403 is formed over the first electrode 401. The EL layer 403 corresponds to the structure in which the layer 104, the unit 103, and the layer 105 are combined, the structure in which the layer 104, the unit 103, the intermediate layer 106, the unit 103(2), and the layer 105 are combined, or the like in any one of Embodiments 1 to 6. Note that for these structures, the corresponding description can be referred to.

The second electrode 404 is formed to cover the EL layer 403. The second electrode 404 corresponds to the electrode 102 in any one of Embodiment 1 to Embodiment 6. In the case where light emission is extracted from the first electrode 401 side, the second electrode 404 is formed with a material having high reflectivity. The second electrode 404 is supplied with a voltage when connected to the pad 412.

As described above, the lighting device described in this embodiment includes a light-emitting device including the first electrode 401, the EL layer 403, and the second electrode 404. Since the light-emitting device is alight-emitting device with high emission efficiency, the lighting device in this embodiment can have low power consumption.

The substrate 400 provided with the light-emitting device having the above structure is fixed to a sealing substrate 407 with sealants 405 and 406 and sealing is performed, whereby the lighting device is completed. It is possible to use only either the sealant 405 or the sealant 406. In addition, the inner sealant 406 (not shown in FIG. 10B) can be mixed with a desiccant, which enables moisture to be adsorbed, resulting in improved reliability.

When parts of the pad 412 and the first electrode 401 are provided to extend to the outside of the sealants 405 and 406, those can serve as external input terminals. An IC chip 420 mounted with a converter or the like may be provided over the external input terminals.

The lighting device described in this embodiment uses the light-emitting device described in any one of Embodiment 1 to Embodiment 6 as an EL element; thus, the lighting device can have low power consumption.

### Embodiment 11

In this embodiment, examples of electronic devices each partly including the light-emitting device described in any one of Embodiment 1 to Embodiment 6 are described. The light-emitting device described in any one of Embodiment 1 to Embodiment 6 is a light-emitting device with favorable emission efficiency and low power consumption. As a result, the electronic devices described in this embodiment can be electronic devices each including a light-emitting portion with low power consumption.

Examples of the electronic device including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic devices are shown below.

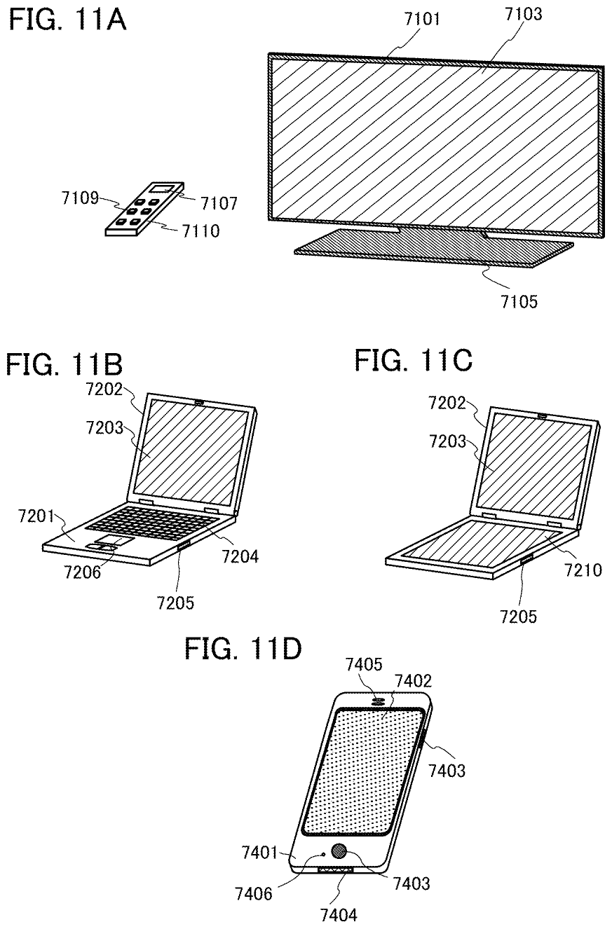

FIG. 11A illustrates an example of a television device. In the television device, a display portion 7103 is incorporated in a housing 7101. Here, the housing 7101 is supported by a stand 7105. Images can be displayed on the display portion 7103, and the light-emitting devices described in any one of Embodiment 1 to Embodiment 6 are arranged in a matrix in the display portion 7103.

The television device can be operated with an operation switch of the housing 7101 or a separate remote controller 7110. With operation keys 7109 of the remote controller 7110, channels and volume can be operated and images displayed on the display portion 7103 can be operated. Furthermore, the remote controller 7110 may be provided with a display portion 7107 for displaying data output from the remote controller 7110.

Note that the television device has a structure including a receiver, a modem, or the like. With the use of the receiver, a general television broadcast can be received, and moreover, when the television device is connected to a communication network with or without wires via the modem, one-way (from a sender to a receiver) or two-way (between a sender and a receiver or between receivers) data communication can be performed.

FIG. 11B shows a computer that includes a main body 7201, a housing 7202, a display portion 7203, a keyboard 7204, an external connection port 7205, a pointing device 7206, and the like. Note that this computer is fabricated using the light-emitting devices described in any one of Embodiment 1 to Embodiment 6 arranged in a matrix in the display portion 7203. The computer in FIG. 11B may be such a mode as illustrated in FIG. 11C. The computer in FIG. 11C is provided with a second display portion 7210 instead of the keyboard 7204 and the pointing device 7206. The second display portion 7210 is of a touch-panel type, and input can be performed by operating display for input displayed on the second display portion 7210 with a finger or a dedicated pen. The second display portion 7210 can also display images other than the display for input. The display portion 7203 may also be a touch panel. Connecting the two screens with a hinge can prevent troubles such as a crack in or damage to the screens caused when the computer is stored or carried.

FIG. 11D illustrates an example of a portable terminal. The portable terminal includes operation buttons 7403, an external connection port 7404, a speaker 7405, a microphone 7406, and the like in addition to a display portion 7402 incorporated in a housing 7401. Note that the portable terminal includes the display portion 7402 that is fabricated by arranging the light-emitting devices described in any one of Embodiment 1 to Embodiment 6 in a matrix.

The portable terminal illustrated in FIG. 11D can have a structure in which information can be input by touching the display portion 7402 with a finger or the like. In this case, operations such as making a call and creating an e-mail can be performed by touching the display portion 7402 with a finger or the like.

The display portion 7402 has mainly three screen modes. The first mode is a display mode mainly for displaying images. The second mode is an input mode mainly for inputting data such as text. The third mode is a display-and-input mode in which the two modes, the display mode and the input mode, are combined.

For example, in the case of making a call or creating an e-mail, the text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed by determining the orientation of the portable terminal (whether the portable terminal is placed vertically or horizontally).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is moving image data, the screen mode is switched to the display mode. When the signal is text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 can also function as an image sensor. For example, an image of a palm print, a fingerprint, or the like is taken when the display portion 7402 is touched with the palm or the finger, whereby personal authentication can be performed. Furthermore, by providing a backlight that emits near-infrared light or a sensing light source that emits near-infrared light in the display portion, an image of a finger vein, a palm vein, or the like can be taken.

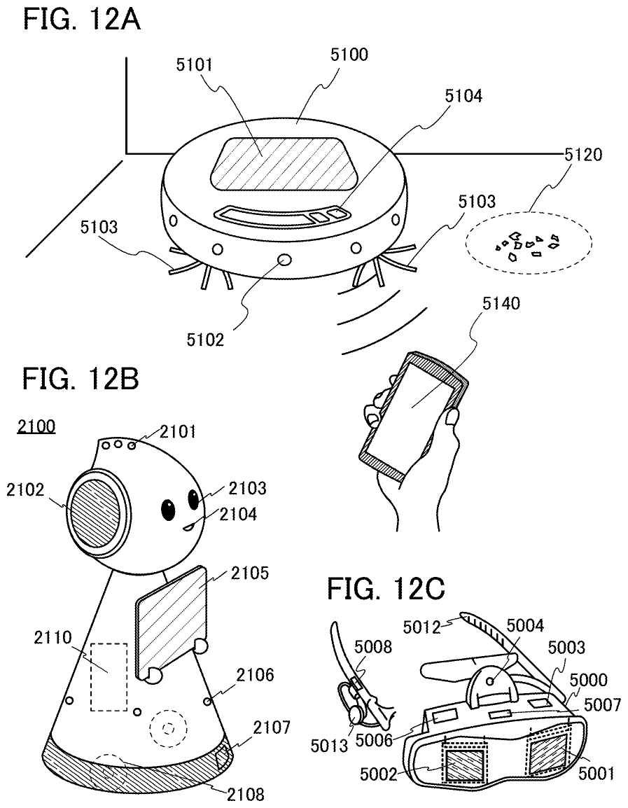

FIG. 12A is a schematic view showing an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and vacuums the dust through the inlet provided on the bottom surface.

The cleaning robot 5100 can determine whether there is an obstacle such as a wall, furniture, or a step by analyzing images taken by the cameras 5102. When an object that is likely to be caught in the brush 5103, such as a wire, is detected by image analysis, the rotation of the brush 5103 can be stopped.

The display 5101 can display the remaining capacity of a battery, the amount of vacuumed dust, or the like. The display 5101 may display a path on which the cleaning robot 5100 has run. The display 5101 may be a touch panel, and the operation buttons 5104 may be provided on the display 5101.

The cleaning robot 5100 can communicate with a portable electronic device 5140 such as a smartphone. Images taken by the cameras 5102 can be displayed on the portable electronic device 5140. Accordingly, an owner of the cleaning robot 5100 can monitor his/her room even when the owner is not at home. The owner can also check the display on the display 5101 by the portable electronic device 5140 such as a smartphone.

The light-emitting apparatus of one embodiment of the present invention can be used for the display 5101.

A robot 2100 illustrated in FIG. 12B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of detecting a speaking voice of a user, an environmental sound, and the like. The speaker 2104 has a function of outputting sound. The robot 2100 can communicate with a user by using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 12C is a diagram illustrating an example of a goggle-type display. The goggle-type display includes, for example, a housing 5000, a display portion 5001, a speaker 5003, an LED lamp 5004, operation keys (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, flow rate, humidity, gradient, oscillation, odor, or infrared ray), a microphone 5008, a display portion 5002, a support 5012, and an earphone 5013.

The light-emitting apparatus of one embodiment of the present invention can be used for the display portion 5001 and the display portion 5002.

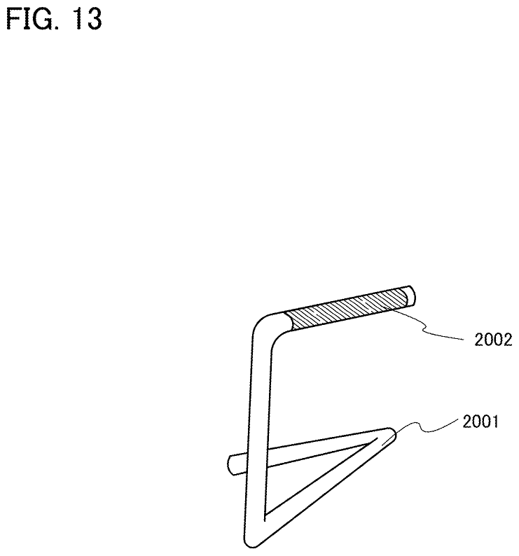

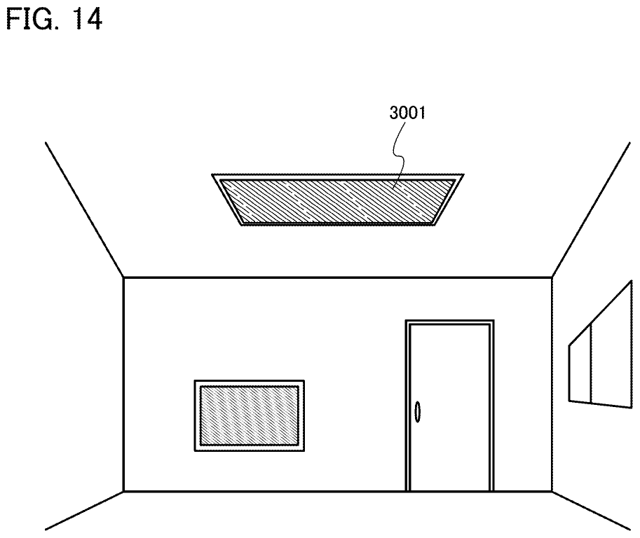

FIG. 13 shows an example where the light-emitting device described in any one of Embodiment 1 to Embodiment 6 is used for a table lamp which is a lighting device. The table lamp illustrated in FIG. 13 includes a housing 2001 and a light source 2002, and the lighting device described in Embodiment 10 may be used for the light source 2002.

FIG. 14 shows an example where the light-emitting device described in any one of Embodiment 1 to Embodiment 6 is used for an indoor lighting device 3001. Since the light-emitting device described in any one of Embodiment 1 to Embodiment 6 is a light-emitting device with high emission efficiency, the lighting device can have low power consumption. In addition, the light-emitting device described in any one of Embodiment 1 to Embodiment 6 can have a larger area, and thus can be used for a large-area lighting device. Furthermore, the light-emitting device described in any one of Embodiment 1 to Embodiment 6 is thin, and thus can be used for a lighting device having a reduced thickness.

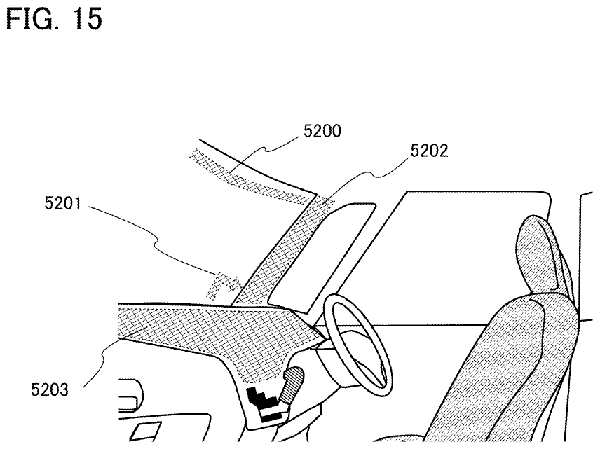

The light-emitting device described in any one of Embodiment 1 to Embodiment 6 can also be incorporated in a windshield or a dashboard of an automobile. FIG. 15 illustrates one mode in which the light-emitting device described in any one of Embodiment 1 to Embodiment 6 is used for a windshield or a dashboard of an automobile. A display region 5200 to a display region 5203 are each a display region provided using the light-emitting device described in any one of Embodiment 1 to Embodiment 6.

The display region 5200 and the display region 5201 are display apparatuses provided in the automobile windshield, in which the light-emitting devices described in any one of Embodiment 1 to Embodiment 6 are incorporated. When the light-emitting devices described in any one of Embodiment 1 to Embodiment 6 are fabricated using electrodes having light-transmitting properties as a first electrode and a second electrode, what is called see-through display apparatuses, through which the opposite side can be seen, can be obtained. Such see-through display apparatuses can be provided even in the automobile windshield without hindering the view. Note that in the case where a driving transistor or the like is provided, a transistor having a light-transmitting property, such as an organic transistor using an organic semiconductor material or a transistor using an oxide semiconductor, is preferably used.

The display region 5202 is a display apparatus provided in a pillar portion, in which the light-emitting devices described in any one of Embodiment 1 to Embodiment 6 are incorporated. The display region 5202 can compensate for the view hindered by the pillar by displaying an image taken by an imaging unit provided in the car body. Similarly, the display region 5203 provided in the dashboard portion can compensate for the view hindered by the car body by displaying an image taken by an imaging unit provided on the outside of the automobile; thus, blind areas can be eliminated to enhance the safety. Images that compensate for the areas that a driver cannot see enable the driver to ensure safety easily and comfortably.

The display region 5203 can provide a variety of kinds of information by displaying navigation data, speed, revolutions, a mileage, a fuel level, a gearshift state, air-condition setting, and the like. The content or layout of the display can be changed freely in accordance with the preference of a user. Note that such information can also be displayed on the display region 5200 to the display region 5202. The display region 5200 to the display region 5203 can also be used as lighting devices.

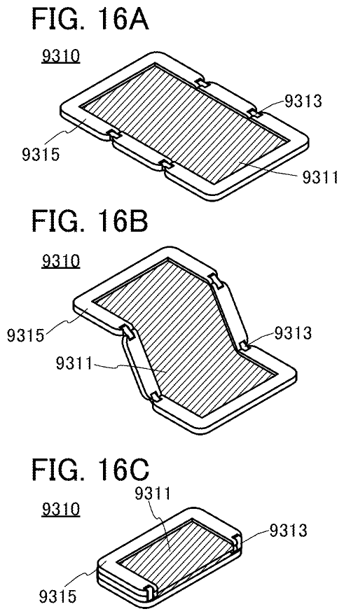

FIG. 16A to FIG. 16C illustrate a foldable portable information terminal 9310. FIG. 16A illustrates the portable information terminal 9310 that is opened. FIG. 16B illustrates the portable information terminal 9310 that is in the state of being changed from one of an opened state and a folded state to the other. FIG. 16C illustrates the portable information terminal 9310 that is folded. The portable information terminal 9310 is excellent in portability when folded, and is excellent in display browsability when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

Note that the structures described in this embodiment can be combined with the structures described in any of Embodiment 1 to Embodiment 6 as appropriate.

As described above, the application range of the light-emitting apparatus including the light-emitting device described in any one of Embodiment 1 to Embodiment 6 is wide, so that this light-emitting apparatus can be applied to electronic devices in a variety of fields. With the use of the light-emitting device described in any one of Embodiment 1 to Embodiment 6, an electronic device with low power consumption can be obtained.

Note that this embodiment can be combined with any of the other embodiments described in this specification as appropriate.

### Example 1

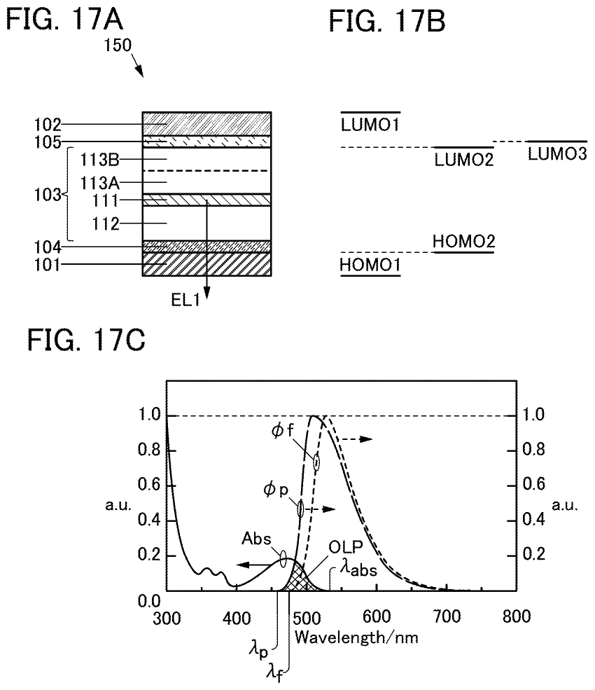

In this example, a light-emitting device 222(22) of one embodiment of the present invention is described with reference to FIG. 17 to FIG. 45. Note that in the tables in this example, subscript and superscript characters are written in ordinary size for convenience. For example, a subscript character in an abbreviation or a superscript character in a unit are written in ordinary size in the tables. The corresponding description in the specification gives an accurate reading of such notations in the tables.

FIG. 17A to FIG. 17C are diagrams showing the structure of the light-emitting device 150.

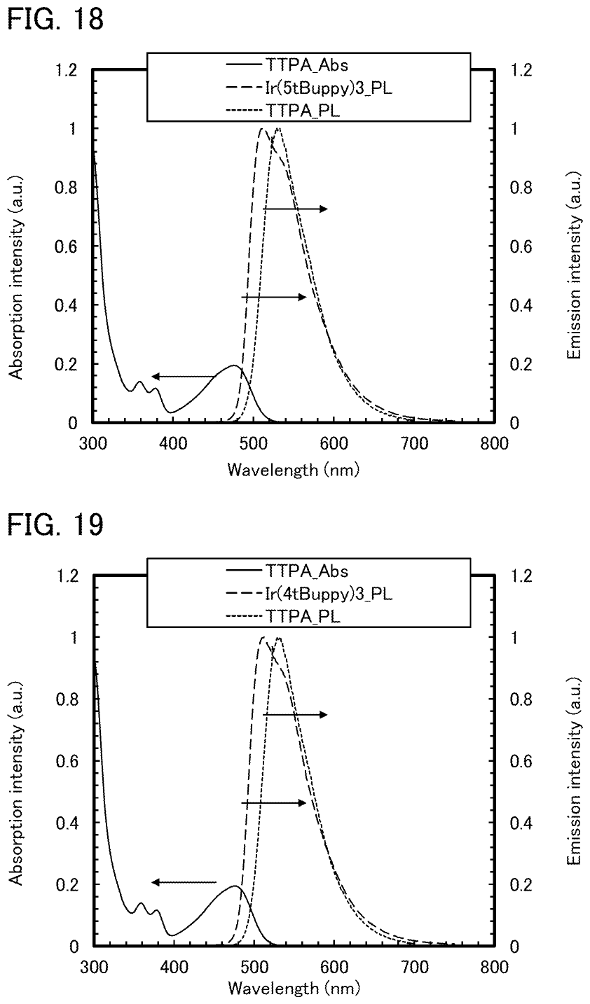

FIG. 18 is a graph showing an absorption spectrum of TTPA, an emission spectrum of Ir(5tBuppy)₃, and an emission spectrum of TTPA.

FIG. 19 is a graph showing an absorption spectrum of TTPA, an emission spectrum of Ir(4tBuppy)₃, and an emission spectrum of TTPA.

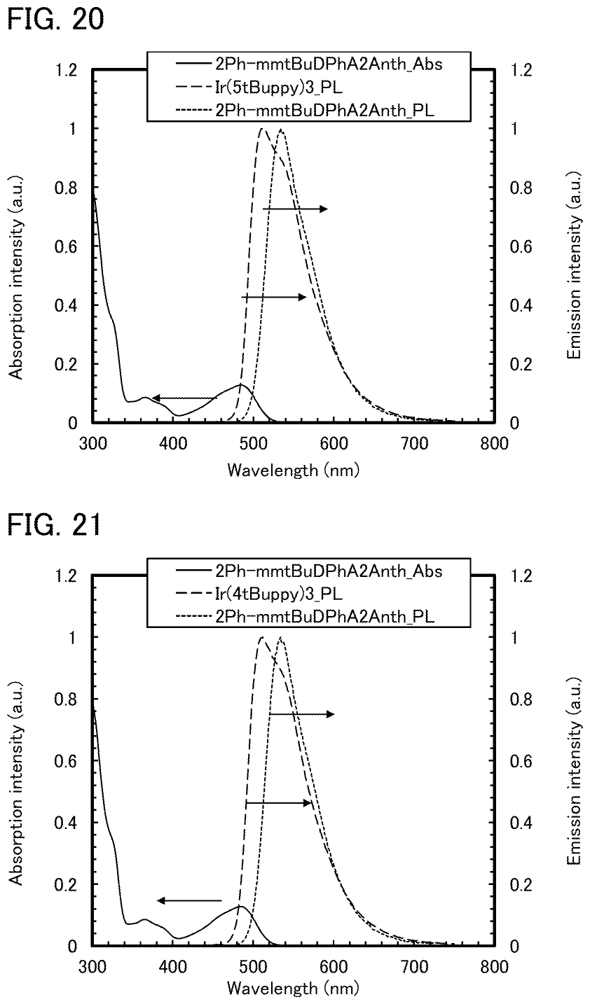

FIG. 20 is a graph showing an absorption spectrum of 2Ph-mmtBuDPhA2Anth, an emission spectrum of Ir(5tBuppy)₃, and an emission spectrum of 2Ph-mmtBuDPhA2Anth.

FIG. 21 is a graph showing an absorption spectrum of 2Ph-mmtBuDPhA2Anth, an emission spectrum of Ir(4tBuppy)₃, and an emission spectrum of 2Ph-mmtBuDPhA2Anth.

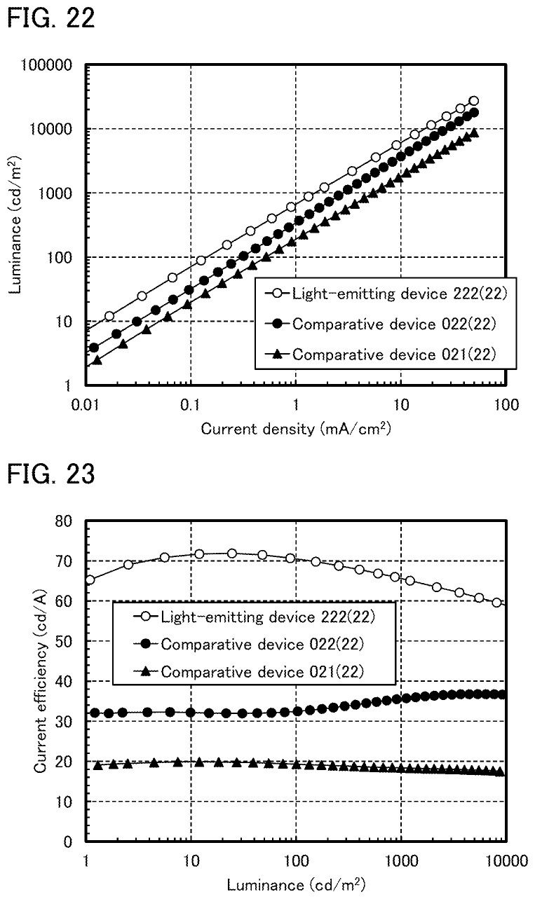

FIG. 22 is a graph showing current density-luminance characteristics of the light-emitting device 222(22).

FIG. 23 is a graph showing luminance-current efficiency characteristics of the light-emitting device 222(22).

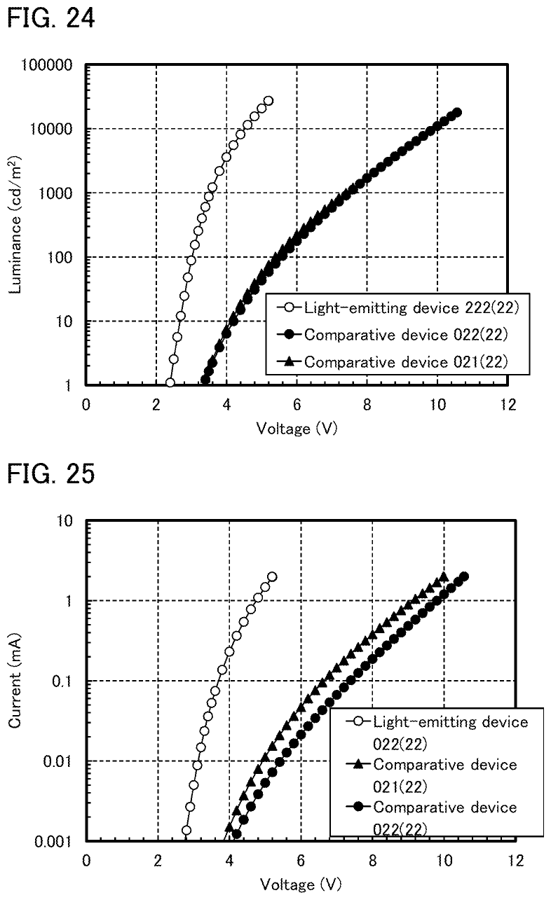

FIG. 24 is a graph showing voltage-luminance characteristics of the light-emitting device 222(22).

FIG. 25 is a graph showing voltage-current characteristics of the light-emitting device 222(22).

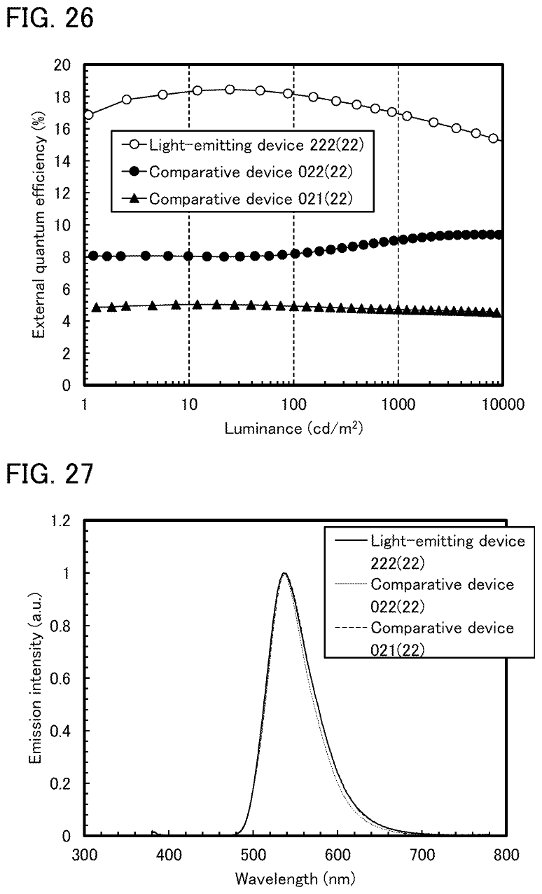

FIG. 26 is a graph showing luminance-external quantum efficiency characteristics of the light-emitting device 222(22). Note that the external quantum efficiency was calculated from luminance assuming that the light distribution characteristics of the light-emitting device are Lambertian type.

FIG. 27 is a graph showing an emission spectrum of the light-emitting device 222(22) emitting light at a luminance of 1000 cd/m².

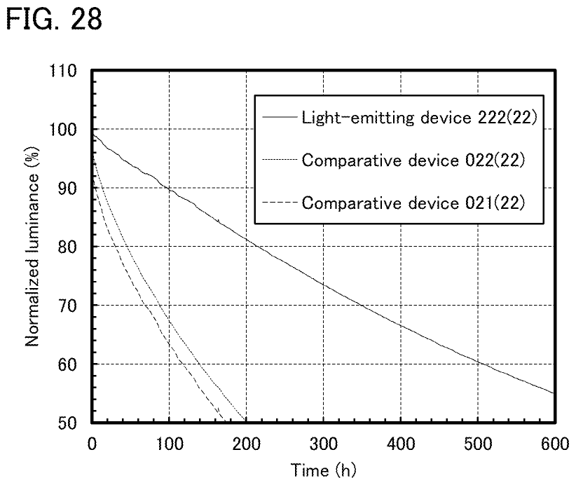

FIG. 28 is a graph showing normalized luminance-temporal change characteristics of the light-emitting device 222(22) emitting light at a constant current density of 50 mA/cm².

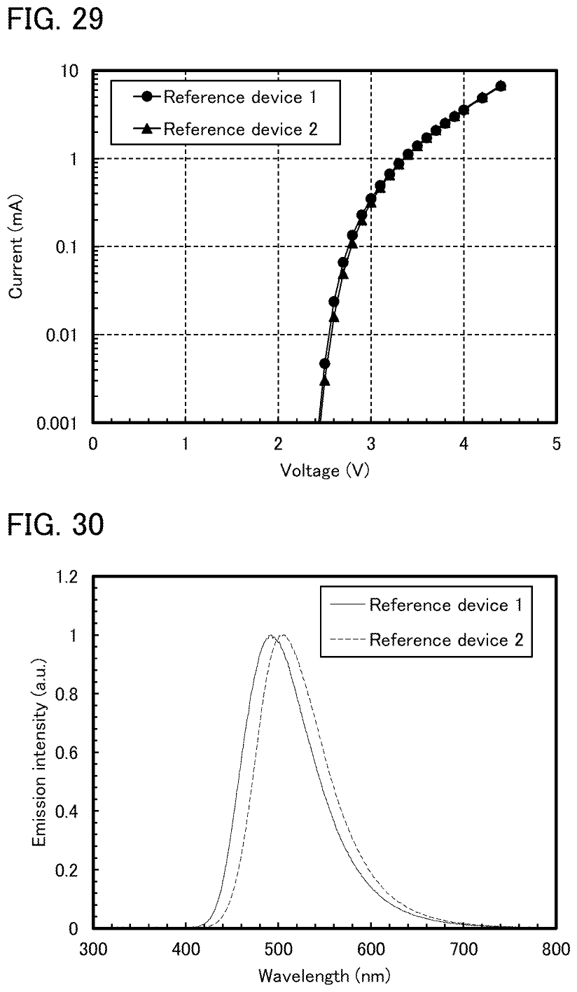

FIG. 29 is a graph showing voltage-current characteristics of reference devices.

FIG. 30 is a graph showing emission spectra of the reference devices each emitting light at a current density of 2.5 mA/cm².

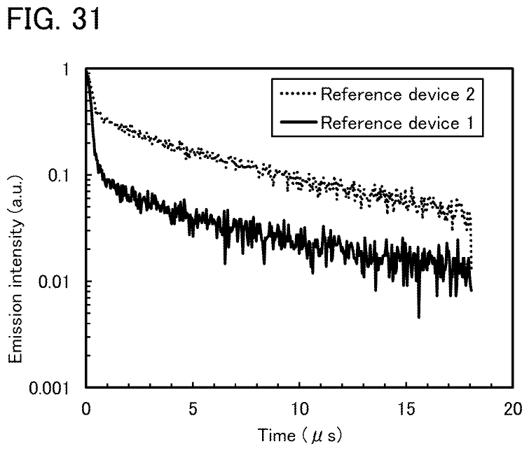

FIG. 31 is a graph showing changes in emission intensity of the light-emitting devices each operating in pulse driving at a voltage enabling 1300 cd/m².

### <Light-Emitting Device 222(22)>

The fabricated light-emitting device 222(22) described in this example, has a structure similar to that of the light-emitting device 150 (see FIG. 17A).

The light-emitting device 150 includes the electrode 101, the electrode 102, and the layer 111 (see FIG. 17A). The electrode 102 includes a region overlapping with the electrode 101, and the layer 111 is positioned between the electrode 101 and the electrode 102.

The layer 111 contains a light-emitting material FM, an energy donor material ED, and a host material.

The light-emitting material FM has a function of emitting fluorescent light, and an absorption spectrum Abs of the light-emitting material FM has the longest-wavelength edge at a wavelength λabs (nm) (see FIG. 17C).

An organometallic complex is used as the energy donor material ED, the organometallic complex has a ligand, the ligand has a substituent R¹, and the substituent R¹ is any of an alkyl group, a cycloalkyl group, and a trialkylsilyl group. Note that the number of carbon atoms of the alkyl group is 3 to 12, the number of carbon atoms forming a ring of the cycloalkyl group is 3 to 10, and the number of carbon atoms of the trialkylsilyl group is 3 to 12.

The organometallic complex has a function of emitting phosphorescent light at room temperature, the spectrum of the phosphorescent light has the shortest-wavelength edge at a wavelength λp (nm), and the wavelength λp is positioned at a wavelength shorter than the wavelength λabs.

The organometallic complex has a first HOMO level HOMO1 and a first LUMO level LUMO1 (see FIG. 17B).

The host material has a function of emitting delayed fluorescent light at room temperature, and the host material has a second HOMO level HOMO2 and a second LUMO level LUMO2.

The first HOMO level HOMO1, the first LUMO level LUMO1, the second HOMO level HOMO2 and the second LUMO level LUMO2 satisfy the following formula (1).

[Formula 7]

(LUMO2−HOMO2)<(LUMO1−HOMO1) (1)

### <<Structure of Light-Emitting Device 222(22)>>

Table 1 shows the structure of the light-emitting device 222(22). The structure formulae, HOMO levels, and LUMO levels of materials used for the light-emitting device described in this example are shown below.

The absorption spectrum of 2Ph-mmtBuDPhA2Anth used as the light-emitting material FM of the light-emitting device 222(22) has the longest-wavelength edge at a wavelength of 519 nm (see FIG. 20). Note that the absorption spectrum of the light-emitting material FM in the toluene solution was measured at room temperature with the use of an ultraviolet-visible spectrophotometer (V550, produced by JASCO Corporation).

Ir(5tBuppy)₃ used as the organometallic complex of the light-emitting device 222(22) has a function of emitting phosphorescent light. The spectrum of the phosphorescent light has the shortest-wavelength edge at a wavelength of 484 nm, and the edge is positioned at a wavelength shorter than the wavelength of 519 nm. Furthermore, Ir(5tBuppy)₃ has the first HOMO level HOMO1 at −5.32 eV and the first LUMO level LUMO1 at −2.25 eV. Note that the phosphorescent spectrum of the dichloromethane solution of the organometallic complex was measured at room temperature with the use of a fluorescence spectrophotometer (FP-8600, produced by JASCO Corporation). The HOMO level and the LUMO level of the organometallic complex were calculated from the oxidation potential and the reduction potential obtained by cyclic voltammetry (CV) measurement with the use of an electrochemical analyzer (ALS model 600A or 600C, produced by BAS Inc.).

The material used as the host material of the light-emitting device 222(22) has a function of emitting delayed fluorescent light. Specifically, mPCCzPTzn-02 emits delayed fluorescent light. The material has the second HOMO level HOMO2 at −5.69 eV and the second LUMO level LUMO2 at −3.00 eV (see Table 2). Note that the HOMO level and the LUMO level of the host material were calculated from the oxidation potential and the reduction potential obtained by cyclic voltammetry (CV) measurement with the use of an electrochemical analyzer (ALS model 600A or 600C, produced by BAS Inc.).

Note that the value of (LUMO2−HOMO2) is 2.69 eV, which is smaller than 3.07 eV that is the value of (LUMO1−HOMO1).

TABLE 1

| | Reference | | Composition | Thick- |
|---|---|---|---|---|
| Structure | numeral | Material | ratio | ness/nm |
| Electrode | 102 | Al | | 200 |
| layer | 105 | LiF | | 1 |
| layer | 113B | TmPyPB | | 10 |
| layer | 113A | 35DCzPPy | | 20 |
| layer | 111 | mPCCzPTzn- | 1:0.1:0.05 | 40 |
| | | 02:Ir(5tBuppy)3:2Ph- | | |
| | | mmtBuDPhA2Anth | | |
| layer | 112 | mCzFLP | | 20 |
| layer | 104 | DBT3PII:MoOx | 1:0.5 | 40 |
| Electrode | 101 | ITSO | | 70 |

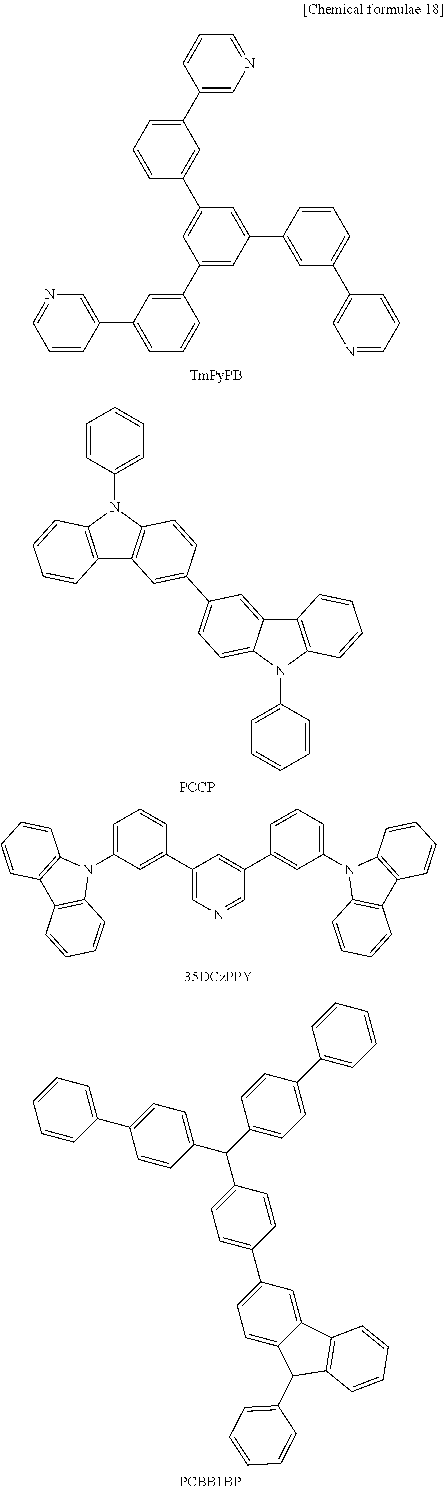

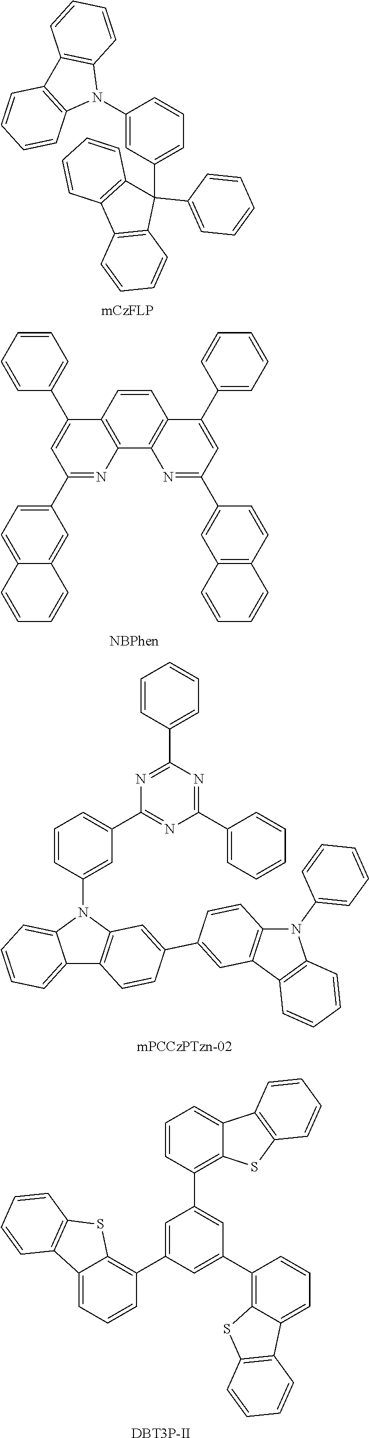 [SMILES: c1ccc(C2(c3cccc(-n4c5ccccc5c5ccccc54)c3)c3ccccc3-c3ccccc32)cc1 ; c1ccc(-c2cc(-c3ccc4ccccc4c3)nc3c2ccc2c(-c4ccccc4)cc(-c4ccc5ccccc5c4)nc23)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc2c(c1)sc1c(-c3cc(-c4cccc5c4sc4ccccc45)cc(-c4cccc5c4sc4ccccc45)c3)cccc12 ; "DBT3P-II"]

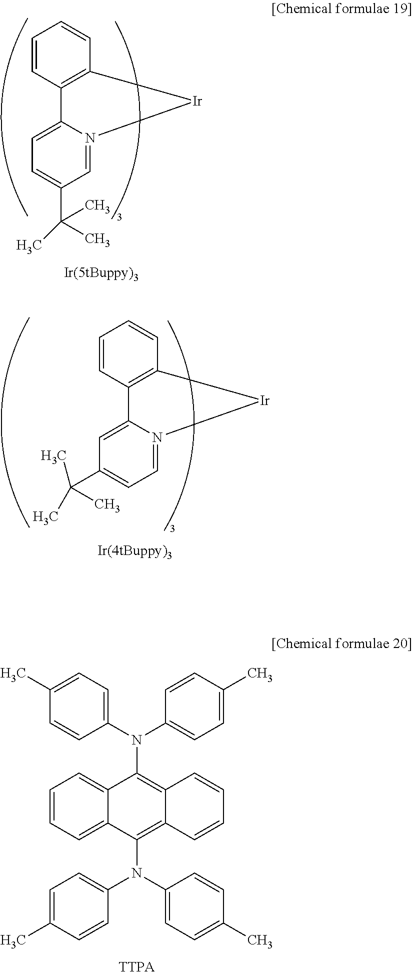

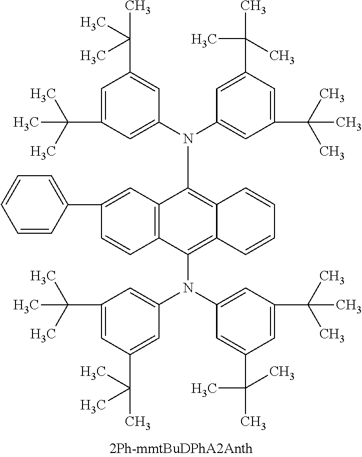 [SMILES: CC(C)(C)c1cc(N(c2cc(C(C)(C)C)cc(C(C)(C)C)c2)c2c3ccccc3c(N(c3cc(C(C)(C)C)cc(C(C)(C)C)c3)c3cc(C(C)(C)C)cc(C(C)(C)C)c3)c3cc(-c4ccccc4)ccc23)cc(C(C)(C)C)c1]

TABLE 2

| | HOMO/ | LUMO/ | ΔE/ |
|---|---|---|---|
| | eV | eV | eV |
| mPCCzPTzn-02 | −5.69 | −3.00 | 2.69 |
| PCCP | −5.63 | −1.96 | 3.67 |
| mCBP | −5.93 | −2.22 | 3.71 |
| Ir(4tBuppy)3 | −5.26 | −2.25 | 3.01 |
| Ir(5tBuppy)3 | −5.32 | −2.25 | 3.07 |
| Ir(ppy)3 | −5.32 | −2.31 | 3.01 |
| TTPA | −5.34 | −2.88 | 2.46 |
| 2Ph-mmtBuDPhA2Anth | −5.35 | −2.87 | 2.48 |

### <<Fabrication Method of Light-Emitting Device 222(22)>>

The light-emitting device 222(22) described in this example was fabricated by a method including the following steps.

### [First Step]

In the first step, the electrode 101 was formed. Specifically, the electrode 101 was formed by a sputtering method using indium oxide-tin oxide containing silicon or silicon oxide (abbreviation: ITSO) as a target.

The electrode 101 contains ITSO and has a thickness of 70 nm and an area of 4 mm² (2 mm×2 mm).

Next, a substrate over which the electrode 101 was formed was washed with water, baked at 200° C. for an hour, and then subjected to UV ozone treatment for 370 seconds. After that, the substrate was transferred into a vacuum evaporation apparatus where the pressure was reduced to approximately 10-4 Pa, and vacuum baking was performed at 170° C. for 30 minutes in a heating chamber of the vacuum evaporation apparatus. Then, the substrate was cooled down for approximately 30 minutes.

### [Second Step]

In the second step, the layer 104 was formed over the electrode 101. Specifically, materials were co-deposited by a resistance-heating method.

Note that the layer 104 contains 4,4′,4″-(benzene-1,3,5-triyl)tri(dibenzothiophene) (abbreviation: DBT3P-II) and molybdenum(VI) oxide (abbreviation: MoO₃) at DBT3P-II:MoO₃=1:0.5 (weight ratio) and has a thickness of 40 nm.

### [Third Step]

In the third step, the layer 112 was formed over the layer 104. Specifically, the material was deposited by a resistance-heating method.

Note that the layer 112 contains 9-[3-(9-phenyl-9H-fluoren-9-yl)phenyl]-9H-carbazole (abbreviation: mCzFLP) and has a thickness of 20 nm.

### [Fourth Step]

In the fourth step, the layer 111 was formed over the layer 112. Specifically, the materials were co-deposited by a resistance-heating method.

Note that the layer 111 contains 9-[3-(4,6-diphenyl-1,3,5-triazin-2-yl)phenyl]-9′-phenyl-2,3′-bi-9H-carbazole (abbreviation: mPCCzPTzn-02), tris[2-[5-(tert-butyl)-2-pyridinyl-κN]phenyl-κC]iridium (abbreviation: Ir(5tBuppy)₃), and N,N′-bis(3,5-di-tert-butylphenyl)-N,N′-bis[3,5-bis(3,5-di-tert-butylphenyl)phenyl]-2-phenylanthracene-9,10-diamine (abbreviation: 2Ph-mmtBuDPhA2Anth) at mPCCzPTzn-02:Ir(5tBuppy)₃:2Ph-mmtBuDPhA2Anth=1:0.1:0.05 (weight ratio) and has a thickness of 40 nm. Note that mPCCzPTzn-02 is a substance exhibiting thermally activated delayed fluorescence.

TABLE 3

| | HOST | ED | FM |
|---|---|---|---|
| Light-emitting | mPCCzPTzn-02 | Ir(5tBuppy)3 | 2Ph- |
| device 222(22) | | | mmtBuDPhA2Anth |
| Comparative | mCBP | Ir(5tBuppy)3 | TTPA |
| device 021(22) | | | |
| Comparative | mCBP | Ir(5tBuppy)3 | 2Ph- |
| device 022(22) | | | mmtBuDPhA2Anth |

### [Fifth Step]

In the fifth step, the layer 113A was formed over the layer 111. Specifically, the material was deposited by a resistance-heating method.

Note that the layer 113A contains 3,5-bis[3-(9H-carbazol-9-yl)phenyl]pyridine (abbreviation: 35DCzPPy) and has a thickness of 20 nm.

### [Sixth Step]

In the sixth step, the layer 113B was formed over the layer 113A. Specifically, the material was deposited by a resistance-heating method.

Note that the layer 113B contains 1,3,5-tri[3-(3-pyridyl)phenyl]benzene (abbreviation: TmPyPB) and has a thickness of 10 nm.

### [Seventh Step]

In the seventh step, the layer 105 was formed over the layer 113B. Specifically, the material was deposited by a resistance-heating method.

Note that the layer 105 contains lithium fluoride (abbreviation: LiF) and has a thickness of 1 nm.

### [Eighth Step]

In the eighth step, the electrode 102 was formed over the layer 105. Specifically, the material was deposited by a resistance-heating method.

Note that the electrode 102 contains aluminum (abbreviation: Al) and has a thickness of 200 nm.

### <<Operation Characteristics of Light-Emitting Device 222(22)>>

When supplied with electric power, the light-emitting device 222(22) emitted green light EL1 (see FIG. 17A). The operation characteristics of the light-emitting device 222(22) were measured (see FIG. 22 to FIG. 27). The luminance, CIE chromaticity, and emission spectra were measured at room temperature with a spectroradiometer (SR-UL1R manufactured by TOPCON TECHNOHOUSE CORPORATION).

Table 4 shows main initial characteristics of the fabricated light-emitting devices emitting light at a luminance of approximately 1000 cd/m². Table 4 also shows a time LT90 taken for the luminance to drop to 90% of its initial value at a constant current density (50 mA/cm²), which were obtained under the condition where the light-emitting devices each emitted light. Table 4 also shows the characteristics of other light-emitting devices having structures described later.

TABLE 4

| | | | | | | | External | LT90 |
|---|---|---|---|---|---|---|---|---|
| | | | Current | | | Current | quantum | @50 mA/ |
| | Voltage | Current | density | Chromaticity | Chromaticity | efficiency | efficiency | cm2 |
| | (V) | (mA) | (mA/cm2) | x | y | (cd/A) | (%) | (h) |
| Light-emitting device 222(22) | 3.5 | 0.05 | 1.3 | 0.35 | 0.62 | 66.0 | 17.0 | 97.0 |
| Light-emitting device 321(22) | 3.0 | 0.08 | 2.0 | 0.38 | 0.60 | 44.2 | 11.5 | 194.2 |
| Light-emitting device 331(22) | 3.1 | 0.11 | 2.8 | 0.37 | 0.61 | 39.8 | 10.4 | 192.0 |
| Light-emitting device 322(22) | 2.8 | 0.04 | 1.0 | 0.35 | 0.62 | 78.6 | 20.1 | 196.0 |
| Light-emitting device 332(22) | 2.9 | 0.05 | 1.4 | 0.35 | 0.62 | 81.9 | 20.9 | 142.0 |
| Comparative device 022(22) | 7.4 | 0.10 | 2.6 | 0.34 | 0.63 | 35.5 | 9.0 | 13.7 |
| Comparative device 021(22) | 7.4 | 0.22 | 5.5 | 0.35 | 0.62 | 18.3 | 4.7 | 4.3 |
| Comparative device 311(22) | 3.5 | 0.11 | 2.7 | 0.38 | 0.60 | 35.7 | 9.3 | 174.2 |
| Comparative device 312(22) | 3.4 | 0.06 | 1.5 | 0.35 | 0.62 | 59.3 | 15.1 | 115.0 |

The light-emitting device 222(22) was found to exhibit favorable characteristics. For example, the light-emitting device 222(22) emitted light with an emission spectrum derived from the light-emitting material FM, having a peak wavelength at approximately 540 nm (see FIG. 27). Light emission derived from the energy donor material ED was not observed. Alternatively, energy was transferred from the energy donor material ED to the light-emitting material FM. Undesirable energy transfer from the energy donor material ED to the light-emitting material FM was able to be inhibited. Energy transfer from the energy donor material ED to the light-emitting material FM by the Dexter mechanism was able to be inhibited.

The light-emitting device 222(22) was able to achieve a luminance of approximately 1000 cd/m² at a voltage lower than those of the comparative device 022(22) and the comparative device 021(22) (see Table 4). Furthermore, the light-emitting device 222(22) exhibited higher external quantum efficiency than the comparative device 022(22). Moreover, the light-emitting device 222(22) exhibited higher external quantum efficiency than the comparative device 021(22).

The light-emitting device 222(22) took a longer time for the luminance to drop to 90% of its initial value than the comparative device 022(22) under the condition where light was emitted at a constant current density of 50 mA/cm².

### Reference Example 1

The fabricated comparative device 022(22) described in this reference example is different from the light-emitting device 222(22) in that 3,3′-9H-carbazol-9-yl-biphenyl (abbreviation: mCBP) is used as the host material instead of mPCCzPTzn-02. The fabricated comparative device 021(22) described in this reference example is different from the light-emitting device 222(22) in that mCBP is used as the host material instead of mPCCzPTzn-02 and that N,N,V,N-tetrakis(4-methylphenyl)-9,10-anthracenediamine (abbreviation: TTPA) is used as the light-emitting material FM instead of 2Ph-mmtBuDPhA2Anth.

<<Structure of comparative device 022(22)>>

Table 5 shows the structure of the fabricated comparative device 022(22) described in this reference example. Note that the comparative device 022(22) is different from the light-emitting device 222(22) in that mCBP is used as the host material.

The mCBP used as the host material of the light-emitting device 022(22) does not emit delayed fluorescent light. The material has the second HOMO level HOMO2 at −5.93 eV and the second LUMO level LUMO2 at −2.22 eV (see Table 2). Note that the HOMO level and the LUMO level of the host material were calculated from the oxidation potential and the reduction potential obtained by cyclic voltammetry (CV) measurement with the use of an electrochemical analyzer (ALS model 600A or 600C, produced by BAS Inc.).

Note that the value of (LUMO2−HOMO2) is 3.71 eV, which is larger than 3.07 eV that is the value of (LUMO1−HOMO1).

TABLE 5

| | Reference | | Composition | Thick- |
|---|---|---|---|---|
| Structure | numeral | Material | ratio | ness/nm |
| Electrode | 102 | Al | | 200 |
| layer | 105 | LiF | | 1 |
| layer | 113B | TmPyPB | | 10 |
| layer | 113A | 35DCzPPy | | 20 |
| layer | 111 | mCBP:Ir(5tBuppy)3:2Ph- | 1:0.1:0.05 | 40 |
| | | mmtBuDPhA2Anth | | |
| layer | 112 | mCzFLP | | 20 |
| layer | 104 | DBT3PII:MoOx | 1:0.5 | 40 |
| Electrode | 101 | ITSO | | 70 |

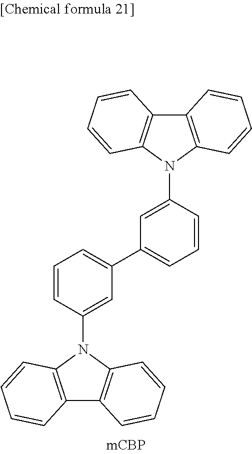 [SMILES: c1cc(-c2cccc(-n3c4ccccc4c4ccccc43)c2)cc(-n2c3ccccc3c3ccccc32)c1]

### <<Fabrication Method of Comparative Device 022(22)>>

The light-emitting device 022(22) described in this example was fabricated by a method including the following steps.

Note that the fabrication method of the light-emitting device 022(22) is different from the fabrication method of the light-emitting device 222(22) in that mCBP is used as the host material instead of mPCCzPTzn-02 in the step of forming the layer 111. Different portions are described in detail here, and the above description is referred to for portions formed by a similar method.

### [Fourth Step]

In the fourth step, the layer 111 was formed over the layer 112. Specifically, the materials were co-deposited by a resistance-heating method.

Note that the layer 111 contains mCBP, Ir(5tBuppy)₃, and 2Ph-mmtBuDPhA2Anth at mCBP:Ir(5tBuppy)₃:2Ph-mmtBuDPhA2Anth=1:0.1:0.05 (weight ratio) and has a thickness of 40 nm (see Table 3).

### <<Structure of Comparative Device 021(22)>>

The fabricated comparative device 021(22) described in this reference example is different from the light-emitting device 222(22) in that mCBP is used as the host material and that TTPA is used as the light-emitting material FM instead of 2Ph-mmtBuDPhA2Anth.

The mCBP used as the host material of the light-emitting device 022(22) does not emit delayed fluorescent light. The material has the second HOMO level HOMO2 at −5.93 eV and the second LUMO level LUMO2 at −2.22 eV (see Table 2).

Note that the value of (LUMO2−HOMO2) is 3.71 eV, which is larger than 3.07 eV that is the value of (LUMO1−HOMO1).

Furthermore, TTPA used as the light-emitting material FM of the light-emitting device 021(22) has a second substituent R². The second substituent R² is a methyl group.

### <<Fabrication Method of Comparative Device 021(22)>>

The light-emitting device 021(22) described in this example was fabricated by a method including the following steps.

Note that the fabrication method of the light-emitting device 021(22) is different from the fabrication method of the light-emitting device 222(22) in that mCBP is used as the host material instead of mPCCzPTzn-02 and that TTPA is used as the light-emitting material FM instead of 2Ph-mmtBuDPhA2Anth in the step of forming the layer 111. Different portions are described in detail here, and the above description is referred to for portions formed by a similar method.

[Fourth step]In the fourth step, the layer 111 was formed over the layer 112. Specifically, the materials were co-deposited by a resistance-heating method.

Note that the layer 111 contains mCBP, Ir(5tBuppy)₃, and TTPA at mCBP:Ir(5tBuppy)₃:TTPA=1:0.1:0.05 (weight ratio) and has a thickness of 40 nm (see Table 3).

### Reference Example 2

A fabricated reference device 1 described in this reference example has a structure similar to that of the light-emitting device 150 (see FIG. 17A).

The light-emitting device 150 includes the electrode 101, the electrode 102, and the layer 111. The electrode 102 includes a region overlapping with the electrode 101, and the layer 111 is positioned between the electrode 101 and the electrode 102. The light-emitting device 150 includes the layer 104 and the layer 105.

The layer 111 contains a host material, and the host material has a function of emitting delayed fluorescent light at room temperature.

### <<Structure of Reference Device 1>>

Table 6 shows the structure of the reference device 1. The structure formulae of the materials used in the reference device described in this example are shown below.

TABLE 6

| | Reference | | Composition | Thick- |
|---|---|---|---|---|
| Structure | numeral | Material | ratio | ness/nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn-02 | | 30 |
| Layer | 112 | PCCP | | 20 |
| Layer | 104 | DBT3PII:MoOx | 1:0.5 | 30 |
| Electrode | 101 | ITSO | | 70 |

### <<Fabrication Method of Reference Device 1>>

The reference device 1 described in this example was fabricated by a method including the following steps.

### [First Step]

In the first step, the electrode 101 was formed. Specifically, the electrode 101 was formed by a sputtering method using indium oxide-tin oxide containing silicon or silicon oxide (abbreviation: ITSO) as a target.

The electrode 101 contains ITSO and has a thickness of 70 nm and an area of 4 mm² (2 mm×2 mm).

Next, a substrate over which the electrode 101 was formed was washed with water, baked at 200° C. for an hour, and then subjected to UV ozone treatment for 370 seconds. After that, the substrate was transferred into a vacuum evaporation apparatus where the pressure was reduced to approximately 10⁻⁴ Pa, and vacuum baking was performed at 170° C. for 30 minutes in a heating chamber of the vacuum evaporation apparatus. Then, the substrate was cooled down for approximately 30 minutes.

### [Second Step]

In the second step, the layer 104 was formed over the electrode 101. Specifically, the materials were co-deposited by a resistance-heating method.

Note that the layer 104 contains DBT3P-II and MoO₃ at DBT3P-II:MoO₃=1:0.5 (weight ratio) and has a thickness of 30 nm.

### [Third Step]

In the third step, the layer 112 was formed over the layer 104. Specifically, the material was deposited by a resistance-heating method.

Note that the layer 112 contains 3,3′-bis(9-phenyl-9H-carbazole) (abbreviation: PCCP) and has a thickness of 20 nm.

### [Fourth Step]

In the fourth step, the layer 111 was formed over the layer 112. Specifically, a material was deposited by a resistance-heating method.

Note that the layer 111 contains mPCCzPTzn-02 and has a thickness of 30 nm.

### [Fifth Step]

In the fifth step, the layer 113A was formed over the layer 111. Specifically, a material was deposited by a resistance-heating method.

The layer 113A contains mPCCzPTzn-02 and has a thickness of 20 nm.

### [Sixth Step]

In the sixth step, the layer 113B was formed over the layer 113A. Specifically, the material was deposited by a resistance-heating method.

Note that the layer 113B contains 2,9-bis(naphthalen-2-yl)-4,7-diphenyl-1,10-phenanthroline (abbreviation: NBPhen) and has a thickness of 10 nm.

### [Seventh Step]

In the seventh step, the layer 105 was formed over the layer 113B. Specifically, the material was deposited by a resistance-heating method.

The layer 105 contains LiF and has a thickness of 1 nm.

### [Eighth Step]

In the eighth step, the electrode 102 was formed over the layer 105. Specifically, the material was deposited by a resistance-heating method.

The electrode 102 contains Al and has a thickness of 200 nm.

### <<Operation Characteristics of Reference Device 1>>

When supplied with electric power, the reference device 1 emitted light EL1 (see FIG. 17A). The operation characteristics of the reference device 1 were measured (see FIG. 29 and FIG. 30). Note that the luminance and the CIE chromaticity were measured with a luminance colorimeter (BM-5A produced by TOPCON TECHNOHOUSE CORPORATION) and the emission spectrum was measured with a multi-channel spectrometer (PMA-11 produced by Hamamatsu Photonics K.K.) at room temperature.

Delayed fluorescent light was measured with the use of a picosecond fluorescence lifetime measurement system (produced by Hamamatsu Photonics K.K.). Specifically, a voltage corresponding to a condition enabling 1300 cd/m² was applied to the reference device 1, a predetermined voltage was kept in a rectangular pulse form during 100 s, and attenuation of delayed fluorescent light was observed during 20 s. Furthermore, a negative bias, −5 V, was applied during a period of observing the attenuation of the delayed fluorescence. The measurement was repeated at a cycle of 10 Hz, and then obtained data was added up. FIG. 31 shows the emission intensity of the reference device 1 in pulse driving at a predetermined voltage.

Holes supplied from the electrode 101 and electrons supplied from the electrode 102 were recombined in the layer 111, and light emission was obtained from the host material in the resulting generated excited state, specifically, mPCCzPTzn-02 in an excited state (see FIG. 30). In addition, at least light emission from excitons having a short lifetime of 0.3 μs or less and light emission from excitons having a long lifetime of 6 μs were observed (see FIG. 31). Thus, it was found that singlet excitons were generated through triplet excitons having a long lifetime.

### Example 2

In this example, a light-emitting device 321(22) to a light-emitting device 332(22) of one embodiment of the present invention are described with reference to FIG. 17 and FIG. 32 to FIG. 38. Note that in the tables in this example, subscript and superscript characters are written in ordinary size for convenience. For example, a subscript character in an abbreviation or a superscript character in a unit are written in ordinary size in the tables. The corresponding description in the specification gives an accurate reading of such notations in the tables.

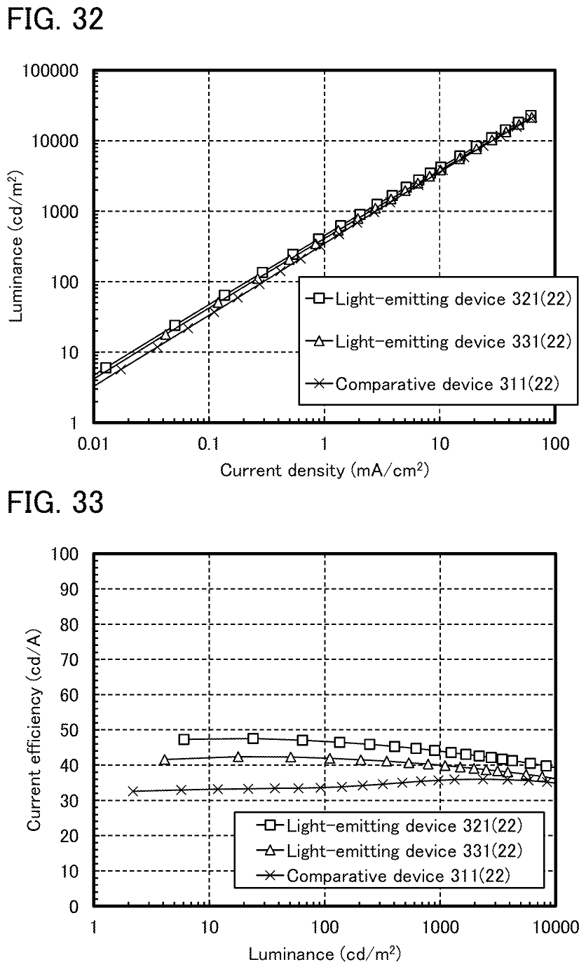

FIG. 32 is a graph showing current density-luminance characteristics of the light-emitting device 321(22) and the light-emitting device 331(22).

FIG. 33 is a graph showing luminance-current efficiency characteristics of the light-emitting device 321(22) and the light-emitting device 331(22).

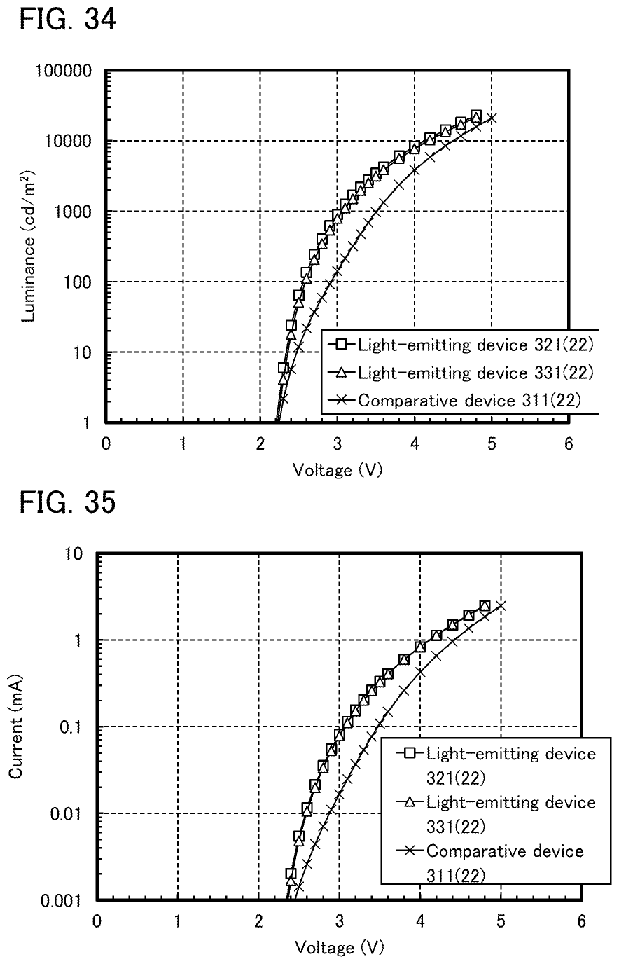

FIG. 34 is a graph showing voltage-luminance characteristics of the light-emitting device 321(22) and the light-emitting device 331(22).

FIG. 35 is a graph showing voltage-current characteristics of the light-emitting device 321(22) and the light-emitting device 331(22).

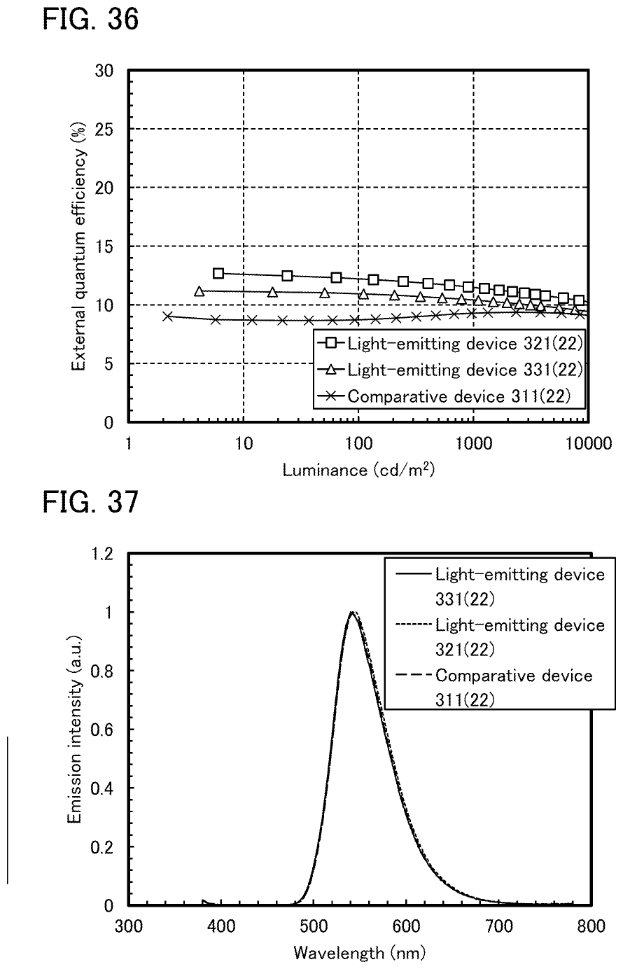

FIG. 36 is a graph showing luminance-external quantum efficiency characteristics of the light-emitting device 321(22) and the light-emitting device 331(22). Note that the external quantum efficiency was calculated from luminance assuming that the light distribution characteristics of the light-emitting devices are Lambertian type.

FIG. 37 is a graph showing emission spectra of the light-emitting device 321(22) and the light-emitting device 331(22) each emitting light at a luminance of 1000 cd/m².

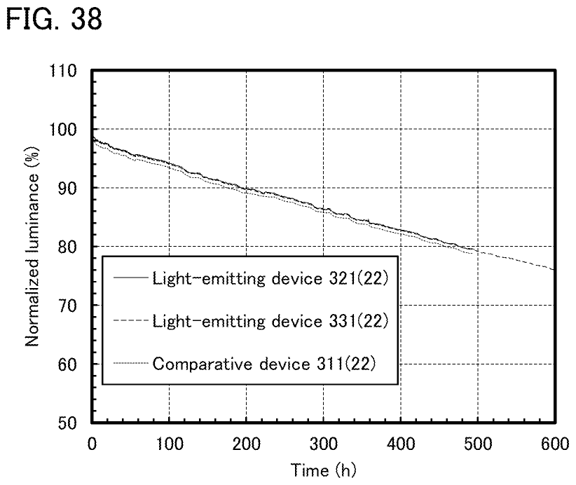

FIG. 38 is a graph showing normalized luminance-temporal change characteristics of the light-emitting device 321(22) and the light-emitting device 331(22) each emitting light at a constant current density of 50 mA/cm².

### <Light-Emitting Device 321(22)>

The fabricated light-emitting device 321(22) described in this example has a structure similar to that of the light-emitting device 150 (see FIG. 17A).

The light-emitting device 150 includes the electrode 101, the electrode 102, and the layer 111 (see FIG. 17A). The electrode 102 includes a region overlapping with the electrode 101, and the layer 111 is positioned between the electrode 101 and the electrode 102.

The layer 111 contains a light-emitting material FM, an energy donor material ED, and a host material.

The light-emitting material FM has a function of emitting fluorescent light, and an absorption spectrum Abs of the light-emitting material FM has the longest-wavelength edge at a wavelength λabs (nm) (see FIG. 17C).

An organometallic complex is used as the energy donor material ED, the organometallic complex has a ligand, the ligand has a substituent R¹, and the substituent R¹ is any of an alkyl group, a cycloalkyl group, and a trialkylsilyl group. Note that the number of carbon atoms of the alkyl group is 3 to 12, the number of carbon atoms forming a ring of the cycloalkyl group is 3 to 10, and the number of carbon atoms of the trialkylsilyl group is 3 to 12.

The organometallic complex has a function of emitting phosphorescent light at room temperature, the spectrum of the phosphorescent light has the shortest-wavelength edge at a wavelength λp (nm), and the wavelength λp is positioned at a wavelength shorter than the wavelength λabs.

The organometallic complex has a first HOMO level HOMO1 and a first LUMO level LUMO1 (see FIG. 17B).

The host material has a function of emitting delayed fluorescent light at room temperature, and the host material has a second HOMO level HOMO2 and a second LUMO level LUMO2.

The first HOMO level HOMO1, the first LUMO level LUMO1, the second HOMO level HOMO2 and the second LUMO level LUMO2 satisfy the following formula (1).

[Formula 8]

(LUMO2−HOMO2)<(LUMO1−HOMO1) (1)

### <<Structure of Light-Emitting Device 321(22)>>

Table 7 shows the structure of the light-emitting device 321(22). The structure formulae, HOMO levels, and LUMO levels of materials used for the light-emitting device described in this example are shown below.

The absorption spectrum of TTPA used as the light-emitting material FM of the light-emitting device 321(22) has the longest-wavelength edge at a wavelength of 514 nm (see FIG. 18). Note that the absorption spectrum of the light-emitting material FM in the toluene solution was measured at room temperature with the use of an ultraviolet-visible spectrophotometer (V550, produced by JASCO Corporation).

Ir(5tBuppy)₃ used as the organometallic complex of the light-emitting device 321(22) has a function of emitting phosphorescent light. The spectrum of the phosphorescent light has the shortest-wavelength edge at a wavelength of 484 nm, and the edge is positioned at a wavelength shorter than the wavelength of 514 nm. Furthermore, Ir(5tBuppy)₃ has the first HOMO level HOMO1 at −5.32 eV and the first LUMO level LUMO1 at −2.25 eV. Note that the phosphorescent spectrum of the dichloromethane solution of the organometallic complex was measured at room temperature with the use of a fluorescence spectrophotometer (FP-8600, produced by JASCO Corporation). The HOMO level and the LUMO level of the organometallic complex were calculated from the oxidation potential and the reduction potential obtained by cyclic voltammetry (CV) measurement with the use of an electrochemical analyzer (ALS model 600A or 600C, produced by BAS Inc.).

The mixed material used as the host material of the light-emitting device 321(22) has a function of emitting delayed fluorescent light. Specifically, the mixed material containing mPCCzPTzn-02 and PCCP emits delayed fluorescent light. The mixed material has the second HOMO level HOMO2 at −5.63 eV and the second LUMO level LUMO2 at −3.00 eV (see Table 2). Note that the HOMO level and the LUMO level of the host material were calculated from the oxidation potential and the reduction potential obtained by cyclic voltammetry (CV) measurement with the use of an electrochemical analyzer (ALS model 600A or 600C, produced by BAS Inc.).

Note that the value of (LUMO2−HOMO2) is 2.63 eV, which is smaller than 3.07 eV that is the value of (LUMO1−HOMO1).

TABLE 7

| | Reference | | Composition | Thickness/ |
|---|---|---|---|---|
| Structure | numeral | Material | ratio | nm |
| Electrode | 102 | Al | | 200 |
| Layer | 105 | LiF | | 1 |
| Layer | 113B | NBPhen | | 10 |
| Layer | 113A | mPCCzPTzn-02 | | 20 |
| Layer | 111 | mPCCzPTzn- | 0.5:0.5:0.1:0.05 | 40 |
| | | 02:PCCP:Ir(5tBuppy)3:TTPA | | |
| Layer | 112 | PCBBilBP | | 20 |
| Layer | 104 | DBT3PII:MoOx | 1:0.5 | 40 |
| Electrode | 101 | ITSO | | 70 |

### <<Fabrication Method of Light-Emitting Device 321(22)>>

The light-emitting device 321(22) described in this example was fabricated by a method including the following steps.

### [First Step]

In the first step, the electrode 101 was formed. Specifically, the electrode 101 was formed by a sputtering method using indium oxide-tin oxide containing silicon or silicon oxide (abbreviation: ITSO) as a target.

The electrode 101 contains ITSO and has a thickness of 70 nm and an area of 4 mm² (2 mm×2 mm).

Next, a substrate over which the electrode 101 was formed was washed with water, baked at 200° C. for an hour, and then subjected to UV ozone treatment for 370 seconds. After that, the substrate was transferred into a vacuum evaporation apparatus where the pressure was reduced to approximately 10-4 Pa, and vacuum baking was performed at 170° C. for 30 minutes in a heating chamber of the vacuum evaporation apparatus. Then, the substrate was cooled down for approximately 30 minutes.

### [Second Step]

In the second step, the layer 104 was formed over the electrode 101. Specifically, the materials were co-deposited by a resistance-heating method.

Note that the layer 104 contains DBT3P-II and MoO₃ at DBT3P-II:MoO₃=1:0.5 (weight ratio) and has a thickness of 40 nm.

### [Third Step]

In the third step, the layer 112 was formed over the layer 104. Specifically, the material was deposited by a resistance-heating method.

Note that the layer 112 contains 4,4′-diphenyl-4″-(9-phenyl-9H-carbazol-3-yl)triphenylamine (abbreviation: PCBBi1BP) and has a thickness of 20 nm.

### [Fourth Step]

In the fourth step, the layer 111 was formed over the layer 112. Specifically, the materials were co-deposited by a resistance-heating method.

Note that the layer 111 contains mPCCzPTzn-02, PCCP, Ir(5tBuppy)₃, and TTPA at mPCCzPTzn-02:PCCP:Ir(5tBuppy)₃:TTPA=0.5:0.5:0.1:0.05 (weight ratio) and has a thickness of 40 nm. Note that mPCCzPTzn-02 and PCCP are substances that form an exciplex.

TABLE 8

| | HOST | ED | FM |
|---|---|---|---|
| Light-emitting | mPCCzPTzn-02:PCCP | Ir(5tBuppy)3 | TTPA |
| device 321(22) | | | |
| Light-emitting | mPCCzPTzn-02:PCCP | Ir(4tBuppy)3 | TTPA |
| device 331(22) | | | |
| Comparative | mPCCzPTzn-02:PCCP | Ir(ppy)3 | TTPA |
| device 311(22) | | | |

### [Fifth Step]

In the fifth step, the layer 113A was formed over the layer 111. Specifically, the material was deposited by a resistance-heating method.

The layer 113A contains mPCCzPTzn-02 and has a thickness of 20 nm.

### [Sixth Step]

In the sixth step, the layer 113B was formed over the layer 113A. Specifically, the material was deposited by a resistance-heating method.

Note that the layer 113B contains NBPhen and has a thickness of 10 nm.

### [Seventh Step]

In the seventh step, the layer 105 was formed over the layer 113B. Specifically, the material was deposited by a resistance-heating method.

The layer 105 contains LiF and has a thickness of 1 nm.

### [Eighth Step]

In the eighth step, the electrode 102 was formed over the layer 105. Specifically, the material was deposited by a resistance-heating method.

The electrode 102 contains Al and has a thickness of 200 nm.

### <Light-Emitting Device 331(22)>

The fabricated light-emitting device 331(22) described in this example has a structure similar to that of the light-emitting device 150 (see FIG. 17A).

### <<Structure of Light-Emitting Device 331(22)>>

The light-emitting device 331(22) is different from the light-emitting device 321(22) in that tris[2-[4-(tert-butyl)-2-pyridinyl-κC]phenyl-κC]iridium (abbreviation: Ir(4tBuppy)₃) is used as the energy donor material ED.

Ir(4tBuppy)₃ used as the organometallic complex of the light-emitting device 331(22) has a function of emitting phosphorescent light (see FIG. 19). The spectrum of the phosphorescent light has the shortest-wavelength edge at a wavelength of 482 nm, and the edge is positioned at a wavelength shorter than the wavelength of 514 nm. Furthermore, Ir(4tBuppy)₃ has the first HOMO level HOMO1 at −5.26 eV and the first LUMO level LUMO1 at −2.25 eV. Note that the phosphorescent spectrum of the dichloromethane solution of the organometallic complex was measured at room temperature with the use of a fluorescence spectrophotometer (FP-8600, produced by JASCO Corporation). The HOMO level and the LUMO level of the organometallic complex were calculated from the oxidation potential and the reduction potential obtained by cyclic voltammetry (CV) measurement with the use of an electrochemical analyzer (ALS model 600A or 600C, produced by BAS Inc.).

Note that the value of (LUMO2−HOMO2) is 2.63 eV, which is smaller than 3.01 eV that is the value of (LUMO1−HOMO1).

### <<Fabrication Method of Light-Emitting Device 331(22)>>

The light-emitting device 331(22) described in this example was fabricated by a method including the following steps.

Note that the fabrication method of the light-emitting device 331(22) is different from the fabrication method of the light-emitting device 321(22) in that Ir(4tBuppy)₃ is used as the energy donor material ED instead of Ir(5tBuppy)₃ in the step of forming the layer 111. Different portions are described in detail here, and the above description is referred to for portions formed by a similar method.

### [Fourth Step]

In the fourth step, the layer 111 was formed over the layer 112. Specifically, the materials were co-deposited by a resistance-heating method.

Note that the layer 111 contains mPCCzPTzn-02, PCCP, Ir(4tBuppy)₃, and TTPA at mPCCzPTzn-02:PCCP:Ir(4tBuppy)₃:TTPA=0.5:0.5:0.1:0.05 (weight ratio) and has a thickness of 40 nm (see Table 8). Note that mPCCzPTzn-02 and PCCP are substances that form an exciplex.

### <<Operation Characteristics of Light-Emitting Device 321(22) and Light-Emitting Device 331(22)>>

When supplied with electric power, the light-emitting device 321(22) and the light-emitting device 331(22) emitted green light EL1 (see FIG. 17A). The operation characteristics of the light-emitting device 321(22) and the light-emitting device 331(22) were measured (see FIG. 32 to FIG. 37). The luminance, CIE chromaticity, and emission spectra were measured at room temperature with a spectroradiometer (SR-UL1R manufactured by TOPCON TECHNOHOUSE CORPORATION).

Table 4 shows main initial characteristics of the fabricated light-emitting devices emitting light at a luminance of approximately 1000 cd/m². Table 4 also shows a time LT90 taken for the luminance to drop to 90% of its initial value at a constant current density (50 mA/cm²), which were obtained under the condition where the light-emitting devices each emitted light. Table 4 also shows the characteristics of other light-emitting devices having structures described later.

The light-emitting device 321(22) and the light-emitting device 331(22) were each found to exhibit favorable characteristics. For example, the light-emitting device 321(22) and the light-emitting device 331(22) each emitted light with an emission spectrum derived from the light-emitting material FM, having a peak wavelength at approximately 540 nm (see FIG. 37). Light emission derived from the energy donor material ED was not observed. Alternatively, energy was transferred from the energy donor material ED to the light-emitting material FM. Undesirable energy transfer from the energy donor material ED to the light-emitting material FM was able to be inhibited. Energy transfer by the Dexter mechanism was able to be inhibited.

The light-emitting device 321(22) and the light-emitting device 331(22) were each able to achieve a luminance of approximately 1000 cd/m² at a voltage lower than that of a comparative device 311(22) (see Table 4). Moreover, the light-emitting device 321(22) and the light-emitting device 331(22) each exhibited higher external quantum efficiency than the comparative device 311(22).

The light-emitting device 321(22) and the light-emitting device 331(22) each took a longer time for the luminance to drop to 90% of its initial value than the comparative device 311(22) under the condition where light was emitted at a constant current density of 50 mA/cm².

### Reference Example 3

The fabricated comparative device 311(22) described in this reference example is different from the light-emitting device 321(22) and the light-emitting device 331(22) in that tris(2-phenylpyridinato-N,C²′)iridium(III) (abbreviation: Ir(ppy)₃) is used as the energy donor material ED.

### <<Structure of Comparative Device 311(22)>>

The fabricated comparative device 311(22) described in this reference example is different from the light-emitting device 321(22) in that Ir(ppy)₃ is used as the energy donor material ED.

Ir(ppy)₃ used as the organometallic complex of the light-emitting device 311(22) has a ligand. Note that the ligand does not have an alkyl group, a cycloalkyl group, or a trialkylsilyl group.

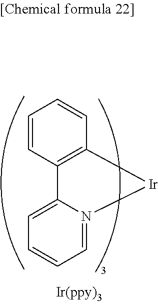

### <<Fabrication Method of Comparative Device 311(22)>>

The comparative device 311(22) was fabricated by a method including the following steps.

Note that the fabrication method of the comparative device 311(22) is different from the fabrication method of the light-emitting device 321(22) in that Ir(ppy)₃ is used as the energy donor material ED instead of Ir(5tBuppy)₃ in the step of forming the layer 111. Different portions are described in detail here, and the above description is referred to for portions formed by a similar method.

### [Fourth Step]

In the fourth step, the layer 111 was formed over the layer 112. Specifically, the materials were co-deposited by a resistance-heating method.

Note that the layer 111 contains mPCCzPTzn-02, PCCP, Ir(ppy)₃, and TTPA at mPCCzPTzn-02:PCCP:Ir(ppy)₃:TTPA=0.5:0.5:0.1:0.05 (weight ratio) and has a thickness of 40 nm (see Table 8).

### Reference Example 4

A fabricated reference device 2 described in this reference example is different from the reference device 1 in the structure of the layer 111. Specifically, the reference device 2 is different from the reference device 1 in that a mixed material containing mPCCzPTzn-02 and PCCP is used as the host material instead of using only mPCCzPTzn-02 as the host material.

### <<Fabrication Method of Reference Device 2>>

The reference device 2 described in this example was fabricated by a method including the following steps.

Note that the fabrication method of the reference device 2 is different from the fabrication method of the reference device 1 in the step of forming the layer 111. Different portions are described in detail here, and the above description is referred to for portions formed by a similar method.

### [Fourth Step]

In the fourth step, the layer 111 was formed over the layer 112. Specifically, the materials were deposited by a resistance-heating method.

The layer 111 contains mPCCzPTzn-02 and PCCP at mPCCzPTzn-02:PCCP=0.8:0.2 (weight ratio) and has a thickness of 30 nm.

### <<Operation Characteristics of Reference Device 2>>

When supplied with electric power, the reference device 2 emitted light EL1 (see FIG. 17A). The operation characteristics of the reference device 2 were measured (see FIG. 29 and FIG. 30). Note that the luminance and the CIE chromaticity were measured with a luminance colorimeter (BM-5A produced by TOPCON TECHNOHOUSE CORPORATION) and the emission spectrum was measured with a multi-channel spectrometer (PMA-11 produced by Hamamatsu Photonics K.K.) at room temperature.

Delayed fluorescent light was measured with the use of a picosecond fluorescence lifetime measurement system (produced by Hamamatsu Photonics K.K.). Specifically, a voltage corresponding to a condition enabling 1300 cd/m² was applied to the reference device 2, a predetermined voltage was kept in a rectangular pulse form during 100 s, and attenuation of delayed fluorescent light was observed during 20 s. Furthermore, a negative bias, −5 V, was applied during a period of observing the attenuation of the delayed fluorescence. The measurement was repeated at a cycle of 10 Hz, and then obtained data was added up. FIG. 31 shows the emission intensity of the reference device 2 in pulse driving at a predetermined voltage.

Holes supplied from the electrode 101 and electrons supplied from the electrode 102 were recombined in the layer 111, and light emission was obtained from the host material in the resulting generated excited state, specifically, an exciplex of mPCCzPTzn-02 and PCCP (see FIG. 30). In addition, at least light emission from excitons having a short lifetime of 0.3 μs or less and light emission from excitons having a long lifetime of 4 μs were observed (see FIG. 31). Thus, it was found that singlet excitons were generated through triplet excitons having a long lifetime.

### Example 3

In this example, the light-emitting device 322(22) to the light-emitting device 332(22) of one embodiment of the present invention are described with reference to FIG. 17 and FIG. 39 to FIG. 45. Note that in the tables in this example, subscript and superscript characters are written in ordinary size for convenience. For example, a subscript character in an abbreviation or a superscript character in a unit are written in ordinary size in the tables. The corresponding description in the specification gives an accurate reading of such notations in the tables.

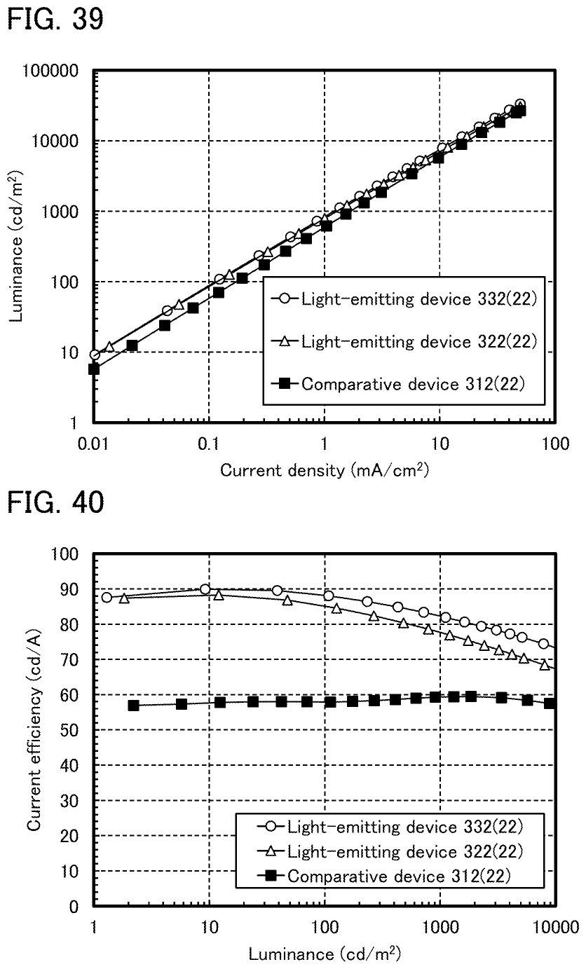

FIG. 39 is a graph showing current density-luminance characteristics of the light-emitting device 322(22) and the light-emitting device 332(22).

FIG. 40 is a graph showing luminance-current efficiency characteristics of the light-emitting device 322(22) and the light-emitting device 332(22).

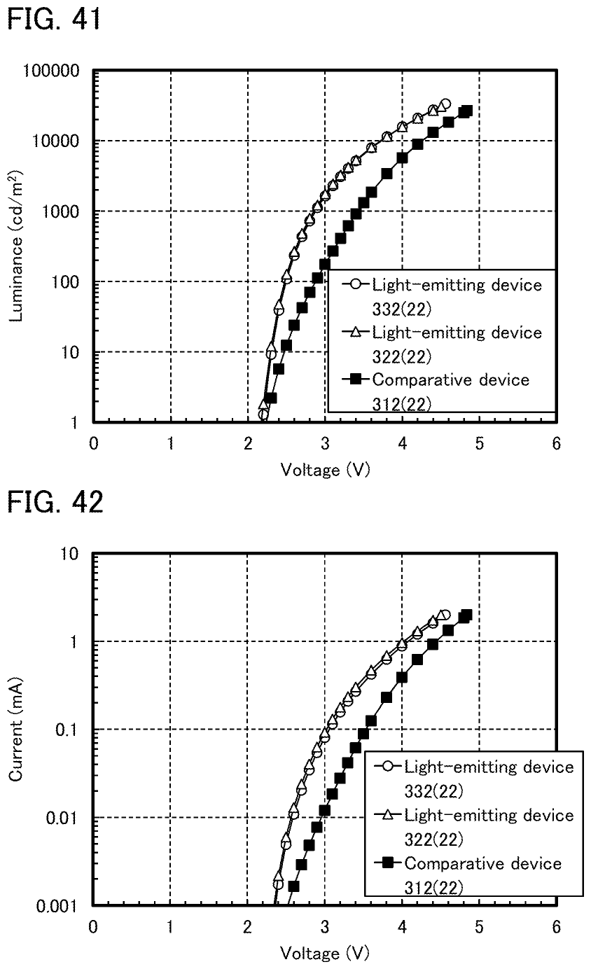

FIG. 41 is a graph showing voltage-luminance characteristics of the light-emitting device 322(22) and the light-emitting device 332(22).

FIG. 42 is a graph showing voltage-current characteristics of the light-emitting device 322(22) and the light-emitting device 332(22).

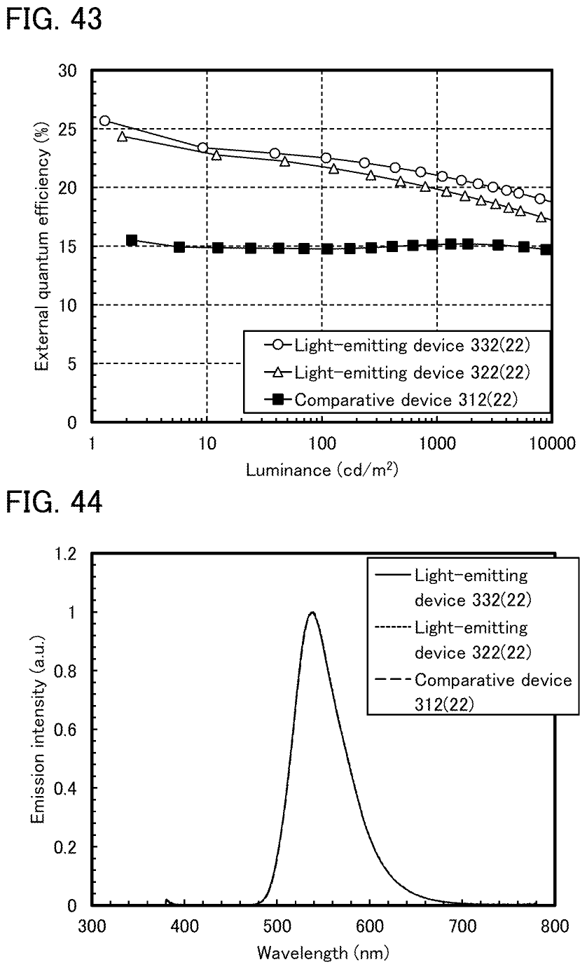

FIG. 43 is a graph showing luminance-external quantum efficiency characteristics of the light-emitting device 322(22) and the light-emitting device 332(22). Note that the external quantum efficiency was calculated from luminance assuming that the light distribution characteristics of the light-emitting devices are Lambertian type.

FIG. 44 is a graph showing emission spectra of the light-emitting device 322(22) and the light-emitting device 332(22) each emitting light at a luminance of 1000 cd/m².

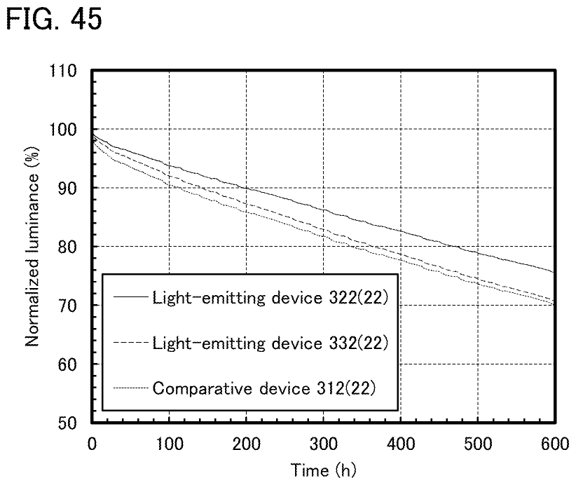

FIG. 45 is a graph showing normalized luminance-temporal change characteristics of the light-emitting device 322(22) and the light-emitting device 332(22) each emitting light at a constant current density of 50 mA/cm².

### <Light-Emitting Device 322(22)>

The fabricated light-emitting device 322(22) described in this example has a structure similar to that of the light-emitting device 150 (see FIG. 17A). Note that the light-emitting device 322(22) is different from the light-emitting device 321(22) in that 2Ph-mmtBuDPhA2Anth is used as the light-emitting material FM.

The light-emitting material FM has a second substituent R², and the second substituent R² is any of a methyl group, a branched alkyl group, a substituted or unsubstituted cycloalkyl group, and a trialkylsilyl group. Note that the number of carbon atoms of the branched alkyl group is 3 to 12, the number of carbon atoms forming a ring of the cycloalkyl group is 3 to 10, and the number of carbon atoms of the trialkylsilyl group is 3 to 12.

### <<Structure of Light-Emitting Device 322(22)>>

The fabricated light-emitting device 322(22) described in this example is different from the light-emitting device 321(22) in that 2Ph-mmtBuDPhA2Anth is used as the light-emitting material FM.

The absorption spectrum of 2Ph-mmtBuDPhA2Anth used as the light-emitting material FM of the light-emitting device 322(22) has the longest-wavelength edge at a wavelength of 519 nm (see FIG. 20).

Ir(5tBuppy)₃ used as the organometallic complex of the light-emitting device 322(22) has a function of emitting phosphorescent light. The spectrum of the phosphorescent light has the shortest-wavelength edge at a wavelength of 484 nm, and the edge is positioned at a wavelength shorter than the wavelength of 519 nm.

### <<Fabrication Method of Light-Emitting Device 322(22)>>

The light-emitting device 322(22) was fabricated by a method including the following steps.

Note that the fabrication method of the light-emitting device 322(22) is different from the fabrication method of the light-emitting device 321(22) in that 2Ph-mmtBuDPhA2Anth is used as the light-emitting material FM instead of TTPA in the step of forming the layer 111. Different portions are described in detail here, and the above description is referred to for portions formed by a similar method.

### [Fourth Step]

In the fourth step, the layer 111 was formed over the layer 112. Specifically, the materials were co-deposited by a resistance-heating method.

Note that the layer 111 contains mPCCzPTzn-02, PCCP, Ir(5tBuppy)₃, and 2Ph-mmtBuDPhA2Anth at mPCCzPTzn-02:PCCP:Ir(5tBuppy)₃:2Ph-mmtBuDPhA2Anth=0.5:0.5:0.1:0.05 (weight ratio) and has a thickness of 40 nm.

TABLE 9

| | HOST | ED | FM |
|---|---|---|---|
| Light-emitting | mPCCzPTzn- | Ir(5tBuppy)3 | 2Ph- |
| devi [symbol] 322(22) | 02:PCCP | | mmtBuDPhA2Anth |
| Light-emitting | mPCCzPTzn- | Ir(4tBuppy)3 | 2Ph- |
| devi [symbol] 332(22) | 02:PCCP | | mmtBuDPhA2Anth |
| comparisondevice | mPCCzPTzn- | Ir(ppy)3 | 2Ph- |
| 312(22) | 02:PCCP | | mmtBuDPhA2Anth |

[symbol]

indicates data missing or illegible when filed

### <Light-Emitting Device 332(22)>

The fabricated light-emitting device 332(22) described in this example has a structure similar to that of the light-emitting device 150 (see FIG. 17A). Note that the light-emitting device 332(22) is different from the light-emitting device 321(22) in that Ir(4tBuppy)₃ is used as the energy donor material ED and that 2Ph-mmtBuDPhA2Anth is used as the light-emitting material FM.

### <<Structure of Light-Emitting Device 332(22)>>

The fabricated light-emitting device 332(22) described in this example is different from the light-emitting device 321(22) in that Ir(4tBuppy)₃ is used as the energy donor material ED and 2Ph-mmtBuDPhA2Anth is used as the light-emitting material FM.

The absorption spectrum of 2Ph-mmtBuDPhA2Anth used as the light-emitting material FM of the light-emitting device 332(22) has the longest-wavelength edge at a wavelength of 519 nm (see FIG. 21).

Ir(4tBuppy)₃ used as the organometallic complex of the light-emitting device 332(22) has a function of emitting phosphorescent light. The spectrum of the phosphorescent light has the shortest-wavelength edge at a wavelength of 482 nm, and the edge is positioned at a wavelength shorter than the wavelength of 519 nm. Furthermore, Ir(4tBuppy)₃ has the first HOMO level HOMO1 at −5.26 eV and the first LUMO level LUMO1 at −2.25 eV.

Note that the value of (LUMO2−HOMO2) is 2.63 eV, which is smaller than 3.01 eV that is the value of (LUMO1−HOMO1).

### <<Fabrication Method of Light-Emitting Device 332(22)>>

The light-emitting device 332(22) described in this example was fabricated by a method including the following steps.

Note that the fabrication method of the light-emitting device 332(22) is different from the fabrication method of the light-emitting device 321(22) in that Ir(4tBuppy)₃ is used as the energy donor material ED instead of Ir(5tBuppy)₃ and 2Ph-mmtBuDPhA2Anth is used as the light-emitting material FM instead of TTPA in the step of forming the layer 111. Different portions are described in detail here, and the above description is referred to for portions formed by a similar method.

### [Fourth Step]

In the fourth step, the layer 111 was formed over the layer 112. Specifically, the materials were co-deposited by a resistance-heating method.

Note that the layer 111 contains mPCCzPTzn-02, PCCP, Ir(4tBuppy)₃, and 2Ph-mmtBuDPhA2Anth at mPCCzPTzn-02:PCCP:Ir(4tBuppy)₃:2Ph-mmtBuDPhA2Anth=0.5:0.5:0.1:0.05 (weight ratio) and has a thickness of 40 nm (see Table 9).

### <<Operation Characteristics of Light-Emitting Device 322(22) and Light-Emitting Device 332(22)>>

When supplied with electric power, the light-emitting device 322(22) and the light-emitting device 332(22) emitted green light EL1 (see FIG. 17A). The operation characteristics of the light-emitting device 322(22) and the light-emitting device 332(22) were measured (see FIG. 39 to FIG. 44). The luminance, CIE chromaticity, and emission spectra were measured at room temperature with a spectroradiometer (SR-UL1R manufactured by TOPCON TECHNOHOUSE CORPORATION).

Table 4 shows main initial characteristics of the light-emitting device 322(22) and the light-emitting device 332(22) each emitting light at a luminance of approximately 1000 cd/m². Table 4 also shows a time LT90 taken for the luminance to drop to 90% of its initial value at a constant current density (50 mA/cm²), which were obtained under the condition where the light-emitting devices each emitted light.

The light-emitting device 322(22) and the light-emitting device 332(22) were each found to exhibit favorable characteristics. For example, the light-emitting device 322(22) and the light-emitting device 332(22) each emitted light with an emission spectrum derived from the light-emitting material FM, having a peak wavelength at approximately 540 nm (see FIG. 44). Light emission derived from the energy donor material ED was not observed. Alternatively, energy was transferred from the energy donor material ED to the light-emitting material FM. Undesirable energy transfer from the energy donor material ED to the light-emitting material FM was able to be inhibited. Energy transfer by the Dexter mechanism was able to be inhibited.

The light-emitting device 322(22) and the light-emitting device 332(22) were each able to achieve a luminance of approximately 1000 cd/m² at a voltage lower than that of a comparative device 312(22) (see Table 4). Moreover, the light-emitting device 322(22) and the light-emitting device 332(22) each exhibited higher external quantum efficiency than the comparative device 312(22).

The light-emitting device 322(22) and the light-emitting device 332(22) each took a longer time for the luminance to drop to 90% of its initial value than the comparative device 312(22) under the condition where light was emitted at a constant current density of 50 mA/cm² and had higher reliability than the comparative device 312(22) (see FIG. 45).

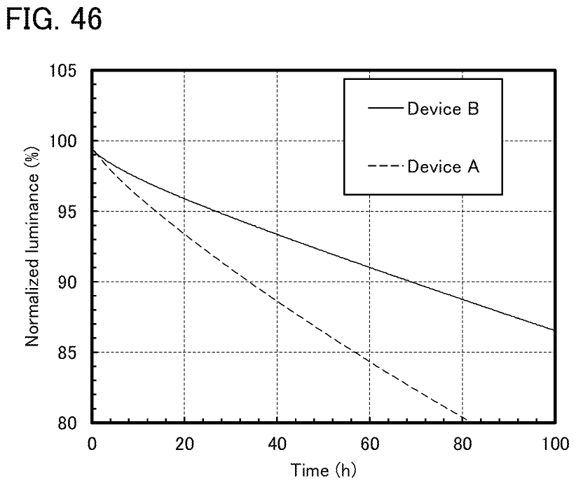

The light-emitting device of one embodiment of the present invention can have higher reliability than a conventional light-emitting device in an environment at 65° C. For example, when the green light-emitting devices emit light at approximately 29000 cd/m², it can be expected that the time taken for the luminance to drop to 90% of the initial luminance of the light-emitting device B with reliability is twice as long as that of the conventional light-emitting device A (see FIG. 46).

### Reference Example 5

The fabricated comparative device 312(22) described in this reference example is different from the light-emitting device 322(22) and the light-emitting device 332(22) in that tris(2-phenylpyridinato-N,C²′)iridium(III) (abbreviation: Ir(ppy)₃) is used as the energy donor material ED.

### <Structure of Comparative Device 312(22)>

In the fabricated comparative device 312(22) described in this reference example, Ir(ppy)₃ was used as the energy donor material ED.

### <<Structure of Comparative Device 312(22)>>

In the fabricated comparative device 312(22) described in this reference example, Ir(ppy)₃ was used as the energy donor material ED.

### <<Fabrication Method of Comparative Device 312(22)>>

The comparative device 312(22) was fabricated by a method including the following steps.

Note that the fabrication method of the comparative device 312(22) is different from the fabrication method of the light-emitting device 321(22) in that Ir(ppy)₃ is used as the energy donor material ED instead of Ir(5tBuppy)₃ and 2Ph-mmtBuDPhA2Anth is used as the light-emitting material FM instead of TTPA in the step of forming the layer 111. Different portions are described in detail here, and the above description is referred to for portions formed by a similar method.

### [Fourth Step]

In the fourth step, the layer 111 was formed over the layer 112. Specifically, the materials were co-deposited by a resistance-heating method.

Note that the layer 111 contains mPCCzPTzn-02, PCCP, Ir(ppy)₃, and 2Ph-mmtBuDPhA2Anth at mPCCzPTzn-02:PCCP:Ir(ppy)₃:2Ph-mmtBuDPhA2Anth=0.5:0.5:0.1:0.05 (weight ratio) and has a thickness of 40 nm (see Table 9).

### REFERENCE NUMERALS

101: electrode, 101S: electrode, 102: electrode, 103: unit, 103S: unit, 104: layer, 105: layer, 106: intermediate layer, 106A: layer, 106B: layer, 111: layer, 112: layer, 113: layer, 113A: layer, 113B: layer, 114: layer, 114N: layer, 114P: layer, 150: light-emitting device, 170: optical functional device, 400: substrate, 401: electrode, 403: EL layer, 404: electrode, 405: sealant, 406: sealant, 407: sealing substrate, 412: pad, 420: IC chip, 521: insulating film, 528: insulating film, 573: insulating film, 573A: insulating film, 573B: insulating film, 601: source line driver circuit, 602: pixel portion, 603: gate line driver circuit, 604: sealing substrate, 605: sealant, 607: space, 608: wiring, 609: FPC, 610: element substrate, 611: switching FET, 612: current control FET, 613: electrode, 614: insulator, 616: EL layer, 617: electrode, 618: light-emitting device, 623: FET, 700: functional panel, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: interlayer insulating film, 1021: interlayer insulating film, 1022: electrode, 1024B: electrode, 1024G: electrode, 1024R: electrode, 1024 W: electrode, 1025: partition, 1028: EL layer, 1029: electrode, 1031: sealing substrate, 1032: sealant, 1033: base material, 1034B: coloring layer, 1034G: coloring layer, 1034R: coloring layer, 1035: black matrix, 1036: overcoat layer, 1037: interlayer insulating film, 1040: pixel portion, 1041: driver circuit portion, 1042: peripheral portion, 2001: housing, 2002: light source, 2100: robot, 2101: illuminance sensor, 2102: microphone, 2103: upper camera, 2104: speaker, 2105: display, 2106: lower camera, 2107: obstacle sensor, 2108: moving mechanism, 2110: arithmetic device, 3001: lighting device, 5000: housing, 5001: display portion, 5002: display portion, 5003: speaker, 5004: LED lamp, 5006: connection terminal, 5007: sensor, 5008: microphone, 5012: support, 5013: earphone, 5100: cleaning robot, 5101: display, 5102: camera, 5103: brush, 5104: operation button, 5120: dust, 5140: portable electronic device, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: display portion, 7401: housing, 7402: display portion, 7403: operation button, 7404: external connection port, 7405: speaker, 7406: microphone, 9310: portable information terminal, 9311: display panel, 9313: hinge, 9315: housing

1. A light-emitting device comprising:
a first electrode;
a second electrode; and
a first layer,
wherein the second electrode comprises a region overlapping with the first electrode,
wherein the first layer is positioned between the first electrode and the second electrode,
wherein the first layer comprises a light-emitting material, a first organic compound, and a first material,
wherein the light-emitting material is configured to emit fluorescent light,
wherein an absorption spectrum of the light-emitting material has a longest-wavelength edge at a first wavelength,
wherein the first organic compound is configured to convert triplet excitation energy into light emission,
wherein a spectrum of light emitted by the first organic compound has a shortest-wavelength edge at a second wavelength,
wherein the second wavelength is shorter than the first wavelength,
wherein the first organic compound comprises a first substituent,
wherein the first substituent is any of an alkyl group, a substituted or unsubstituted cycloalkyl group, and a trialkylsilyl group,
wherein a number of carbon atoms of the alkyl group is 3 to 12,
wherein a number of carbon atoms forming a ring of the cycloalkyl group is 3 to 10,
wherein a number of carbon atoms of the trialkylsilyl group is 3 to 12, and
wherein the first material is configured to emit delayed fluorescent light at room temperature.

2. A light-emitting device comprising:
a first electrode;
a second electrode; and
a first layer,
wherein the second electrode comprises a region overlapping with the first electrode,
wherein the first layer is positioned between the first electrode and the second electrode,
wherein the first layer comprises a light-emitting material, a first organic compound, and a first material,
wherein the light-emitting material is configured to emit fluorescent light,
wherein an absorption spectrum of the light-emitting material has a longest-wavelength edge at a first wavelength,
wherein the first organic compound is configured to convert triplet excitation energy into light emission,
wherein a spectrum of light emitted by the first organic compound has a shortest-wavelength edge at a second wavelength,
wherein the second wavelength is shorter than the first wavelength,
wherein the first organic compound comprises a first substituent,
wherein the first substituent is any of an alkyl group, a substituted or unsubstituted cycloalkyl group, and a trialkylsilyl group,
wherein a number of carbon atoms of the alkyl group is 3 to 12,
wherein a number of carbon atoms forming a ring of the cycloalkyl group is 3 to 10,
wherein a number of carbon atoms of the trialkylsilyl group is 3 to 12, and
wherein the first material comprises a second organic compound and a third organic compound, and
wherein the second organic compound and the third organic compound form an exciplex.

3. The light-emitting device according to claim 1,
wherein the first organic compound comprises a first HOMO level HOMO1 and a first LUMO level LUMO1,
wherein the first material comprises a second HOMO level HOMO2 and a second LUMO level LUMO2, and
wherein the first HOMO level HOMO1, the first LUMO level LUMO1, the second HOMO level HOMO2, and the second LUMO level LUMO2 satisfy a formula (1) below:
[Formula 1]
(LUMO2−HOMO2)<(LUMO1−HOMO1) (1)

4. The light-emitting device according to claim 1,
wherein the light-emitting material comprises a second substituent,
wherein the second substituent is any of a methyl group, a branched alkyl group, a substituted or unsubstituted cycloalkyl group, and a trialkylsilyl group,
wherein a number of carbon atoms of the branched alkyl group is 3 to 12,
wherein a number of carbon atoms forming a ring of the cycloalkyl group is 3 to 10, and
wherein a number of carbon atoms of the trialkylsilyl group is 3 to 12.

5. The light-emitting device according to claim 1,
wherein the light-emitting material comprises five or more second substituents,
wherein at least five of the five or more second substituents are each independently any of a branched alkyl group, a substituted or unsubstituted cycloalkyl group, and a trialkylsilyl group,
wherein a number of carbon atoms of the branched alkyl group is 3 to 12,
wherein a number of carbon atoms forming a ring of the cycloalkyl group is 3 to 10, and
wherein a number of carbon atoms of the trialkylsilyl group is 3 to 12.

6. The light-emitting device according to claim 3,
wherein the light-emitting material comprises a third LUMO level, and
wherein the third LUMO level is higher than the second LUMO level LUMO2.

7. The light-emitting device according to claim 6,
wherein the second HOMO level HOMO2 is higher than the first HOMO level HOMO1, and
wherein the second LUMO level LUMO2 is lower than the first LUMO level LUMO1.

8. The light-emitting device according to claim 6,
wherein the first HOMO level HOMO1 is higher than the second HOMO level HOMO2.

9. The light-emitting device according to claim 6,
wherein the first LUMO level LUMO1 is lower than the second LUMO level LUMO2.

10. A light-emitting apparatus comprising the light-emitting device according to claim 1, and a transistor or a substrate.

11. A display device comprising the light-emitting device according to claim 1, and at least one of a transistor and a substrate.

12. A lighting device comprising the light-emitting apparatus according to claim 10, and a housing.

13. An electronic device comprising the display device according to claim 11, and at least one of a sensor, an operation button, a speaker, and a microphone.

14. The light-emitting device according to claim 2,
wherein the first organic compound comprises a first HOMO level HOMO1 and a first LUMO level LUMO1,
wherein the first material comprises a second HOMO level HOMO2 and a second LUMO level LUMO2, and
wherein the first HOMO level HOMO1, the first LUMO level LUMO1, the second HOMO level HOMO2, and the second LUMO level LUMO2 satisfy a formula (1) below:
[Formula 1]
(LUMO2−HOMO2)<(LUMO1−HOMO1) (1)

15. The light-emitting device according to claim 2,
wherein the light-emitting material comprises a second substituent,
wherein the second substituent is any of a methyl group, a branched alkyl group, a substituted or unsubstituted cycloalkyl group, and a trialkylsilyl group,
wherein a number of carbon atoms of the branched alkyl group is 3 to 12,
wherein a number of carbon atoms forming a ring of the cycloalkyl group is 3 to 10, and
wherein a number of carbon atoms of the trialkylsilyl group is 3 to 12.

16. The light-emitting device according to claim 2,
wherein the light-emitting material comprises five or more second substituents,
wherein at least five of the five or more second substituents are each independently any of a branched alkyl group, a substituted or unsubstituted cycloalkyl group, and a trialkylsilyl group,
wherein a number of carbon atoms of the branched alkyl group is 3 to 12,
wherein a number of carbon atoms forming a ring of the cycloalkyl group is 3 to 10, and
wherein a number of carbon atoms of the trialkylsilyl group is 3 to 12.

17. The light-emitting device according to claim 14,
wherein the light-emitting material comprises a third LUMO level, and
wherein the third LUMO level is higher than the second LUMO level LUMO2.

18. The light-emitting device according to claim 17,
wherein the second HOMO level HOMO2 is higher than the first HOMO level HOMO1, and
wherein the second LUMO level LUMO2 is lower than the first LUMO level LUMO1.

19. The light-emitting device according to claim 17,
wherein the first HOMO level HOMO1 is higher than the second HOMO level HOMO2.

20. The light-emitting device according to claim 17,
wherein the first LUMO level LUMO1 is lower than the second LUMO level LUMO2.

21. A light-emitting apparatus comprising the light-emitting device according to claim 2, and a transistor or a substrate.

22. A display device comprising the light-emitting device according to claim 2, and at least one of a transistor and a substrate.

23. A lighting device comprising the light-emitting apparatus according to claim 21, and a housing.

24. An electronic device comprising the display device according to claim 22, and at least one of a sensor, an operation button, a speaker, and a microphone.
